(19) United States
(12) Patent Application Publication
(10) Pub. No.: US 2026/0314318 A1
(43) Pub. Date: Oct. 8, 2026

(54) MASS TRANSFER APPARATUS AND MASS TRANSFER METHOD THEREOF

(71) Applicant: Century Technology (ShenZhen) Corp.,LTD, Shen-zhen (CN)

(72) Inventors: Ke-Xian LIU, Shen-zhen (CN); Xiao-Min DENG, Shen-zhen (CN); Lei-Cheng SUN, Shen-zhen (CN); Hsin-Chieh WU, Shen-zhen (CN); Chang ZHANG, Shen-zhen (CN); Sung-Nan CHENG, Shen-zhen (CN); Bing-Bing LIU, Shen-zhen (CN); Yang MEI, Shen-zhen (CN); Yong LI, Shen-zhen (CN); Chen-Qiong LV, Shen-zhen (CN); Shao-Fu YANG, Shen-zhen (CN); Deng-Kai CHANG, Shen-zhen (CN)

(21) Appl. No.: 19/484,412

(22) PCT Filed: May 14, 2024
(86) PCT No.: PCT/CN2024/093165

§ 371 Date: Nov. 14, 2025

(30) Foreign Application Priority Data
May 15, 2023 (CN) 202310543893.3
Jan. 4, 2024 (CN) 202410011580.8
Jan. 4, 2024 (CN) 202410026371.0
Jan. 4, 2024 (CN) 202410026991.4
Mar. 8, 2024 (CN) 202410271471.X
Mar. 8, 2024 (CN) 202410276425.9
Mar. 22, 2024 (CN) 202410343426.0
Apr. 29, 2024 (CN) 202410532604.4
Apr. 29, 2024 (CN) 202410534685.1
Apr. 29, 2024 (CN) 202410537019.3
Apr. 29, 2024 (CN) 202410551676.3

(51) Int. Cl. H10P 72/50; B25J 11/00; B25J 15/06; H05B 3/68; H10P 72/00; H10P 72/78

(52) U.S. Cl. CPC H10P 72/53; B25J 11/0095; B25J 15/0616; H10P 72/0446; H10P 72/78; H05B 3/68

(57) ABSTRACT

A mass transfer apparatus and a mass transfer method. The mass transfer apparatus includes a supporting portion, a picking and disposing portion, an inspection portion and a control portion. The supporting portion is used to fix at least one of a first substrate and a second substrate. The picking and disposing portion is used to be controlled to pick up a target object from the first substrate or to dispose the target object on the second substrate. The inspection portion is used to inspect a relative position of at least one of the first substrate and the second substrate and the picking and disposing portion, thus generating relative position information to control movement of the supporting portion and the picking and disposing portion. The control portion is used to control operations of the supporting portion and the picking and disposing portion according to the relative position information.

### FIELD

The present invention relates to the field of semiconductor manufacturing technology, and particularly to a mass transfer apparatus and a mass transfer method thereof.

### BACKGROUND

The size of a light-emitting diode (LED) may vary widely depending on its intended application. A large-sized LED is often used in lighting or disinfection (e.g., UV LEDs), while a small-sized LED (such as a mini-LED or a micro-LED) is commonly used in a backlight module for a display, or is directly used as pixels in a display panel (e.g., a self-luminous display panel such as an OLED).

For small-sized LED chips, particularly micro-LEDs, given the differences in material lattice matching and substrate size, a micro-LED thin-film transfer process is necessary after epitaxial growth to transfer millions of micrometer-scale micro-LEDs onto the display substrate. This process of transferring the micro-LEDs onto the display substrate is known as the mass transfer technology. In the field of mass transfer technology, if the transfer process cannot be completed efficiently within a reasonable time frame, mass production cannot be achieved.

In addition, in the existing technology, although various types of mass transfer technology have been introduced, no existing solution may simultaneously meet the demands of high transfer quantity and high precision. Thus, commercialization of the mass transfer technology still faces many challenges. For example, after the LED chips are transferred onto the display substrate of a display panel, some of the LED chips transferred onto the display substrate may become defective (e.g., damaged or short-circuited) due to issues with the LED chips themselves or errors during the transfer process, thereby reducing the manufacturing yield of the display panel.

To improve the yield of the display panel, after mass transfer, the corresponding chip inspection and repair process must be carried out. During the chip inspection, the defective LED chips need to be identified, and then the defective LED chips being identified are removed through the repair process. Subsequently, new LED chips are disposed in the same locations to complete the repair of the display substrate.

However, in the conventional repair process, it is very time-consuming to remove the defective LED chips and to replace them with new ones, and damages to the surrounding LED chips may easily occur during the removal process of the defective LED chips, such that the LED chips around the original defective chips also become defective, thus increasing the cost of manufacturing the display panel. Further, the equipment used for picking and disposing the LED chips in the repair process and the solders used for reflow soldering often face various limitations when applied to the small-sized LEDs, thereby causing difficulties in the repair process.

In addition, given the significantly larger quantity of chips involved in the mass transfer process compared to traditional applications, the issues of the defective products generated during the mass transfer and assembly processes are a major concern, thus necessitating electrical testing of the defective products. However, in the existing manufacturing process of the micro-LED device, the electrical testing typically relies on connections to the components. Thus, it is generally performed only at the final stage before shipment of the products.

On the other hand, after the LED chips are aligned to face the same direction on an alignment substrate in the mass transfer process, if the chip bodies of the LED chips are located at the bottom of the troughs of the alignment substrate without being exposed, for one of ordinary skill in the art, a crucial issue in this field exists in how the LED chips may be flipped accurately and quickly with their chip bodies at the bottom of the troughs of the alignment substrate, particularly how the LED chips may be prevented from falling during the flipping process such that the LED chips may be fixed onto the target substrate with the chip bodies facing upward.

In addition, after the LED chips are flipped, for one of ordinary skill in the art, a crucial issue in this field exists in how the chip bodies may be fixed onto the target substrate rapidly and smoothly with them facing upward.

### SUMMARY

One objective of the present invention is to provide a display panel, which may effectively enhance the efficiency of the chip repair process after the mass transfer process.

One objective of the present invention is to provide a mass transfer apparatus and a mass transfer method thereof, which may effectively enhance the success rate of picking and disposing the target objects.

One objective of the present invention is to provide an electrical testing apparatus and an electrical testing method, which may effectively enhance the efficiency and the accuracy of the transfer.

One embodiment of the present invention relates to a mass transfer apparatus, which includes a supporting portion, a picking and disposing portion, an inspection portion and a control portion. The supporting portion is used to fix at least one of a first substrate and a second substrate. The picking and disposing portion is disposed relative to the supporting portion, and is used to be controlled to pick up a target object from the first substrate or to dispose the target object on the second substrate. The inspection portion is disposed relative to the supporting portion and the picking and disposing portion, and is used to inspect a relative position of at least one of the first substrate and the second substrate and the picking and disposing portion, thus generating relative position information to control movement of the supporting portion and the picking and disposing portion. The control portion is coupled to the supporting portion, the picking and disposing portion and the inspection portion, and is used to control operations of the supporting portion and the picking and disposing portion according to the relative position information. When the picking and disposing portion disposes the target object on the second substrate, the supporting portion is controlled to output energy to the second substrate, such that an attaching force of the target object to the second substrate is greater than an attaching force of the target object to the picking and disposing portion.

One embodiment of the present invention relates to a mass transfer apparatus, which includes a supporting portion, a picking and disposing portion, an inspection portion, a control portion and an alignment actuation portion. The supporting portion is suited for supporting an alignment substrate. The alignment actuation portion is disposed on the supporting portion, and is used to apply an acting force to the alignment substrate on the supporting portion, such that LED chips on the alignment substrate are arranged to the corresponding locations on the alignment substrate.

One embodiment of the present invention relates to a mass transfer apparatus, which includes a picking and disposing portion and an adhesive substrate. The picking and disposing portion is used to pick up or dispose a plurality of target objects. The adhesive substrate is disposed in the picking and disposing portion. The adhesive substrate includes a rigid layer and an adhesive layer. The adhesive layer is disposed on a body of the substrate. The adhesive layer includes one or more protrusion structures to contact the target objects so as to pick up or dispose the target objects.

One embodiment of the present invention relates to a mass transfer method, which is applicable to the mass transfer apparatus, where the mass transfer apparatus further includes a supporting portion. The supporting portion is used to support a first alignment substrate and a second alignment substrate. The mass transfer method includes the following steps: applying an acting force to a plurality of target objects, such that the target objects fall into the first alignment substrate respectively toward a first direction; controlling the picking and disposing portion to pick up the target objects from the first alignment substrate; controlling the picking and disposing portion to dispose the target objects being picked up on the second alignment substrate; and applying an acting force to the target objects on the second alignment substrate through the second alignment substrate, such that an attaching force of the target objects to the second substrate is greater than an attaching force of the target objects to the picking and disposing portion, and the target objects are transferred from the picking and disposing portion to the second alignment substrate.

In certain embodiments of the present invention, the adhesive layer further has a plurality of second protrusion structures. The second protrusion structures are disposed on the body of the substrate, and the first protrusion structures are disposed on the second protrusion structures.

In certain embodiments of the present invention, the shape of each second protrusion structure is in a cuboid, a cylinder, or a triangular prism.

In certain embodiments of the present invention, the shape of each first protrusion structure is identical to the shape of each second protrusion structure.

In certain embodiments of the present invention, the shape of each first protrusion structure is different from the shape of each second protrusion structure.

In certain embodiments of the present invention, an area of a cross-section of each first protrusion structure is less than an area of a cross-section of each second protrusion structure.

In certain embodiments of the present invention, a sum of areas of cross-sections of the first protrusion structures disposed on the same second protrusion structure is less than an area of the cross-section of each second protrusion structure.

In certain embodiments of the present invention, the shape of each first protrusion structure is in a cuboid, a cylinder, or a triangular prism.

One embodiment of the present invention relates to an alignment substrate, which includes a body and a plurality of slots formed on the body, where at least one of the slots includes the following structures: a first side wall, a second side wall, a first bottom surface and a second bottom surface. The first side wall surrounds a periphery of the first bottom surface, and a bottom of the first side wall is connected to the first bottom surface. A side of the second bottom surface is connected to a top of the first side wall. The second side wall surrounds a periphery of the second bottom surface, and a bottom of the second side wall is connected to another side of the second bottom surface. A sum of heights of the first side wall and the second side wall is greater than a width of the first bottom surface.

One embodiment of the present invention relates to an alignment substrate, which includes a body, a plurality of slots formed on the body and a plurality of micro-hole structures, where at least one of the slots includes the following structures: a first bottom surface and a first side wall. The first side wall surrounds a periphery of the first bottom surface, and a bottom of the first side wall is connected to the first bottom surface. The micro-hole structures are disposed respectively corresponding to the slots, and are formed between the first bottom surface and a bottom of the body. Each of the micro-hole structures has a first opening and a second opening, the first opening is exposed to the first bottom surface, and the second opening is exposed to the bottom of the body.

One embodiment of the present invention relates to an alignment substrate, which includes a body and a plurality of slots formed on the body, where at least one of the slots includes the following structures: a first bottom surface and a first side wall. The first side wall surrounds a periphery of the first bottom surface, and a bottom of the first side wall is connected to the first bottom surface. At least one surface of the first side wall is not perpendicular to the first bottom surface.

One embodiment of the present invention relates to a mass transfer method, which is applicable to a mass transfer apparatus comprising a picking and disposing portion and a supporting portion. The supporting portion is configured to support a first substrate and a second substrate, and the mass transfer method includes the following steps: performing position inspection to at least one of the first substrate and the second substrate to obtain relative position information; adjusting relative positions of the picking and disposing portion and the supporting portion according to the relative position information; controlling the picking and disposing portion to pick up the target objects from the first substrate; controlling the picking and disposing portion to dispose the target objects being picked up on the second substrate; and outputting energy to the second substrate, such that an attaching force of the target objects to the second substrate is greater than an attaching force of the target objects to the picking and disposing portion.

One embodiment of the present invention relates to a mass transfer method, which is applicable to a mass transfer apparatus comprising a picking and disposing portion and a supporting portion. The supporting portion is configured to support a first alignment substrate and a second alignment substrate, and the mass transfer method includes the following steps: applying a first acting force to a plurality of target objects, such that the target objects fall on the first alignment substrate; controlling the picking and disposing portion to pick up the target objects from the first alignment substrate; controlling the picking and disposing portion to dispose the target objects being picked up on the second alignment substrate; and applying a second acting force to the target objects on the second alignment substrate, such that an attaching force of the target objects to the second alignment substrate is greater than an attaching force of the target objects to the picking and disposing portion, and the target objects are transferred from the picking and disposing portion to the second alignment substrate.

In certain embodiments of the present invention, the second alignment substrate includes a body and a plurality of slots formed on the body, and at least one of the slots has a cross-section structure in a trapezoid.

In certain embodiments of the present invention, the second alignment substrate includes a body, a plurality of slots formed on the body and a plurality of micro-hole structures, where the acting force applied to the target objects are applied through the micro-hole structures.

In certain embodiments of the present invention, the mass transfer method further includes the following step: performing electrical inspection to the target objects in the slots through the second alignment substrate.

One embodiment of the present invention relates to an alignment substrate, which includes a substrate body, a plurality of slots, a plurality of material receiving portions and a curable magnetic material. The plurality of slots are arranged in the substrate body, and the plurality of slots are respectively provided for a plurality of LED chips to be disposed therein. The plurality of material receiving portions are respectively formed at bottoms of the slots. The curable magnetic material is disposed in the plurality of material receiving portions and is cured to form a magnetic structure, and magnetism of the curable magnetic material corresponds to the magnetism of the LED chips.

In certain embodiments of the present invention, the supporting portion includes a plurality of supporting platforms respectively used to fix the first substrate and the second substrate, and the picking and disposing includes a multi-axis movement control mechanism and a clamping mechanism. The multi-axis movement control mechanism is configured to move in a three-dimensional space under control. The multi-axis movement control mechanism has a first movement mode during movement, and when the multi-axis movement control mechanism moves in the first movement mode, three-dimensional coordinates of the multi-axis movement control mechanism are simultaneously changed. The clamping mechanism is connected to the multi-axis movement mechanism and is driven by the movement of the multi-axis movement control mechanism.

In certain embodiments of the present invention, the supporting portion further includes an adhesive substrate. The adhesive substrate is configured to be fixed on the clamping mechanism and has an adhesive layer configured to face a first direction. When the multi-axis movement control mechanism moves to align with at least one substrate of the first substrate and the second substrate according to the relative position information, the first direction is a direction facing toward the at least one substrate.

In certain embodiments of the present invention, the adhesive substrate has a comb-like structure.

In certain embodiments of the present invention, the curable magnetic material is injected into the material receiving portions in an uncured state, and is then cured.

In certain embodiments of the present invention, the curable magnetic material is a magnetic fluid.

In certain embodiments of the present invention, a composition of the curable magnetic material includes: carbon (C), oxygen (O), and iron (Fe).

In certain embodiments of the present invention, in the composition of the curable magnetic material, the carbon content (C) is 42.8%, the oxygen content (O) is 19.5%, and the iron content (Fe) is 37.7%.

In certain embodiments of the present invention, each of the material receiving portions is a hole or a recess, and corresponds to the lower bottom side of the LED chips.

In certain embodiments of the present invention, when each of the material receiving portions is a hole, the hole is a blind hole or a through hole.

In certain embodiments of the present invention, each of the material receiving portions is disposed with a certain spacing from the inner side wall of the corresponding slot.

In certain embodiments of the present invention, when viewing the substrate body from above, a cross-sectional area of each of the material receiving portions is smaller than a lower bottom area of each of the LED chips.

One embodiment of the present invention relates to an LED chip, which includes: a light emitting layer, a first electrode, a second electrode, a third electrode, an insulating layer, a sacrificial layer and a mass transfer layer. The first electrode and the second electrode are disposed on one side of the light emitting layer, and the third electrode is disposed on the other opposite side of the light emitting layer. The insulating layer is disposed on the same side as the first electrode and the second electrode, and is formed between the first electrode and the second electrode. The sacrificial layer is formed on a surface of the light emitting layer where the third electrode is disposed and extends to the side surfaces of the light emitting layer and the first electrode/the second electrode. The mass transfer layer is formed on the sacrificial layer and the third electrode, and is electrically connected to the third electrode. The mass transfer layer has a cross-sectional structure which is asymmetrical in an up-down direction.

One embodiment of the present invention relates to a display panel, which includes a display substrate, a plurality of LED chips and a plurality of signal lines. The LED chips are disposed on the display substrate. The signal lines are formed on the display substrate and are electrically connected to the LED chips. The display substrate includes a plurality of configuration regions and a plurality of spare regions. The configuration regions are arranged in an array on the display substrate, and the LED chips are respectively disposed in the configuration regions. The spare regions are arranged in an array on the display substrate and are interleaved with at least a portion of the configuration regions, and the spare regions are used to receive the LED chips.

In certain embodiments of the present invention, when one of the spare regions is provided with an LED chip, the LED chip in the one spare region and the LED chips in the adjacent configuration regions are electrically connected to the same signal line.

In certain embodiments of the present invention, when the LED chip in one of the configuration regions is in a defective state, the spare region adjacent to the one configuration region is provided with the LED chip.

In certain embodiments of the present invention, the configuration regions include: a plurality of first configuration regions, provided with the LED chips having a first wavelength; a plurality of second configuration regions, provided with the LED chips having a second wavelength; and a plurality of third configuration regions, provided with the LED chips having a third wavelength. The first configuration regions, the second configuration regions and the third configuration regions are sequentially arranged on the display substrate.

In certain embodiments of the present invention, the spare regions include: a plurality of first spare regions, respectively located between two adjacent ones of the first configuration regions, and adapted to receive the LED chips having the first wavelength; a plurality of second spare regions, respectively located between two adjacent ones of the second configuration regions, and adapted to receive the LED chips having the second wavelength; and a plurality of third spare regions, respectively located between two adjacent ones of the third configuration regions, and adapted to receive LED chips having the third wavelength.

One embodiment of the present invention relates to a mass transfer method, which is applicable to a mass transfer apparatus including a picking and disposing portion and a supporting portion. The supporting portion is configured to support a first substrate, a reorientation substrate, and a second substrate, and the mass transfer method includes the following steps: controlling the picking and disposing portion to pick up the target objects from the first substrate; controlling the picking and disposing portion to dispose the target objects being picked up on the reorientation substrate; moving and flipping the reorientation substrate, such that the target objects face toward the supporting portion; moving a surface of the reorientation substrate adhered with the target objects toward the second substrate, such that the target objects contact the target substrate; and outputting energy such that an attaching force of the target objects to the second substrate is greater than an attaching force of the target objects to the reorientation substrate.

In certain embodiments of the present invention, the second substrate includes a bonding layer, and the bonding layer has a thickness of 1.0 to 5.0 μm.

In certain embodiments of the present invention, the bonding layer has an adhesion force of 400 to 1000 KPa.

In certain embodiments of the present invention, the reorientation substrate includes an adhesive layer, and the adhesive layer is formed by heat-resistant polyester with adhesive materials disposed on two sides thereof.

In certain embodiments of the present invention, a thickness of the heat-resistant polyester of the adhesive layer may be between 17 μm and 33 μm, and a thickness of each of the adhesive materials may be between 14 μm and 26 μm.

In certain embodiments of the present invention, an adhesion force of the adhesive material is between 0.2 N/25 mm and 20.5 N/25 mm.

One embodiment of the present invention relates to a display panel, which includes a display substrate, a plurality of LED chips and a plurality of signal lines. The LED chips are disposed on the display substrate. The signal lines are formed on the display substrate and are electrically connected to the LED chips. The display substrate includes a plurality of pixel configuration regions arranged in an array on the display substrate, and the LED chips are respectively disposed in the pixel configuration regions. Each of the pixel configuration regions includes: a first chip configuration region configured to accommodate two of the LED chips having a first wavelength in each row and column; two second chip configuration regions, respectively configured to accommodate two of the LED chips having a second wavelength in each row and column, where two edges of the first chip configuration region are respectively adjacent to one edge of the two second chip configuration regions; and a third chip configuration region configured to accommodate two of the LED chips having a third wavelength in each row and column, where two edges of the third chip configuration region are respectively adjacent to the other edge of the two second chip configuration regions. The one edge and the other edge of each of the second chip configuration regions are adjacent to each other, and the first chip configuration region and any one of the second chip configuration regions are located on the same imaginary line.

In certain embodiments of the present invention, the display panel further includes: a gamut control portion, electrically connected to the LED chips via the signal lines to adjust the brightness of at least one of the LED chips.

One embodiment of the present invention relates to an electrical inspection apparatus, which includes a substrate and a jig portion. The substrate is used to support a plurality of target objects after mass transfer. The electrical inspection apparatus is used to perform electrical inspection to the target objects. The jig portion is disposed opposite to the substrate. The jig portion includes an upper electrode jig which is transparent. During the electrical inspection, the upper electrode jig is connected to the target objects, and the substrate serves as a lower electrode of the target objects. The upper electrode jig and the lower electrode are powered to generate a voltage difference to drive the target objects to emit light. After the light beams pass through the jig portion, the electrical inspection apparatus performs electrical inspection to the target objects.

In certain embodiments of the present invention, the jig portion further includes a transparent substrate, and the upper electrode jig is disposed on the transparent substrate.

In certain embodiments of the present invention, the upper electrode jig is disposed corresponding to the light emitting layers of the target objects.

In certain embodiments of the present invention, the target objects are vertical micro-LED chips.

In certain embodiments of the present invention, the electrical inspection apparatus further includes an inspection portion, a power supply portion and a control portion. The inspection portion is disposed opposite to the substrate and the jig portion, such that an inspection range covers at least a part of the regions of the substrate and the jig portion. The inspection portion is used to capture images of the substrate and the jig portion. The power supply portion is used to supply voltage and current to the upper electrode jig and the substrate during the electrical inspection. The control portion is coupled to the substrate, the jig portion, the inspection portion and the power supply portion. The control portion is used to control the operation of the inspection portion and the power supply portion.

One embodiment of the present invention relates to an electrical inspection method for an LED chip, which is applicable to an electrical inspection apparatus including a jig portion. The electrical inspection method includes: performing position inspection to the LED chips disposed on the substrate after mass transfer to obtain position information; adjusting an upper electrode jig of the jig portion to corresponding positions of the LED chips according to the position information; supplying voltage and current to the LED chips for a lighting test; during the lighting test, capturing images of the substrate and the jig portion; and analyzing the captured inspection data to determine whether the LED chips are lit.

### BRIEF DESCRIPTION OF THE DRAWINGS

FIG. 1A and FIG. 1B are schematic views of a mass transfer apparatus according to different embodiments of the present invention.

FIG. 2A and FIG. 2B are flowcharts of a mass transfer method according to different embodiments of the present invention.

FIG. 3A to FIG. 3C are schematic views of the configuration of a mass transfer apparatus according to different embodiments of the present invention.

FIG. 4A and FIG. 4B are schematic views of the configuration of an adhesive substrate according to certain embodiments of the present invention.

FIG. 5A to FIG. 5C are schematic views of the flow of a mass transfer apparatus performing mass transfer according to certain embodiments of the present invention.

FIG. 6A to FIG. 6F are schematic views of the flow of a mass transfer apparatus performing mass transfer according to certain embodiments of the present invention.

FIG. 7A to FIG. 7L are schematic views of the flow of a mass transfer apparatus performing mass transfer according to certain embodiments of the present invention.

FIG. 8A to FIG. 8K are schematic views of the flow of a mass transfer apparatus performing mass transfer according to certain embodiments of the present invention.

FIG. 9A to FIG. 9G are schematic views of the flow of a mass transfer apparatus performing mass transfer according to certain embodiments of the present invention.

FIG. 10A to FIG. 10C are schematic views of the structural configuration of the alignment substrate according to different embodiments of the present invention.

FIG. 11A to FIG. 11H are schematic views of the cross-sectional structure of the alignment substrate according to different embodiments of the present invention.

FIG. 12 is a schematic view of the structural configuration of an LED chip according to certain embodiments of the present invention.

FIG. 13A to FIG. 13I are schematic views of the manufacturing process of the LED chips according to certain embodiments of the present invention.

FIG. 14A to FIG. 14D are schematic views of the structural configuration of the display panel according to certain embodiments of the present invention.

FIG. 15A to FIG. 15C are schematic views of the structural configuration of the display panel according to certain embodiments of the present invention.

FIG. 16 is a schematic view of an electrical inspection apparatus according to one embodiment of the present invention.

FIG. 17A and FIG. 17B are schematic views of the structure of the jig portion according to one embodiment of the present invention.

FIG. 18A to FIG. 18C are schematic views of the inspection process of the electrical inspection apparatus according to different embodiments of the present invention.

FIG. 19 is a flowchart of the electrical inspection method according to one embodiment of the present invention.

### DETAILED DESCRIPTION

In order to make the above-mentioned objectives, features, and advantages of the present technical solution more clear and easily understood, detailed descriptions of specific embodiments of the proposed technical solution are provided below in conjunction with the accompanying drawings. The following descriptions of various embodiments of the present invention are illustrative and are not intended to represent all embodiments of the present invention or to limit the present invention to specific embodiments. All other embodiments obtained by those of ordinary skill in the art based on the embodiments in the present invention without inventive effort shall fall within the scope of protection of this disclosure.

It should be noted that, when a component is referred to as being “disposed on” another component, it can be directly on the other component or there may be intervening components. When a component is considered “connected to” another component, it can be directly connected to the other component or there may be intervening components at the same time. The terms “vertical,” “horizontal,” “left,” “right,” “up,” “down” and similar expressions as used herein are only for indicating relative positional relationships based on the drawings, and do not limit the components using the terms to be implemented only in the manner indicated. When the absolute position of the described object changes, the description of the relative position may also change accordingly.

The terms “substantially,” “generally,” “approximately,” and the like in this disclosure describe the error range implied by possible unexpected influences and deviations in the process or material selection. The error range may include a range of variations that do not significantly change the material structure, configuration, characteristics, and effects, such as a 0% to 10% deviation range, where the error range is clear to those skilled in the art. For example, if it is described that “two objects are substantially parallel,” and it is actually observed that there is a slight difference in height between the two objects, but this difference is negligible relative to the size of the objects themselves (for example, less than 10%) and does not affect the effect, the observed relative configuration between the two objects will still be interpreted as being within the “approximately parallel” range described herein.

All descriptions related to specific numerical values in this disclosure, although not directly described, include the meaning of “approximately” or “substantially,” that is, these specific numerical values will cover possible numerical error ranges, thereby representing possible unexpected influences and deviations in process or material selection. The numerical error range may include numerical changes that do not significantly change the material structure, characteristics, and effects, such as a 0% to 10% deviation range. This error range is clear to those with ordinary skill in the art.

Unless defined otherwise, all technical and scientific terms used herein have the same meaning as commonly understood by those skilled in the art to which the present invention pertains. The terms used in the specification of the present invention herein are for the purpose of describing specific embodiments only, and are not intended to limit the present invention. The term “and/or” as used herein includes any and all combinations of one or more of the associated listed items.

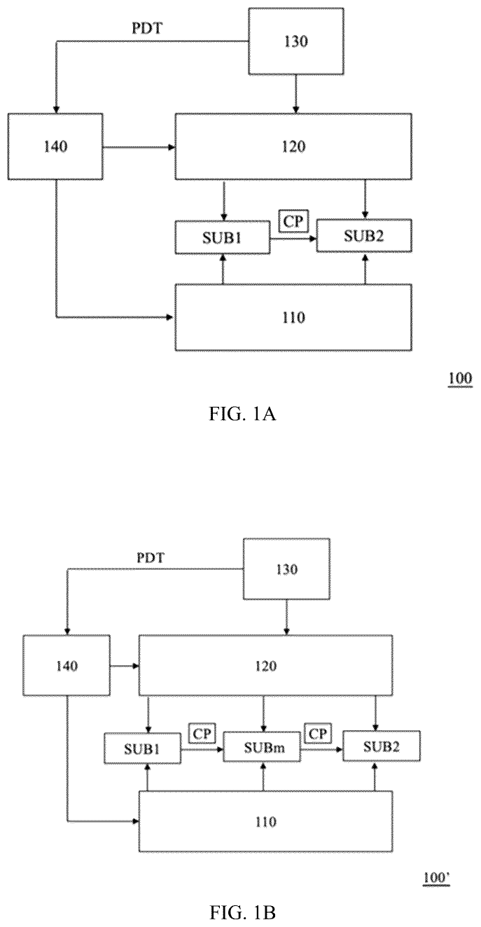

FIG. 1A is a schematic view of a mass transfer apparatus according to certain embodiments of the present invention. Referring to FIG. 1A, the present embodiment relates to a mass transfer apparatus 100, which is used to transfer at least one target object CP on a first substrate SUB1 to a second substrate SUB2. The target object CP may be, for example, a small-sized electronic component such as an LED chip, and more specifically may be, for example, a mini-LED or a micro-LED, and the present invention is not limited thereto. In other embodiments, the mass transfer apparatus 100 may also be used to transfer other types of target objects CP in addition to the LED chips. In certain embodiments, the first substrate SUB1 may be a source substrate carrying the target objects CP, an alignment substrate for adjusting the arrangement of the target objects CP, or a reorientation substrate (an intermediate substrate) for changing the configuration direction of the target objects CP, and the second substrate SUB2 may be the alignment substrate, the intermediate substrate, or a target substrate for carrying the transferred target objects CP. In other words, the mass transfer apparatus 100 of the present embodiment may perform transfer between any one of the above-mentioned types of the first substrate SUB1 and any one of the above-mentioned types of the second substrate SUB2, e.g., performing transfer of the target objects CP between a source substrate and a target substrate, between a source substrate and an alignment substrate, between a source substrate and an intermediate substrate, between an alignment substrate and an intermediate substrate, between an alignment substrate and a target substrate, or between an intermediate substrate and a target substrate, and the present invention is not limited thereto. In certain embodiments, in terms of the material and structure thereof, the target substrate may be, for example, a semiconductor substrate (e.g., a silicon substrate), a photovoltaic conversion substrate (e.g., an organic photovoltaic conversion layer), a semiconductor on insulator (SOI) substrate, a glass substrate or a flexible substrate, but the present invention is not limited thereto. In terms of the function and purpose thereof, the target substrate may be, for example, a display substrate.

In certain embodiments, the semiconductor substrate may also be: an elemental semiconductor, including germanium; a compound semiconductor, including gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor, including a silicon germanium (SiGe) alloy; or a combination thereof.

In certain embodiments, the SOI substrate may include a base substrate, a buried oxide (BOX) layer disposed on the base substrate, and a semiconductor layer disposed on the buried oxide layer.

In certain embodiments, the glass substrate may include, for example, a plurality of thin film transistors (TFTs), and the thin film transistors may be N-type or P-type transistors.

In certain embodiments, the flexible substrate may be formed of materials such as polyimide (PI) or polyethylene terephthalate (PET).

The mass transfer apparatus 100 of the present embodiment includes a supporting portion 110, a picking and disposing portion 120, an inspection portion 130 and a control portion 140. In the present embodiment, the supporting portion 110 is used to fix the first substrate SUB1 and/or the second substrate SUB2, and is used to adjust the positions of the first substrate SUB1 and/or the second substrate SUB2.

The picking and disposing portion 120 is disposed opposite to the supporting portion 110 and is used to pick up the target objects CP from the first substrate SUB1 under control, or to dispose the target objects CP being picked up on the second substrate SUB2. In certain embodiments, the picking and disposing portion 120 may include an adhesive substrate (not shown, which will be further described with examples in subsequent embodiments) and a clamping mechanism. The adhesive substrate may be a rigid substrate, and one surface thereof is configured to have an adhesive force (or being referred to as an adhesive surface). The clamping mechanism may be used to fix the adhesive substrate, and when the picking and disposing portion 120 picks up the objects from the first substrate SUB1, it is controlled to drive the adhesive substrate to move toward the first substrate SUB1, such that the adhesive surface of the adhesive substrate contacts the target objects CP on the first substrate SUB1. Then, the clamping mechanism may drive the adhesive substrate away from the first substrate SUB1 and return to a predetermined position (which may also be other positions not contacting the first substrate SUB1). At this time, the target objects CP on the first substrate SUB1 will adhere to the adhesive substrate and leave the first substrate SUB1 due to the adhesive force on the adhesive substrate, thus completing the action of the picking and disposing portion 120 picking up the target objects CP from the first substrate SUB1.

The inspection portion 130 is disposed opposite to the supporting portion 110 and the picking and disposing portion 120, such that the inspection range may cover at least a part of the regions of the supporting portion 110 and the picking and disposing portion 120. The inspection portion 130 is used to inspect the relative positions of the first substrate SUB1 and/or the second substrate SUB2 disposed on the supporting portion 110 and the picking and disposing portion 120, so as to generate relative position information PDT for controlling the movements of the supporting portion 110 and the picking and disposing portion 120. In certain embodiments, the inspection portion 130 may include one or more image capturing devices, and the image capturing devices may be, for example, one of an optical microscope, a charge-coupled device (CCD) image sensor, a complementary metal-oxide semiconductor (CMOS) image sensor, and an industrial camera, or a combination thereof, and the present invention is not limited thereto.

The control portion 140 is coupled to the supporting portion 110, the picking and disposing portion 120 and the inspection portion 130, and is used to control operations of the supporting portion 110 and the picking and disposing portion 120 according to the relative position information PDT. In certain embodiments, the control portion 140 may be implemented by hardware, firmware, or software, and is not necessarily disposed inside the machine of the mass transfer apparatus 100. For example, the control portion 140 may be implemented by an external computer, and the external computer may transmit signals with each module in the mass transfer apparatus 100 through a specific transmission interface to achieve control.

In the present embodiment, when the picking and disposing portion 120 disposes the target objects CP on the second substrate SUB2, the supporting portion 110 is controlled to output energy to the second substrate SUB2, such that an attaching force of the target objects CP to the second substrate SUB2 is greater than an attaching force of the target objects CP to the picking and disposing portion 120, and the target objects CP may be transferred from the picking and disposing portion 120 to the second substrate SUB2. The action of the supporting portion 110 outputting energy to the second substrate SUB2 may be, for example, heating the second substrate SUB2, such that the attaching force between the target objects CP and the picking and disposing portion 120 is reduced; or applying a contact or non-contact acting force to the second substrate SUB2 to increase the attaching force of the target objects CP to the second substrate SUB2.

Specifically, through the configuration of the above-mentioned mass transfer apparatus 100, it is possible to transfer all (or at least a part of) the target objects on the first substrate SUB1 to the second substrate SUB2 in a single action, without the need to pick and dispose the individual target objects CP separately, thereby greatly reducing the time required for the mass transfer. On the other hand, the application of the above-mentioned mass transfer apparatus 100 may arrange the target objects CP to meet the intervals and/or quantities of the final target transfer substrate through an alignment substrate during the transfer process, such that the mass transfer apparatus 100 may transfer all the target objects CP on the alignment substrate to the target substrate at one time, effectively improving the transfer efficiency.

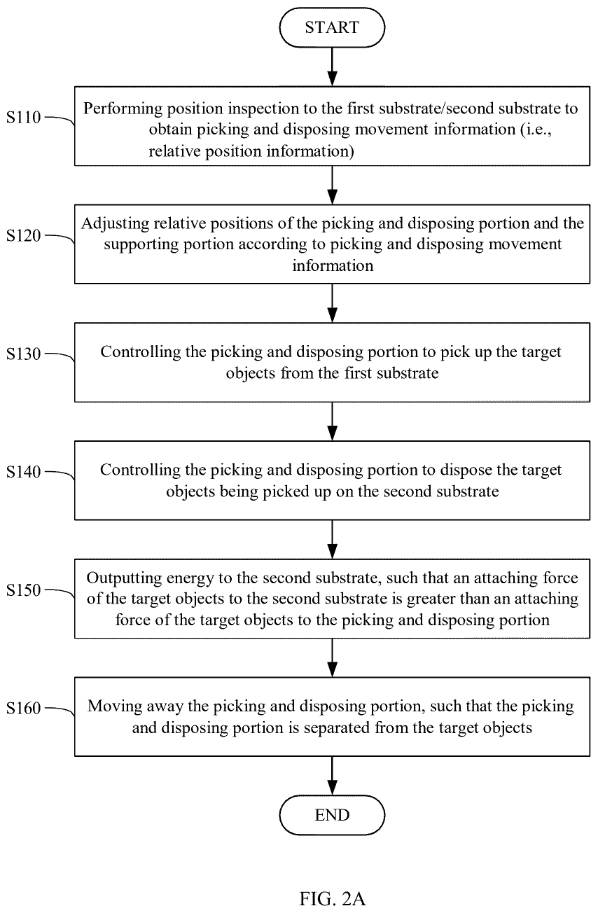

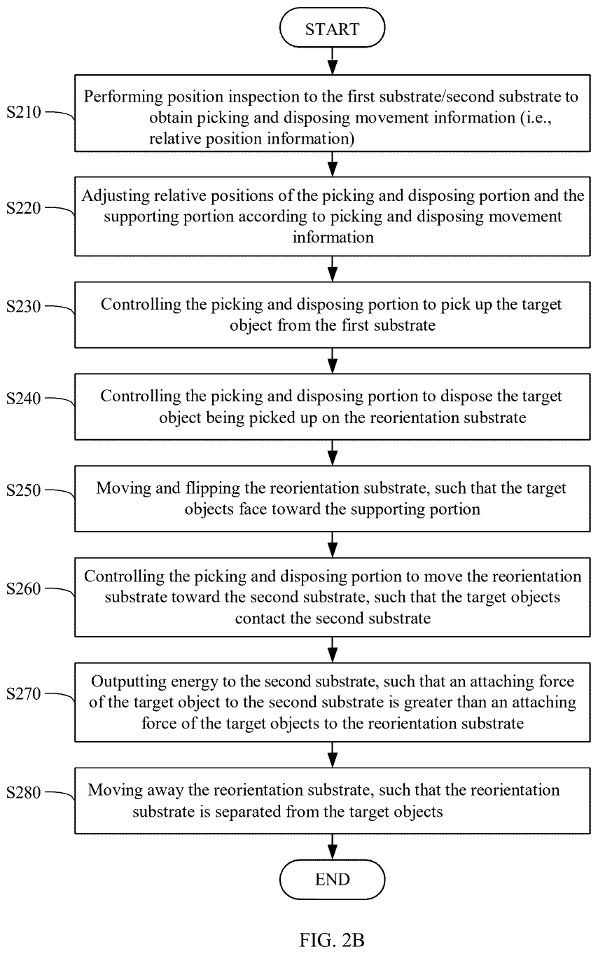

The mass transfer apparatus 100 may be operated by a mass transfer method as shown in FIG. 2A, where FIG. 2A is a flowchart of a mass transfer method according to one embodiment of the present invention. Referring to FIG. 1A and FIG. 2A simultaneously, the mass transfer method of the present embodiment includes: performing position inspection to the first substrate SUB1/second substrate SUB2 to obtain picking and disposing movement information (i.e., relative position information) PDT (step S110); adjusting the relative positions of the picking and disposing portion 120 and the supporting portion 110 according to the relative position information PDT (step S120); controlling the picking and disposing portion 120 to pick up the target objects CP from the first substrate SUB1 (step S130); controlling the picking and disposing portion 120 to dispose the target objects CP being picked up on the second substrate SUB2 (step S140); outputting energy to the second substrate SUB2 such that an attaching force of the target objects CP to the second substrate SUB2 is greater than an attaching force of the target objects CP to the picking and disposing portion 120 (step S150); and moving away the picking and disposing portion 120, such that the picking and disposing portion 120 is separated from the target objects CP (step S160).

Specifically, before performing the above steps, the adhesive substrate (not shown) of the picking and disposing portion 120 may be firstly fixed on the clamping mechanism (not shown), and in the step S110, the alignment marks of the first substrate SUB1/second substrate SUB2 and/or the distance between the picking and disposing portion 120 and the first substrate SUB1/second substrate SUB2 are inspected by the inspection portion 130 to confirm the relative positional relationships between the adhesive substrate and the first substrate SUB1/second substrate SUB2, and the relative position information PDT is generated accordingly. The alignment marks may be, for example, a dummy region on the first substrate SUB1/second substrate SUB2 or a specific pattern or object in the dummy region, and the present invention is not limited thereto. The relative position information PDT may include, for example, the relative displacement amount of the adhesive substrate and the first substrate SUB1/second substrate SUB2 on a plane, and the distance between the adhesive substrate and the first substrate SUB1/second substrate SUB2, but the present invention is not limited thereto.

For example, the inspection portion 130 may obtain the relative displacement amount of the adhesive substrate and the first substrate SUB1/second substrate SUB2 on a plane by inspecting the adhesive substrate and the alignment marks of the first substrate SUB1/second substrate SUB2, and obtain the distance information between the adhesive substrate and the first substrate SUB1/second substrate SUB2 by recording the displacement amount data of the picking and disposing portion 120 moving to contact the first substrate SUB1/second substrate SUB2.

Then, in the step S120, the control portion 140 may control the supporting portion 110 and/or the picking and disposing portion 120 to move in two-dimensional or three-dimensional directions according to the relative position information PDT, such that the adhesive substrate of the picking and disposing portion 120 is aligned with the first substrate SUB1 on the supporting portion 110 (i.e., pre-alignment) before performing picking and disposing. For example, the control portion 140 may control the supporting portion 110 and the picking and disposing portion 120 to move respectively at a fixed interval, such that the region on the first substrate SUB1 where the target objects CP are disposed faces right toward the adhesive substrate of the picking and disposing portion 120.

After the pre-alignment is completed, in the step S130, the control portion 140 controls the picking and disposing portion 120 to move toward the first substrate SUB1 on the supporting portion 110 until the adhesive surface of the adhesive substrate contacts the target objects CP on the first substrate SUB1, such that the adhesive force of the adhesive substrate acts on the target object CP to be transferred. Then, the control portion 140 controls the picking and disposing portion 120 to move away from the first substrate SUB1, such that the target objects CP affected by the adhesive force move away from the first substrate SUB1 with the adhesive substrate, thus completing the action of picking up the target objects CP from the first substrate SUB1 by the picking and disposing portion 120.

After picking up the target objects CP, in the step S140, the control portion 140 further controls the picking and disposing portion 120 to move toward the second substrate SUB2 on the supporting portion 110, such that the target objects CP contact the second substrate SUB2. When the target objects CP are disposed on the second substrate SUB2, the control portion 110 further controls the supporting portion 110 to output energy to the second substrate SUB2, and the output energy acts on the adhesive substrate and/or the second substrate SUB2, such that the attaching force provided by the second substrate SUB2 to the target objects CP is increased and/or the attaching force provided by the adhesive substrate to the target objects CP is reduced, and the target objects CP are transferred from the adhesive substrate to the second substrate SUB2.

In certain embodiments, a bonding layer may be disposed on a surface of the second substrate SUB2 in contact with the target objects CP, and the bonding layer may be implemented by a material that cures when being heated, such as the conductive silver paste. In the step S150, the supporting portion 110 may heat the second substrate SUB2 when the target objects CP are disposed on the second substrate SUB2, so as to cure the bonding layer in contact with the target objects CP, thereby increasing the attaching force of the target objects CP to the second substrate SUB2.

In certain embodiments, the second substrate SUB2, which serves as an alignment substrate, may be provided with micro-hole structures corresponding to the target objects. In the step S150, when the target objects CP are disposed on the second substrate SUB2, the supporting portion 110 may extract the air in the micro-hole structures to establish a vacuum suction force between the second substrate SUB2 and each target object CP, thereby increasing the attaching force of the target objects CP to the second substrate SUB2. The structural configuration of this part will be further described in the subsequent embodiments of the alignment substrate.

In certain embodiments, the second substrate SUB2, which serves as an alignment substrate, includes a magnetic structure, and the magnetic structure may be controlled to generate a magnetic force with a specific direction, such that the target objects CP may fall into the slots of the alignment substrate in the same direction in response to the magnetic force. The structural configuration of this part will be further described in the subsequent embodiments of the alignment substrate.

FIG. 1B is a schematic view of a mass transfer apparatus according to other embodiments of the present invention. Referring to FIG. 1B, the mass transfer apparatus 100′ of the present embodiment is substantially identical to the mass transfer apparatus 100 of the embodiment in FIG. 1A, both including a supporting portion 110, a picking and disposing portion 120, an inspection portion 130 and a control portion 140. Reference to the related descriptions of each component may be made to the embodiment of FIG. 1A as described above, and is not further reiterated herein.

The main difference between the present embodiment and the previous embodiment exists in that the mass transfer apparatus 100′ of the present embodiment may include one or more intermediate transfer processes in the process of transferring the target objects CP on the first substrate SUB1 to the second substrate SUB2. For example, the mass transfer apparatus 100′ of the present embodiment may firstly use the picking and disposing portion 120 to transfer the target objects CP of the source substrate to the alignment substrate for alignment, and then to transfer the target objects CP being aligned to the reorientation substrate. After the reorientation of the target objects CP by the reorientation substrate, the target objects CP are transferred from the reorientation substrate to the target substrate. In other words, in the present embodiment, the predetermined direction in which the target objects CP are disposed on the alignment substrate is opposite to the predetermined direction in which the target objects CP are disposed on the reorientation substrate. For example, the target objects CP may have a first side and a second side opposite to the first side. The predetermined direction of the target objects CP in the alignment substrate may be, for example, with the first side facing upward and the second side facing the bottom surface of the slots of the alignment substrate; and the predetermined direction of the target objects CP in the reorientation substrate may be, for example, with the second side facing upward and the first side facing the substrate body. However, the present invention is not limited thereto.

The mass transfer apparatus 100′ may be operated by the mass transfer method as shown in FIG. 2B, where FIG. 2B is a flowchart of a mass transfer method according to other embodiments of the present invention. Referring to FIG. 1B and FIG. 2B simultaneously, the mass transfer method of the present embodiment includes: performing position inspection on the first substrate SUB1/reorientation substrate SUBm/second substrate SUB2 to obtain picking and disposing movement information (i.e., relative position information) PDT (step S210); adjusting the relative positions of the picking and disposing portion 120 and the supporting portion 110 according to the relative position information PDT (step S220); controlling the picking and disposing portion 120 to pick up the target object CP from the first substrate SUB1 (step S230); controlling the picking and disposing portion 120 to dispose the target objects CP being picked up on the reorientation substrate SUBm (step S240); moving and flipping the reorientation substrate SUBm such that the target objects CP face toward the supporting portion (step S250); controlling the picking and disposing portion 120 to move the reorientation substrate SUBm toward the second substrate SUB2, such that the target objects CP contact the second substrate SUB2 (step S260); outputting energy to the second substrate SUB2 such that an attaching force of the target objects CP to the second substrate SUB2 is greater than an attaching force of the target objects CP to the reorientation substrate SUBm (step S270); and removing the reorientation substrate SUBm, such that the reorientation substrate SUBm is separated from the target objects CP (step S280).

Specifically, the steps S210 to S230 as described above may refer to the steps S110 to S130 of the embodiment of FIG. 2A, and are not further reiterated herein. In the present embodiment, the first substrate SUB1 may be, for example, an alignment substrate for adjusting the arrangement of the target objects CP; the second substrate may be, for example, a target substrate for supporting the target objects CP after being transferred; and the target objects CP may be, for example, LED chips.

In the step S240, the control portion 140 controls the picking and disposing portion 120 to move toward the reorientation substrate SUBm, which is adhesive, on the supporting portion 110, such that the target objects CP contact the reorientation substrate SUBm. In the present embodiment, one side of the reorientation substrate SUBm for disposing the target objects CP may have a certain adhesive force, and the adhesive force of the reorientation substrate SUBm is greater than the adhesive force of the adhesive substrate (not shown) of the picking and disposing portion 120, such that when the target objects CP are disposed on the reorientation substrate SUBm and the adhesive substrate moves away, the target objects CP are removed from the adhesive substrate and remain on the reorientation substrate SUBm.

In the step S250, the mass transfer apparatus 100′ may control the picking and disposing portion 120 to flip the reorientation substrate SUBm through the control portion 140, or by other components, and the present invention is not limited thereto.

In the step S260, the control portion 140 further controls the reorientation substrate SUBm with the target objects CP to move toward the second substrate SUB2 on the supporting portion 110, such that the target objects CP contact the second substrate SUB2. When the target objects CP are disposed on the second substrate SUB2, in the step S270, the control portion 140 further controls the supporting portion 110 to output energy to the second substrate SUB2, and the output energy acts on the reorientation substrate SUBm and/or the second substrate SUB2, such that the attaching force provided by the second substrate SUB2 to the target objects CP is increased and/or the attaching force provided by the reorientation substrate SUBm to the target objects CP is reduced, and the target objects CP may be transferred from the reorientation substrate SUBm to the second substrate SUB2.

In the step S280, the control portion 140 further controls the picking and disposing portion 120 to remove the reorientation substrate SUBm, such that the reorientation substrate SUBm is separated from the target objects CP. After the target objects CP are transferred to the second substrate SUB2, the reorientation substrate SUBm is moved away from the second substrate SUB2, such that the reorientation substrate SUBm is separated from the target objects CP attached to the second substrate SUB2.

Compared with the mass transfer process of FIG. 1A, the present embodiment may further optimize the arrangement and/or configuration direction of the target objects CP to a state suitable for transfer, thereby improving the transfer yield and efficiency.

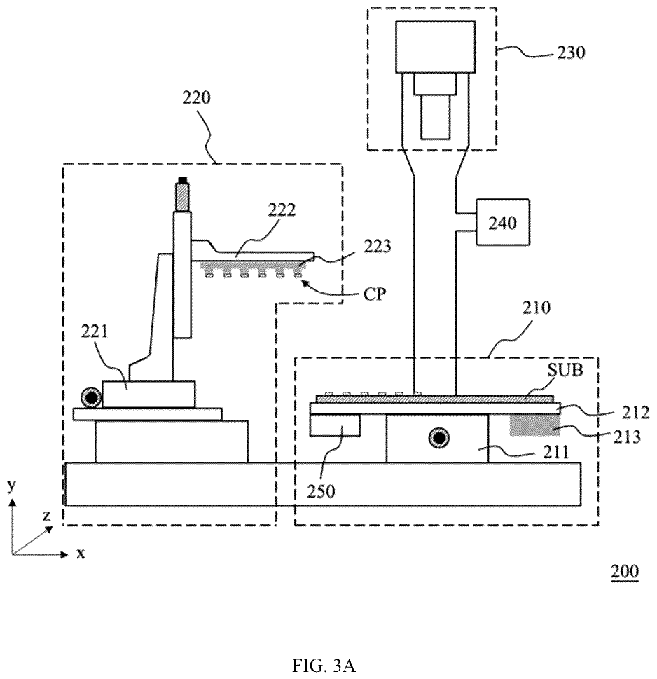

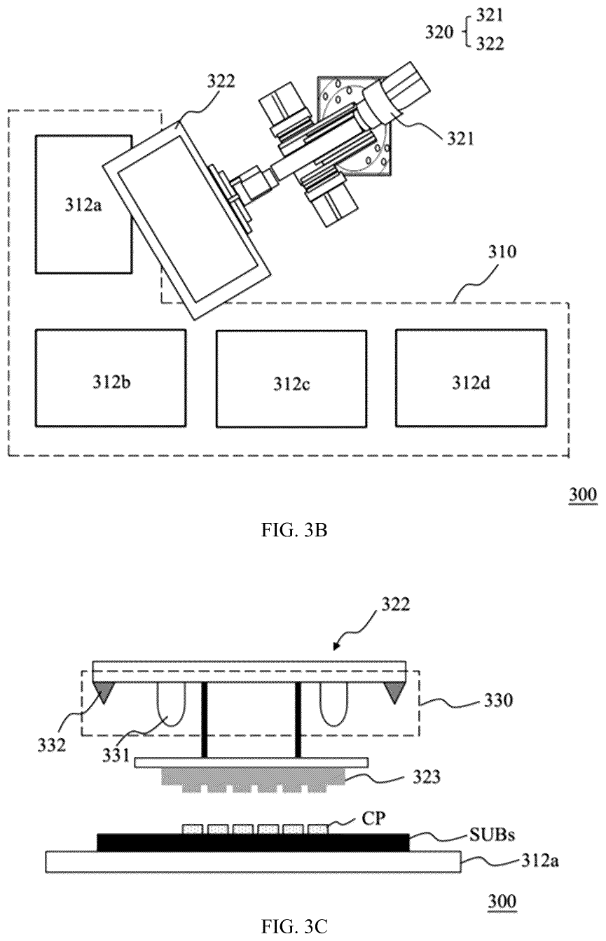

Specific exemplary embodiments of the mass transfer apparatus are described using the structures shown in FIGS. 3A to 3C. FIGS. 3A to 3C are schematic views of the configuration of the mass transfer apparatus according to different embodiments of the present invention. Referring firstly to FIG. 3A, the mass transfer apparatus 200 of the present embodiment includes a supporting portion 210, a picking and disposing portion 220, an inspection portion 230 and a control portion 240. The supporting portion 210 includes a first movement control mechanism 211, a supporting platform 212 and a heating component 213. The picking and disposing portion 220 includes a second movement control mechanism 221, a clamping mechanism 222 and an adhesive substrate 223. The inspection portion 230 of the present embodiment includes a CCD sensor, and the target objects CP to be transferred are, for example, LED chips (hereinafter described as “LED chips CP”), but the present invention is not limited thereto.

Specifically, in the supporting portion 210, the supporting platform 212 is disposed on the first movement control mechanism 211 and is used to support the substrate SUB (which may be a substrate to be transferred or a target substrate). Although only a single supporting platform 212 is shown in the figure as an example, the present invention is not limited thereto. In certain embodiments, the supporting portion 210 may also include a plurality of supporting platforms respectively for supporting a substrate to be transferred (such as the aforementioned first substrate SUB1 or reorientation substrate SUBm) and a target substrate (such as the aforementioned second substrate SUB2). This part will be further described in subsequent embodiments.

The first movement control mechanism 211 may be controlled by the control portion 240 or manually to drive the supporting platform 212 to move in the x-z plane (which may be translation or rotation). The heating component 213 is in contact with the supporting platform 212 and is controlled by the control portion 240 to heat the supporting platform 212, such that heat may be transferred to the substrate SUB through the supporting platform 212.

In the picking and disposing portion 220, the clamping mechanism 222 is disposed on the second movement control mechanism 221 and is used to fix the adhesive substrate 223, such that the adhesive substrate 223 is substantially parallel to the supporting platform 212. The clamping mechanism 222 may fix the adhesive substrate 223 by engaging the adhesive substrate 223 with a specific structural configuration, or by adsorption or adhesion to fix the adhesive substrate 223 on the clamping mechanism 222.

The second movement control mechanism 221 may be configured on the same x-z plane as the first movement control mechanism 211, and may be controlled by the control portion 240 or manually to drive the clamping mechanism 222 and the adhesive substrate 223 to move in the x-z plane. In other words, by controlling the first movement control mechanism 211 and the second movement control mechanism 221, the substrate SUB and the adhesive substrate 223 may be relatively displaced.

The clamping mechanism 222 may also be controlled by the control portion 240 or manually to move on the y-axis perpendicular to the x-z plane, such that the adhesive substrate 223 may be driven to approach or move away from the supporting platform 212. In other words, the clamping mechanism 222 may control the adhesive substrate to move in three-dimensional directions through the configuration of the second movement control mechanism 221 and the clamping mechanism 222.

The adhesive substrate 223 may include a rigid layer and an adhesive layer disposed on one side of the rigid layer. The rigid layer may be implemented by, for example, a glass substrate, and the adhesive layer may be implemented by, for example, a polydimethylsiloxane (PDMS) film. In addition, the adhesive layer of the adhesive substrate 223 may be configured as a comb-like structure as shown in FIG. 3A (i.e., having protrusions arranged at a fixed interval), and the protrusion portions may be used to contact the LED chips CP on the substrate SUB, but the adhesive substrate 223 of the present invention is not limited to this structure.

The CCD sensor of the inspection portion 230 is configured to capture images in the direction facing toward the supporting platform 212, such that when the substrate SUB is disposed on the supporting platform 212, the substrate SUB is located within the image sensing range of the CCD sensor. The image information captured by the CCD sensor is transmitted to the control portion 240 as the relative position information PDT.

In certain embodiments, the mass transfer apparatus 100/200 may further include an alignment actuation portion, which is described by the alignment actuation portion 250 as shown in FIG. 3A. The alignment actuation portion 250 may be disposed on the supporting portion 210 to apply a force to the substrate SUB on the supporting portion 210 and the LED chips CP on the substrate SUB, such that the LED chips CP may be neatly arranged to corresponding positions on the substrate SUB. In the present embodiment, the alignment actuation portion 250 is disposed, for example, at the bottom of the supporting platform 212, and when the alignment actuation portion 250 acts, the acting force is applied to the substrate SUB through the supporting platform 212, but the present invention is not limited thereto.

Specifically, when the alignment substrate is placed on the supporting platform 212, the LED chips CP may be scattered on the alignment substrate without falling into the corresponding slots. The alignment actuation portion 250 may provide a force in this case, such that the LED chips CP fall into the corresponding slots. The acting force provided by the alignment actuation portion 250 may be, for example, vibration, vacuum suction, etc. For example, in the example where the alignment actuation portion 250 provides vibration as the acting force, the alignment actuation portion 250 may be, for example, a plurality of vibration mechanisms (such as voice coil motors), which may provide multi-dimensional vibration forces such that the LED chips CP scattered on the alignment substrate fall into the slots.

In certain embodiments, the alignment actuation portion 250 may include, for example, at least three vibration mechanisms, where one of the three vibration mechanisms causes vibration in a first direction, another one of the three vibration mechanisms causes vibration in a second direction, and the remaining vibration mechanism causes vibration in a third direction. Any one of the above-mentioned first to third directions is substantially parallel to the normal direction of the plane formed by the other two directions. For example, the three vibration mechanisms may be, for example, a first vibration mechanism (not shown), a second vibration mechanism (not shown) and a third vibration mechanism (not shown), where the first vibration mechanism causes up-down vibration, the second vibration mechanism causes left-right vibration, and the third vibration mechanism causes front-rear vibration. In this way, multi-dimensional vibration may more easily make the LED chips CP be vibrated into the slots of the alignment substrate.

In certain embodiments, the supporting platform 212 may also be provided with a plurality of recesses in communication to the alignment actuation portion 250, where the alignment actuation portion 250 may adsorb the substrate SUB and/or the LED chips CP on the substrate SUB onto the supporting platform 212 by evacuating the recesses of the supporting platform 212.

In certain embodiments, the alignment actuation portion 250 may include, for example, an electromagnetic control module (not shown), which may be used to supply power to the electromagnetic generating components in the alignment substrate, such that each slot of the alignment substrate generates a directional magnetic force during the alignment process, and the LED chips CP provided with magnetic components fall into the slots of the alignment substrate in the same direction.

FIGS. 3B and 3C are specific exemplary embodiments of the mass transfer apparatus according to other embodiments of the present invention. FIG. 3B is a top view of the mass transfer apparatus 300, and FIG. 3C is a partial side view of the mass transfer apparatus 300. Referring to FIGS. 3B and 3C simultaneously, the mass transfer apparatus 300 of the present embodiment includes a supporting portion 310, a picking and disposing portion 320, an inspection portion 330 and a control portion (not shown). The supporting portion 310 includes a plurality of supporting platforms 312a to 312d; the picking and disposing portion 320 includes a multi-axis movement control mechanism 321, a clamping mechanism 322 and an adhesive substrate 323; and the inspection portion 330 includes a CCD sensor 331.

Specifically, in the supporting portion 310, the supporting platforms 312a to 312d are fixedly disposed on a base and are respectively used to support the substrate to be transferred (such as the aforementioned first substrate SUB1 or reorientation substrate SUBm) and the target substrate (such as the aforementioned second substrate SUB2).

In the picking and disposing portion 320, the clamping mechanism 322 is disposed on the multi-axis movement control mechanism 321 and is used to fix the adhesive substrate 323, such that the adhesive substrate 323 is substantially parallel to the supporting platforms 312a to 312d. The clamping mechanism 322 may fix the adhesive substrate 323 by engaging the adhesive substrate 323 with a specific structural configuration, or by adsorption or adhesion to fix the adhesive substrate 323 on the clamping mechanism 322.

The multi-axis movement control mechanism 321 may be configured on the base (which may be the same as or different from the base of the supporting platforms 312a to 312d), and may respond to the displacement information of the control portion to drive the clamping mechanism 322 and the adhesive substrate 323 to move in the three-dimensional space. In other words, in addition to moving on the x-z plane, the multi-axis movement control mechanism 321 may also move on the y-axis perpendicular to the x-z plane. Compared with the second movement control mechanism 221 of the picking and disposing portion 220 in FIG. 3A, the multi-axis movement control mechanism 321 may perform displacement between any coordinates in the three-dimensional coordinate system, that is, when it moves, it may drive the clamping mechanism 322 to move and position along a non-linear trajectory.

In other words, the adhesive substrate 323 driven by the clamping mechanism 322 may be displaced in a straight line between any coordinate points in the three-dimensional space, without being limited to firstly displacing on the x-z plane and then displacing on the y-axis, which may further shorten the picking and disposing time.

On the other hand, because the multi-axis movement control mechanism 321 may move arbitrarily on the three-dimensional spatial coordinate points, it may more easily adjust/correct the tilt angle of the clamping mechanism 322 and the adhesive substrate 323, such that the picking and disposing portion 320 may have a better picking and disposing success rate during picking and disposing.

The configuration of the adhesive substrate 323 is similar to that of the adhesive substrate 223 in the embodiment of FIG. 3A as described above. Therefore, reference for the relevant parts may be made to the content of the above-mentioned embodiment, and is not further reiterated herein.

In the inspection portion 330, the CCD sensor 331 is configured to face toward the supporting portion 310, such that the multi-axis movement control mechanism 321, when moving to the corresponding supporting platforms 312a to 312d, may capture images of the substrates disposed on the supporting platforms 312a to 312d. The image information captured by the CCD sensor 331 is transmitted to the control portion as the relative position information PDT, such that the control portion controls the multi-axis movement control mechanism 321 to drive the clamping mechanism 322 and the adhesive substrate 323 to align with the substrates on the supporting platforms 312a to 312d based on the relative position information PDT, and to perform picking and disposing actions after the alignment is completed.

In certain embodiments, the substrates disposed on the supporting platforms 312a to 312d may be provided with alignment marks. The multi-axis movement control mechanism 321 may drive the clamping mechanism 322 and the adhesive substrate 323 to move to a position aligned with the alignment marks, such that the adhesive substrate 323 is aligned with the substrate position.

In certain embodiments, the inspection portion 330 may further include a height sensor 332, which may be used to sense the distance from the clamping mechanism 322/adhesive substrate 323 to the supporting platforms 312a to 312d or the substrates thereon, and to transmit the distance information to the control portion, such that the control portion may control the displacement of the multi-axis movement control mechanism 321 on the z-axis according to the distance information, thereby achieving picking and disposing actions with higher precision.

In certain embodiments, the mass transfer apparatus 300 may further include an alignment actuation portion (not shown) as in the previous embodiment. The alignment actuation portion may be disposed, for example, on one or more of the supporting platforms 312a to 312d, and may apply acting forces to the substrates on the corresponding supporting platforms 312a to 312d and the LED chips CP thereon, such that the LED chips CP may be neatly arranged to corresponding positions on the substrates. Reference for the relevant descriptions of the alignment actuation portion may be made to the content of the above-mentioned embodiment, and is not further reiterated herein.

In the present embodiment, the substrates disposed on the supporting platforms 312a to 312d may be, for example, a source substrate, an alignment substrate, a reorientation substrate and a target substrate, respectively.

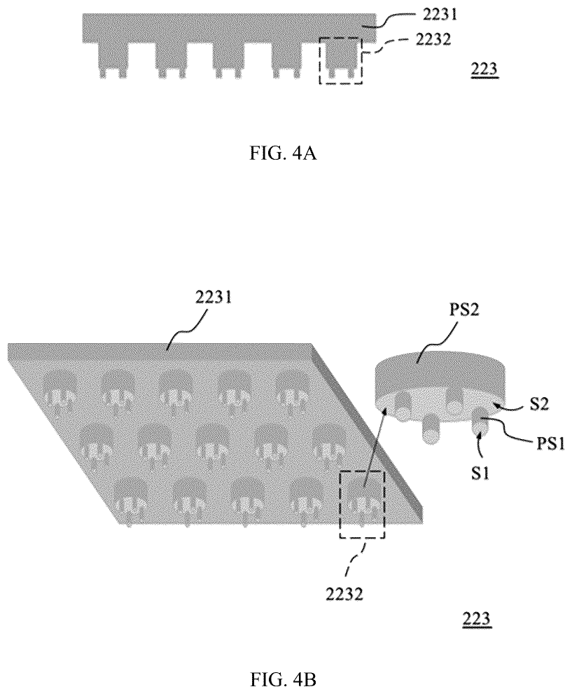

The specific structure of the adhesive substrate 223 is further described below. In the mass transfer process, the use of the structure of the adhesive substrate 223 of the present invention may improve the success rate of picking and disposing the LED chips CP. FIG. 4A is a schematic view of the cross-section of the adhesive substrate structure according to one embodiment of the present invention, and FIG. 4B is a schematic side view of the adhesive substrate structure according to one embodiment of the present invention. Referring to FIGS. 4A and 4B, the adhesive substrate 223 of the present embodiment includes a rigid layer 2231 and an adhesive layer 2232.

The adhesive layer 2232 includes one or more first protruding structures PS1 and second protruding structures PS2, where each first protruding structure PS1 is used to contact an LED chip through its cross-section S1, and each second protruding structure PS2 is used to support the first protruding structure PS1 through its cross-section S2. Specifically, the second protruding structures PS2 are arranged in an array on the rigid layer 2231, and the first protruding structures PS1 are disposed on the second protruding structures PS2. The shapes of the first protruding structures PS1 and the second protruding structures PS2 may be a cuboid, a cylinder, or a triangular prism. The shapes of the first protruding structures PS1 and the second protruding structures PS2 may be identical or different, and the present invention is not limited thereto. In the present embodiment, an area of the cross-section S1 of each first protruding structure PS1 is smaller than an area of the cross-section S2 of each second protruding structure PS2. In certain embodiments, the area of the cross-section S1 of each first protruding structure PS1 may be, for example, between 9 um² and 2025 um², and the area of the cross-section S2 of each second protruding structure PS2 may be, for example, between 100 um² and 22500 um², but the present invention is not limited thereto. In addition, those skilled in the art may understand that the selection of the cross-sectional area of the first/second protruding structures exemplified above will only be reasonably matched for implementation in different embodiments. For example, if the area of the cross-section S1 of each first protruding structure PS1 is 2000 um², those skilled in the art may understand that the area of the cross-section S2 of each second protruding structure PS2 is only in the range greater than 2000 um² and will not be between 100 um² and 2000 um².

In certain embodiments, the adhesive layer 2232 may only include the first protruding structures PS1, and the first protruding structures PS1 are directly disposed on the rigid layer 2231. In certain embodiments, the adhesive layer 2232 may also be a stencil-like structure, and the present invention is not limited thereto.

Taking the protruding structures as cylinders as an example, the cross-section S1 of each first protruding structure PS1 and the cross-section S2 of each second protruding structure PS2 are circular. The cross-section S2 of each second protruding structure PS2 is used to dispose one or more first protruding structures PS1 thereon, and the cross-section S1 of each first protruding structure PS1 is used to contact the LED chip CP for picking and disposing the LED chip CP. In order for the first protruding structures PS1 to be disposed on the second protruding structures PS2, the area of the cross-section S1 of each first protruding structure PS1 is smaller than the area of the cross-section S2 of each second protruding structure PS2, and the total area of the cross-sections S1 of the plurality of first protruding structures PS1 disposed on the same second protruding structure PS2 is also smaller than the area of the cross-section S2 of the second protruding structure PS2. In FIG. 4B, four cylindrical first protruding structures PS1 are disposed on one cylindrical second protruding structure PS2, but the shape, quantity and arrangement of the first protruding structures PS1 and the second protruding structures PS2 of the present invention are not limited thereto. The first protruding structures PS1 may reduce the contact area between the adhesive layer 2232 and the LED chips CP, successfully pick up the LED chips CP, and also smoothly release the LED chips to the target substrate after picking them up. Therefore, in the mass transfer process, the use of the adhesive substrate 223 structure of the present invention may improve the success rate of picking and disposing the LED chips CP.

The manufacturing method of the adhesive substrate 223 is, for example, firstly preparing a silicon disk mold, then injecting a silicone raw liquid into the mold to cure into a film, and finally demolding and cutting to make it. The mold is formed by adopting an etching method to etch small holes corresponding to the LED chips CP to be transferred on a flat silicon disk. In certain embodiments, the precision error of the mold may be less than ±2 um to ensure that the adhesive layer 2232 being formed one-to-one corresponds to the actual arrangement position of the LED chips CP. In the film forming process, the film thickness may be controlled by controlling parameters such as the raw material ratio, vacuum pressure, and temperature, so as to control the cost. In addition, the position of the adhesive layer 2232 may be prevented from shifting according to the film shrinkage law. In the demolding process, while the adhesive layer 2232 is successfully peeled off from the silicon disk mold one-by-one, the integrity of the silicon disk mold is ensured without causing damage to the mold. The above manufacturing method is not used to limit the present invention thereto.

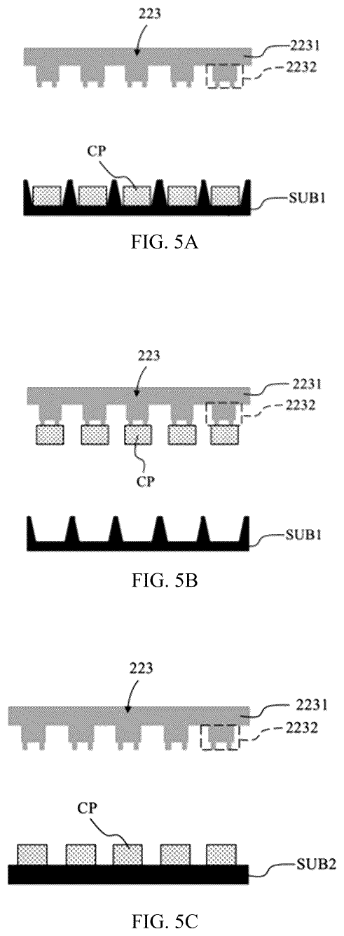

FIGS. 5A to 5C describe the action flows of the adhesive substrate 223 transferring the LED chips CP from the material supporting tray to the target substrate during the mass transfer process. Referring to FIGS. 5A to 5C, the material supporting tray may be, for example, a source substrate. FIG. 5A shows the steps before the adhesive substrate 223 picks up the LED chips CP. FIG. 5B shows the steps after the adhesive substrate 223 picks up the LED chips CP. FIG. 5C shows the steps after the adhesive substrate 223 releases the LED chips CP.

In FIG. 5A, the adhesive layer 2232 (for example, an elastic stamp transfer head) prepared on the rigid layer 2231 one-to-one corresponds to the LED chips CP, thus ensuring position accuracy. Then, the flexibility of the adhesive layer 2232 in the vertical direction (for example, the Z-axis) is utilized to ensure the pickup and transfer of each LED chip CP during the pressing process. The adhesive layer 2232 is not a flat surface, but instead has a plurality of protruding first protruding structures PS1. In FIG. 5B, when the adhesive layer 2232 contacts the LED chip CP and applies a certain acting force, the top plane (that is, the cross-section S1) of the first protruding structure PS1 contacts the LED chip CP and is compressed in response to the acting force (that is, the top collapses), such that the adhesive force of the adhesive layer 2232 may completely act on the LED chip CP to pick up the LED chip CP. When the LED chip CP is located on the adhesive layer 2232, the first protruding structure PS1 on the adhesive layer 2232 will recover its deformation after a period of time. At this time, only the top of the first protruding structure PS1 is in contact with the LED chip CP, so the acting force between the adhesive layer 2232 and the LED chip CP is small. In FIG. 5C, the LED chip CP is brought into contact with the target substrate and slowly moved away, and the LED chip CP is successfully transferred to the target substrate. Therefore, in the mass transfer process, the use of the adhesive substrate 223 structure of the present invention may improve the success rate of picking and disposing the LED chips CP.

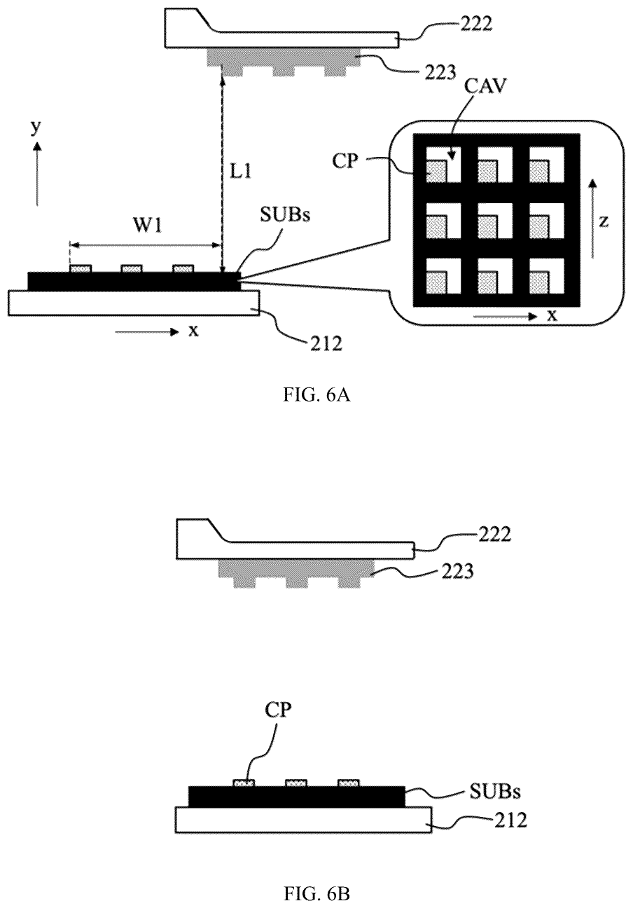

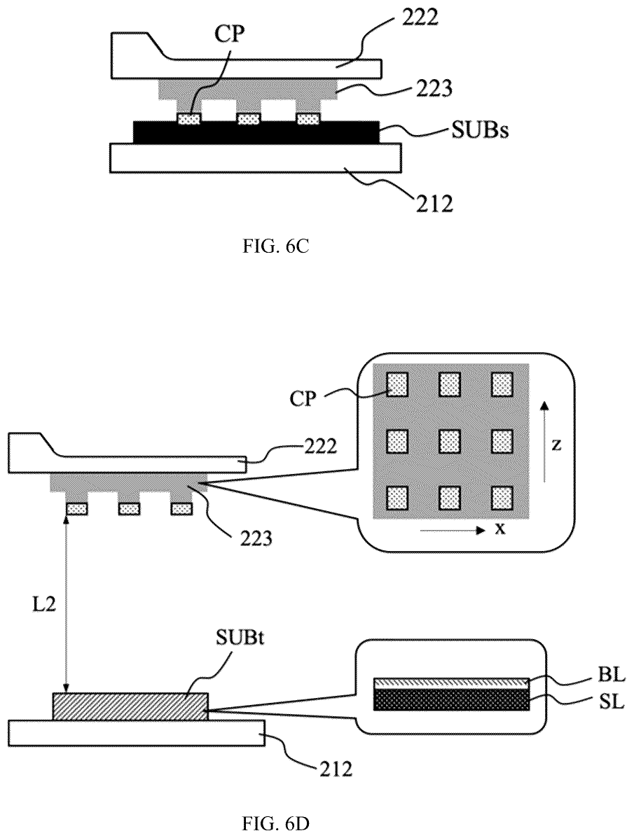

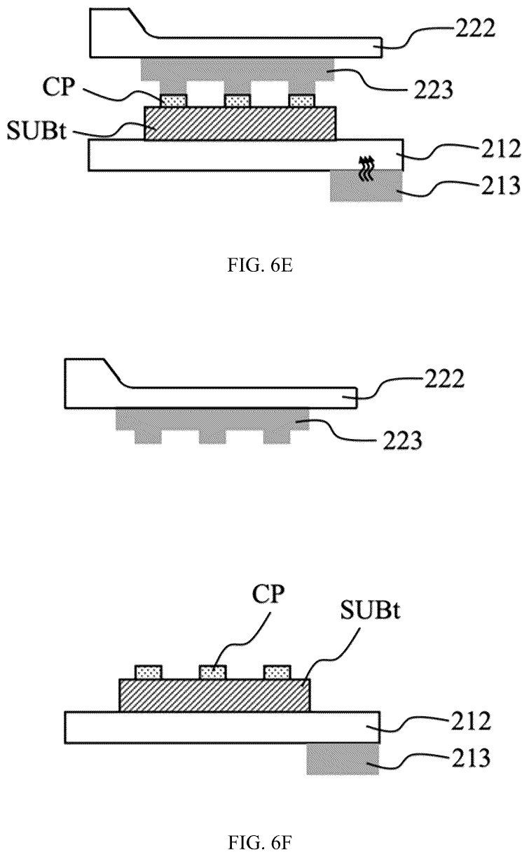

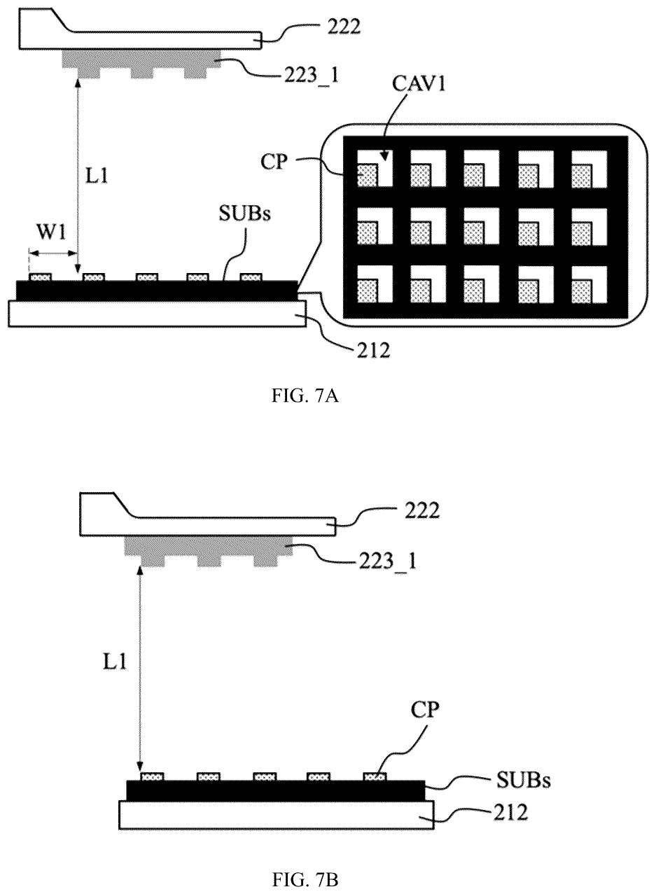

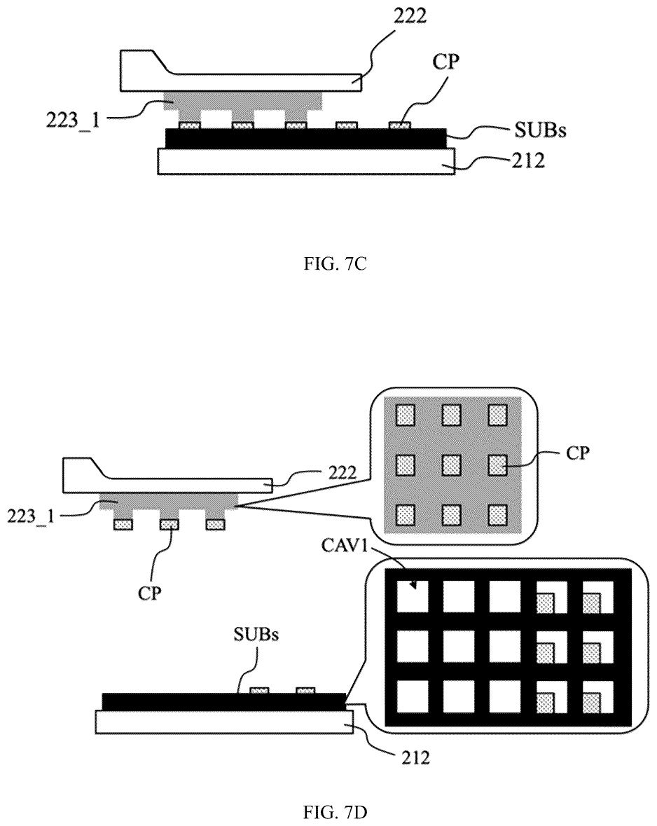

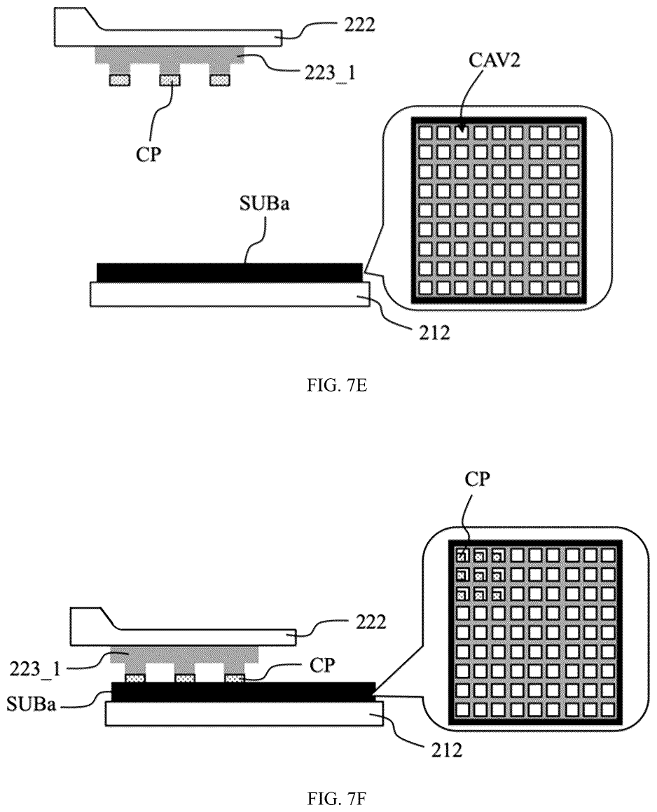

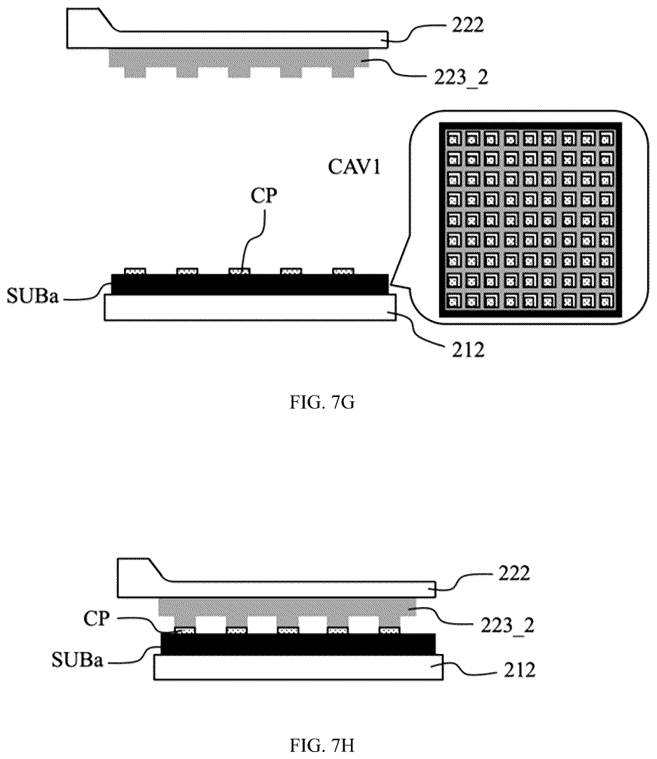

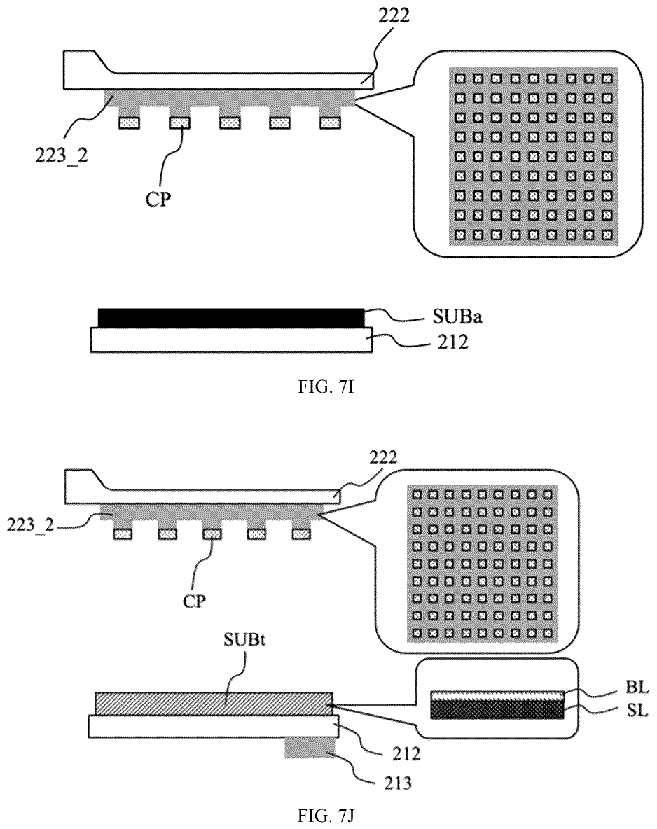

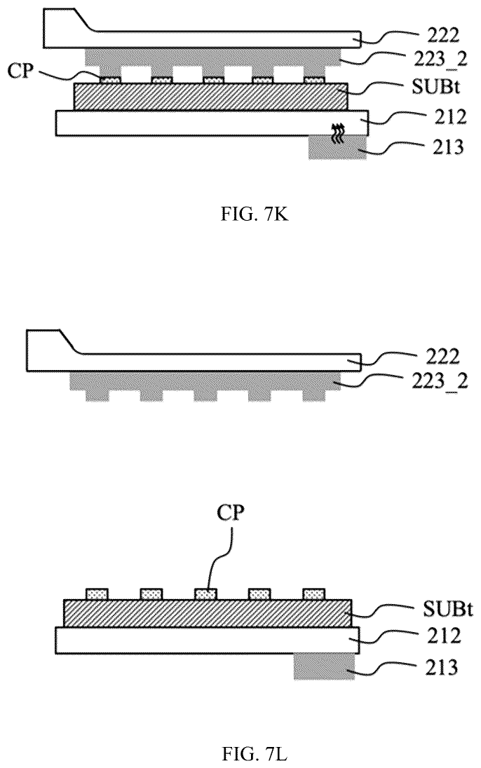

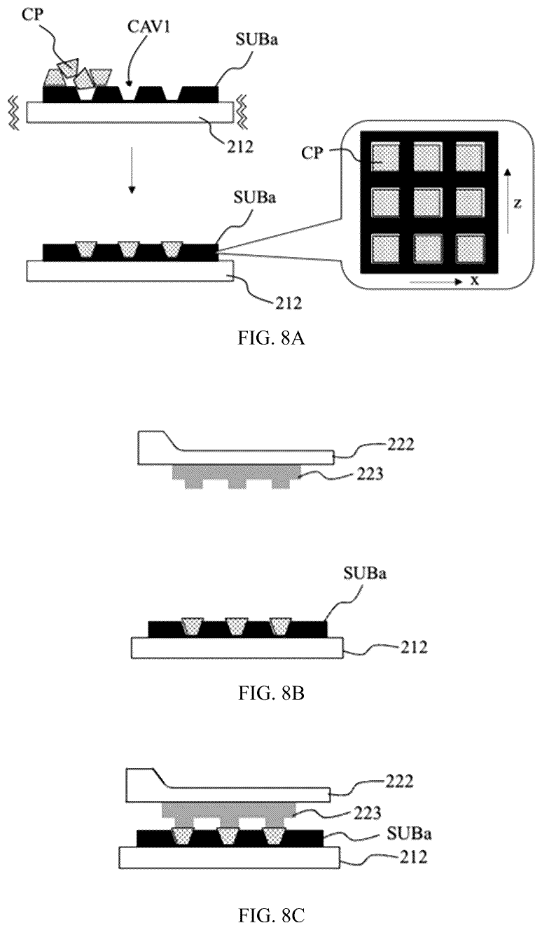

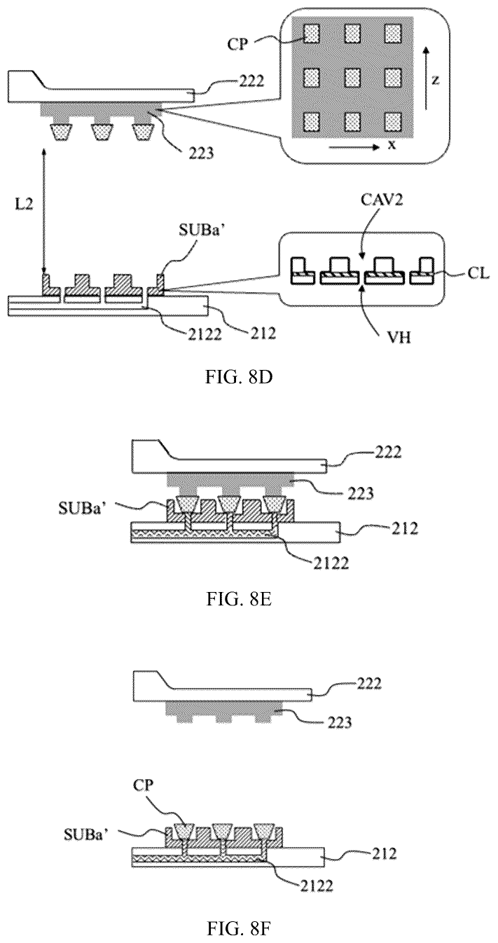

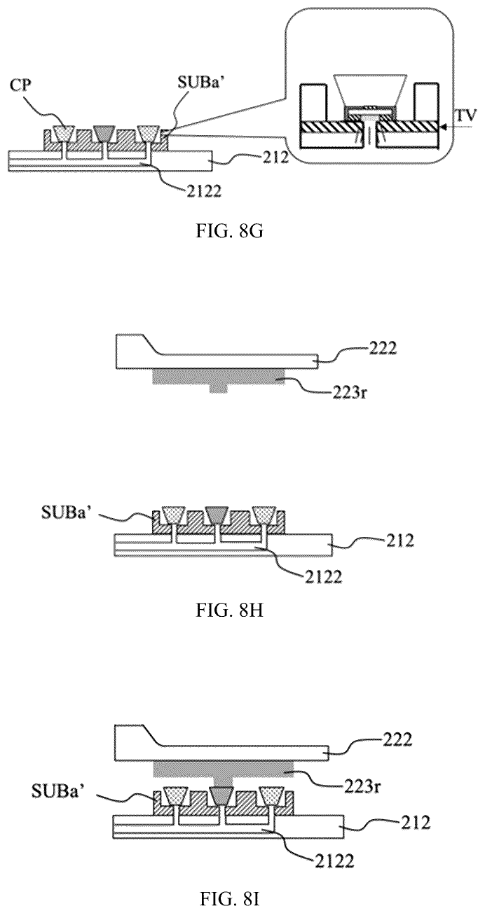

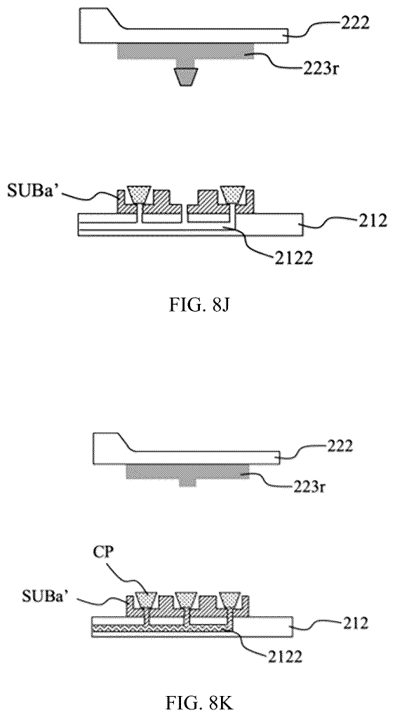

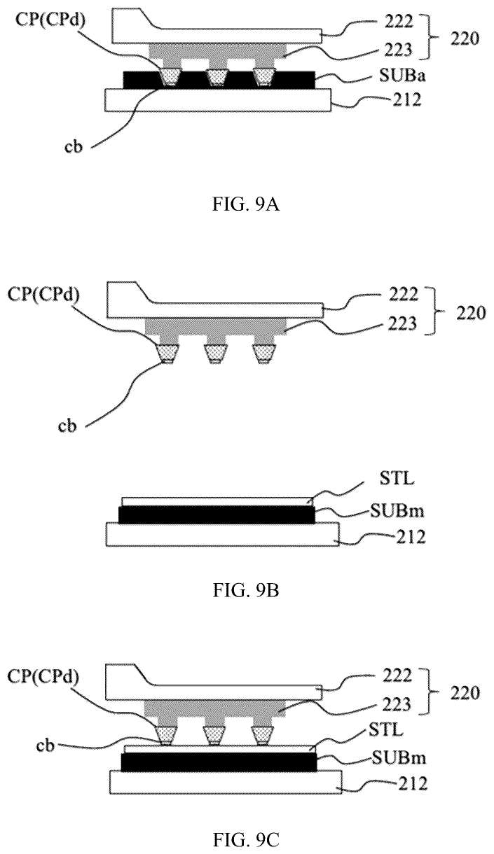

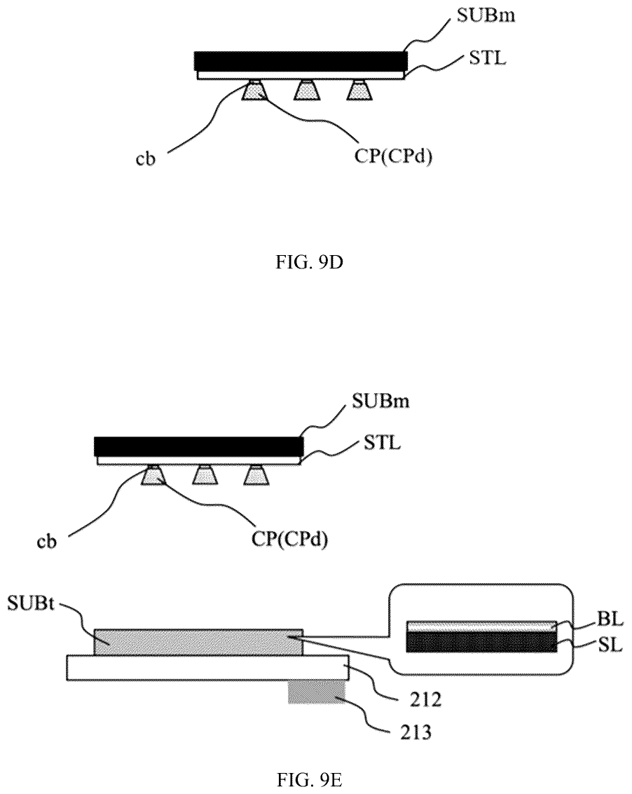

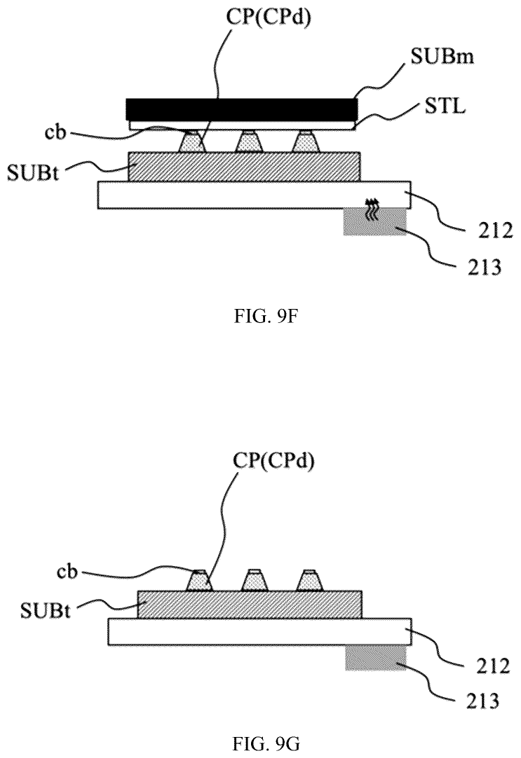

The specific process of operating the mass transfer apparatus 200/300 to perform mass transfer in different embodiments is described below with reference to FIGS. 6A to 6F, FIGS. 7A to 7L, FIGS. 8A to 8K, and FIGS. 9A to 9G. Among them, FIGS. 6A to 6F describe the action flows of the mass transfer apparatus 200/300 directly transferring the LED chips from the source substrate to the target substrate. FIGS. 7A to 7L and FIGS. 8A to 8K describe the action flows of the mass transfer apparatus 200/300 firstly transferring the LED chips from the source substrate to the alignment substrate, and then transferring the LED chips on the alignment substrate to the target substrate. FIGS. 9A to 9G describe the action flows of the mass transfer apparatus 200 transferring the LED chips from the alignment substrate to the reorientation substrate, and then transferring the LED chips on the reorientation substrate to the target substrate. For convenience of description, the following embodiments use the mass transfer apparatus 200 of FIG. 3A as the main body of description, but the present invention is not limited thereto.

Referring to FIG. 3A and FIGS. 6A to 6F firstly, FIGS. 6A to 6F are schematic views of the flows of the mass transfer apparatus performing mass transfer according to certain embodiments of the present invention. As shown in FIG. 6A, the source substrate SUBs of the present embodiment is configured with a 3×3 array of slots CAV as an example (but the present invention is not limited thereto), and each slot CAV may accommodate one LED chip CP. In other words, the LED chips CP are arranged in a 3×3 array on the source substrate SUBs. On the other hand, the comb-like protruding structures on the adhesive substrate 223 are also configured in a 3×3 array corresponding to the slots CAV.

When the mass transfer apparatus 200 starts to operate, the supporting portion 210 and the picking and disposing portion 220 perform pre-alignment to confirm the horizontal displacement amount W1 in the x-z plane between the protrusions on the adhesive substrate 223 and the corresponding slots CAV and the vertical distance L1 in the y-axis between the adhesive substrate 223 and the source substrate SUBs. The above-mentioned action of confirming the horizontal displacement amount W1 may be realized by inspecting the alignment marks of the source substrate SUBs and the adhesive substrate 223 by the CCD sensor of the inspection portion 230. The above-mentioned action of confirming the vertical distance L1 may be realized by moving the adhesive substrate 223 to the dummy region of the source substrate SUBs, and controlling the clamping mechanism 222 to drive the adhesive substrate 223 to move toward the dummy region of the source substrate SUBs until it contacts the dummy region, so as to calculate the vertical distance L1 in the y-axis between the source substrate SUBs and the adhesive substrate 223 based on the recorded movement data.

After obtaining the relative position information PDT such as the horizontal displacement amount W1 and the vertical distance L1, as shown in FIG. 6B, the source substrate SUBs and the adhesive substrate 223 are relatively moved, such that the LED chips CP are aligned with the corresponding protrusions on the adhesive substrate 223. Then, as shown in FIG. 6C, the adhesive substrate 223 moves toward the source substrate SUBs based on the detected vertical distance L1, such that the protruding portions contact the corresponding LED chips CP.

At this time, since the adhesive force of the adhesive substrate 223 acts on the LED chips CP, the LED chips CP adhere to the adhesive substrate 223, and take the LED chips CP away from the source substrate SUBs when the adhesive substrate 223 moves away from the source substrate SUBs. That is, at this time, the LED chips CP on the source substrate SUBs are transferred to the adhesive substrate 223.

As shown in FIG. 6D, the position of the adhesive substrate 223 is re-calibrated to the position aligned with the target substrate SUBt. The calibration process is similar to the pre-alignment process described in FIGS. 6A and 6B, but the present invention is not limited thereto. In the present embodiment, the target substrate SUBt includes, for example, a supporting layer SL and a bonding layer BL disposed on the supporting layer SL, and the bonding layer BL may be implemented by a material that cures when heated, such as conductive silver paste. When the target substrate SUBt is disposed on the supporting platform 212, the bonding layer BL is located on the side close to the adhesive substrate 223.

In certain embodiments, the control portion 240 may also calculate a vertical distance L2 based on the previously pre-positioned data according to the input parameters of the target substrate SUBt. For example, a user may pre-input the thickness of the LED chips CP and the bonding layer BL. Therefore, when performing the alignment calibration of the adhesive substrate 223 and the target substrate SUBt, the displacement amount of the adhesive substrate 223 (equal to the vertical distance L1—thickness of the LED chips—thickness of the bonding layer BL), that is, the vertical distance L2, may be calculated according to the pre-aligned vertical distance L1 and the thicknesses of the LED chips CP and the bonding layer BL.

As shown in FIG. 6E, when the position of the adhesive substrate 223 is calibrated, the clamping mechanism 222 drives the adhesive substrate 223 to move toward the target substrate SUBt, such that the LED chips CP contact the bonding layer BL of the target substrate SUBt. After the LED chips CP contact the target substrate SUBt, the heating component 213 is activated to heat the target substrate SUBt through the supporting platform 212. The bonding layer BL after heating will gradually cure, such that the adhesion force of the LED chips CP to the target substrate SUBt gradually increases.

After a set heating time, the clamping mechanism 222 drives the adhesive substrate 223 to move in the direction away from the target substrate SUBt, as shown in FIG. 6F. At this time, since the attaching force of the LED chips CP to the target substrate SUBt is greater than the attaching force to the adhesive substrate 223, the LED chips CP detach from the adhesive substrate 223 and are transferred and fixed to the target substrate SUBt, thus completing the transfer process.

In some embodiments, the heating temperature set by the heating component 213 may be, for example, 120 °C, and the set heating time may be, for example, 30 minutes, but the present invention is not limited thereto.

Through the above-mentioned mass transfer process, the mass transfer apparatus 200 may transfer all the LED chips CP on the source substrate SUBs to the target substrate SUBt at one time by the adhesive substrate 223, thus effectively improving the efficiency of mass transfer.

Referring to FIG. 3A and FIGS. 7A to 7L, where FIGS. 7A to 7L are schematic views of the flows of the mass transfer apparatus performing mass transfer according to other embodiments of the present invention. The main difference between the present embodiment and the previous embodiment of FIGS. 6A to 6F exists in that the mass transfer apparatus 200 in the present embodiment firstly transfers the LED chips CP on the source substrate SUBs to an alignment substrate SUBa with a size corresponding to the size of the target substrate SUBt, and then transfers all the LED chips CP on the alignment substrate SUBa to the target substrate SUBt at one time. In this way, the operation of transferring the LED chips CP from the small-sized source substrate SUBs to the large-sized target substrate SUBt may be realized.

Specifically, in the present embodiment, the picking and disposing portion 220 includes a plurality of replaceable adhesive substrates 223_1 and 223_2, where the adhesive substrate 223_1 is used for transferring the LED chips CP between the source substrate SUBs and the alignment substrate SUBa, and the adhesive substrate 223_2 is used for transferring the LED chips CP between the alignment substrate SUBa and the target substrate SUBt.

As shown in FIG. 7A, the source substrate SUBs of the present embodiment is configured with a 5×3 array of slots CAVI as an example (but the present invention is not limited thereto), where each slot CAVI may accommodate one LED chip CP. In other words, the LED chips CP are arranged in a 5×3 array on the source substrate SUBs. On the other hand, the comb-like protruding structures on the first adhesive substrate 223_1 corresponding to the source substrate SUBs are configured in a 3×3 array.

When the mass transfer apparatus 200 starts to operate, the supporting portion 210 and the picking and disposing portion 220 perform pre-alignment to confirm the horizontal displacement amount W1 in the x-z plane between the protrusions on the first adhesive substrate 223_1 and the corresponding slots CAV1, and the vertical distance L1 in the y-axis between the first adhesive substrate 223_1 and the source substrate SUBs. The above-mentioned action of confirming the horizontal displacement amount W1 may be realized by inspecting the alignment marks of the source substrate SUBs and the first adhesive substrate 223_1 by the CCD sensor of the inspection portion 230. The above-mentioned action of confirming the vertical distance L1 may be realized by moving the first adhesive substrate 223_1 to the dummy region of the source substrate SUBs, and controlling the clamping mechanism 222 to drive the first adhesive substrate 223_1 to move toward the dummy region of the source substrate SUBs until it contacts the dummy region, so as to calculate the vertical distance L1 in the y-axis between the source substrate SUBs and the first adhesive substrate 223_1 based on the recorded movement data.

After obtaining the relative position information PDT such as the horizontal displacement amount W1 and the vertical distance L1, as shown in FIG. 7B, the source substrate SUBs and the first adhesive substrate 223_1 are relatively moved, such that the LED chips CP are aligned with the corresponding protrusions on the first adhesive substrate 223_1. Then, as shown in FIG. 7C, the first adhesive substrate 223_1 moves toward the source substrate SUBs based on the detected vertical distance L1, such that the protruding portions contact the corresponding LED chips CP.

At this time, as shown in FIG. 7D, since the adhesive force of the first adhesive substrate 223_1 acts on a part of the LED chips CP of the source substrate SUBs, the LED chips CP in contact with the first adhesive substrate 223_1 adhere to the first adhesive substrate 223_1, and when the first adhesive substrate 223_1 moves away from the source substrate SUBs, it takes the part of the LED chips CP away from the source substrate SUBs. That is, at this time, a part of the LED chips CP on the source substrate SUBs are transferred to the first adhesive substrate 223_1.

Then, as shown in FIGS. 7E and 7F, the position of the first adhesive substrate 223_1 will be re-calibrated to the position aligned with the alignment substrate SUBa, and move toward the alignment substrate SUBa to dispose the LED chips CP in the corresponding slots CAV2 of the alignment substrate SUBa. In the present embodiment, the alignment substrate SUBa is configured with the slots CAV2 arranged in a 9×9 array as an example. Each slot CAV2 may also accommodate one LED chip CP, but the present invention is not limited thereto. FIG. 7F shows an example in which the first adhesive substrate 223_1 disposes the LED chips CP arranged in a 3×3 array in the 3×3 empty slots in the upper left corner of the alignment substrate SUBa.

In the present embodiment, the supporting portion 210 may apply acting forces, such as suction forces or adhesion forces, to the slots CAV2 where the LED chips CP are disposed, such that the attaching force of the LED chips CP to the alignment substrate SUBa is greater than the attaching force of the LED chips CP to the first adhesive substrate 223_1. The first adhesive substrate 223_1 then moves in a direction away from the alignment substrate SUBa. At this time, the LED chips CP originally located on the first adhesive substrate 223_1 are transferred to the corresponding slots CAV2 of the alignment substrate SUBa.

Then, the mass transfer apparatus 200 repeats the operations of FIGS. 7A to 7F to successively transfer the LED chips CP on a plurality of source substrates SUBs to the empty slots CAV2 of the alignment substrate SUBa until all the slots CAV2 of the alignment substrate SUBa are filled with LED chips CP, as shown in FIG. 7G.

After all the LED chips CP are transferred to the alignment substrate SUBa, the first adhesive substrate 223_1 of the picking and disposing portion 220 is replaced with a second adhesive substrate 223_2 having a comb-like protruding structures arranged in a 9×9 array, and the step flows similar to FIGS. 7A to 7D described above are executed to transfer all the LED chips CP on the alignment substrate SUBa to the second adhesive substrate 223_2, as shown in FIG. 7I.

Then, as shown in FIG. 7J, the position of the second adhesive substrate 223_2 is re-calibrated to the position aligned with the target substrate SUBt. The calibration process is similar to the pre-alignment process described in FIGS. 6A and 6B, but the present invention is not limited thereto. In the present embodiment, the configuration of the target substrate SUBt is similar to the previous embodiment, and the only difference is the size, and is not further reiterated herein.

As shown in FIG. 7K, when the position of the second adhesive substrate 223_2 is calibrated, the clamping mechanism 222 drives the second adhesive substrate 223_2 to move toward the target substrate SUBt, such that the LED chips CP contact the bonding layer BL of the target substrate SUBt. After the LED chips CP contact the target substrate SUBt, the heating component 213 is activated to heat the target substrate SUBt through the supporting platform 212. The bonding layer BL after heating will gradually cure, such that the attaching force of the LED chips CP to the target substrate SUBt gradually increases.

After a set heating time, the clamping mechanism 222 drives the second adhesive substrate 223_2 to move in the direction away from the target substrate SUBt, as shown in FIG. 7L. At this time, since the attaching force of the LED chips CP to the target substrate SUBt is greater than the attaching force to the second adhesive substrate 223_2, the LED chips CP detach from the second adhesive substrate 223_2 and are transferred and fixed to the target substrate SUBt, thus completing the transfer process.

Referring to FIG. 3A and FIGS. 8A to 8K, where FIGS. 8A to 8K are schematic views of the flows of the mass transfer apparatus performing mass transfer according to other embodiments of the present application. The main difference between the present embodiment and the previous embodiment of FIGS. 7A to 7L exists in that the alignment substrate SUBa in the present embodiment has a different alignment structure and operation process, so as to optimize the transfer reliability between the source substrate SUBs/target substrate SUBt and the alignment substrate SUBa.

Specifically, in the present embodiment, the LED chips CP are designed to have a trapezoidal cross-sectional structure with a narrow upper side and a wide lower side, and the electrodes of the LED chips CP are disposed on the upper bottom side as an example, but the present invention is not limited thereto. In addition, the alignment substrate used in the transfer process of the present embodiment includes a primary alignment substrate SUBa for aligning the direction of the LED chips CP, and a secondary alignment substrate SUBa′ for performing inspection, repair and precise arrangement.

As shown in FIG. 8A, the alignment substrate SUBa of the present embodiment is configured with a 3×3 array of slots CAVI as an example (but the present invention is not limited thereto), where the shape of each slot CAVI is designed to correspond to the LED chips CP with the trapezoidal cross-sectional structure so as to accommodate one LED chip CP. Before the mass transfer apparatus 200 starts to operate, the LED chips CP may be scattered on the alignment substrate SUBa and not fall into the slots CAV1 of the alignment substrate SUBa neatly. When the mass transfer apparatus 200 starts to operate, the alignment actuation portion 250 generates an acting force or control the alignment substrate SUBa to generate an acting force, such that the LED chips CP respond to the acting force and fall into the slots CAV1.

In certain embodiments, the alignment actuation portion 250 generates vibration as the acting force to drive the supporting platform 212 and the alignment substrate SUBa, thereby causing the LED chips CP to respond to the vibration and fall into the slots CAV1.

In certain embodiments, the alignment substrate SUBa further includes an electromagnetic generating component (such as electromagnets), and each LED chip CP is provided with a magnetic component. During the LED chip alignment, the alignment actuation portion 250 provides power to the electromagnetic generating component in the alignment substrate SUBa to generate a magnetic force, and cause the magnetic components on the LED chips CP to respond to the magnetic force and fall into the slots CAV1 in the same direction.

In certain embodiments, since the slots CAVI of the alignment substrate SUBa are designed as inverted trapezoidal structures with a narrow lower side and a wide upper side and correspond to the size of the LED chips CP (as shown in FIG. 8A), the LED chips CP only fall into the slots CAVI with the upper bottom side facing downward when they respond to vibration and fall into the slots CAV1. On the other hand, in certain embodiments, by providing a magnetic structure on the alignment substrate SUBa, the directional characteristics of the magnetic force may also be used to ensure that the LED chips CP all fall into the alignment substrate SUBa in the same direction.

Then, as shown in FIGS. 8B and 8C, after the supporting portion 210 and the picking and disposing portion 220 complete pre-alignment (with the specific process thereof referring to the previous embodiment, and is not further reiterated herein), the alignment substrate SUBa and the adhesive substrate 223 are relatively moved, such that the LED chips CP are aligned with the corresponding protrusions on the adhesive substrate 223, and the adhesive substrate 223 moves toward the alignment substrate SUBa based on the vertical distance being inspected, such that the protruding portions contact the corresponding LED chips CP.

At this time, since the adhesive force of the adhesive substrate 223 acts on the LED chips CP of the alignment substrate SUBa, the LED chips CP in contact with the adhesive substrate 223 adhere to the adhesive substrate 223, and when the adhesive substrate 223 moves away from the alignment substrate SUBa, it takes the LED chips CP away from the alignment substrate SUBa. That is, at this time, the LED chips CP on the alignment substrate SUBa are transferred to the adhesive substrate 223. Then, the position of the adhesive substrate 223 is re-calibrated to the position aligned with the alignment substrate SUBa′, as shown in FIG. 8D.

In the present embodiment, the alignment substrate SUBa′ may be designed, for example, such that the bottom of each slot CAV2 has a corresponding micro-hole structure VH. The supporting platform 212 has vacuum channels 2122 corresponding to the positions of the micro-hole structures VH, and the vacuum channels 2122 and the micro-hole structures VH form a closed pipeline, such that the alignment actuation portion 250 may apply a suction force through the pipeline.

Then, as shown in FIGS. 8E and 8F, the adhesive substrate 223 moves toward the alignment substrate SUBa′ to dispose the LED chips CP in the corresponding slots CAV2 of the alignment substrate SUBa′. In the present embodiment, the alignment substrate SUBa′ is configured with slots CAV2 arranged in a 3×3 array as an example, and each slot CAV2 may also accommodate one LED chip CP, but the present invention is not limited thereto. In the present embodiment, the alignment actuation portion 250 may apply the suction force to the slots CAV2 where the LED chips CP are disposed through the closed pipeline formed by the micro-hole structures VH and the vacuum channels 2122, such that the attaching force of the LED chips CP to the alignment substrate SUBa′ is greater than the attaching force of the LED chips CP to the adhesive substrate 223. The adhesive substrate 223 then moves in a direction away from the alignment substrate SUBa′. At this time, the LED chips CP originally located on the adhesive substrate 223 are transferred to the corresponding slots CAV2 of the alignment substrate SUBa′.

In certain embodiments, after the LED chips CP are transferred to the alignment substrate SUBa′, the electrodes of the LED chips CP contact the conductive layer CL on the alignment substrate SUBa′. Therefore, the LED chips CP on the alignment substrate SUBa′ may be electrically tested by applying a test voltage TV to the conductive layer CL to confirm whether they may be normally lit, as shown in FIG. 8G. During the electrical testing process, if it is found that some LED chips CP are damaged (the second LED chip CP in FIG. 8G is not lit during the test), the damaged LED chips CP may be removed from the alignment substrate SUBa′ by a repair adhesive substrate 223r, and new LED chips CP may be disposed in the slots CAV2 originally occupied by the damaged LED chips CP, as shown in FIGS. 8H to 8K.

The transfer process from the alignment substrate SUBa′ to the target substrate SUBt may refer to the process of FIGS. 7G to 7L as described above, and, and is not further reiterated herein.

Compared with the mass transfer process of FIGS. 7A to 7L, the present embodiment may perform preliminary and subsequent precise alignments by a variety of different alignment substrates, and electrical inspection may also be realized during the mass transfer process on the secondary alignment substrate SUBa′, so as to repair/replace defective LED chips in time, thereby avoiding the problem that the product yield is reduced due to the problem that the LED chips are fixed on the target substrate and cannot be repaired.

It should be noted that the above-mentioned process of replacing the damaged LED chips CP by the repair adhesive substrate 223r after electrical testing is only described as an example. In other embodiments, the user may also use different picking and disposing mechanisms, and the present invention is not limited thereto. The repair adhesive substrate 223r may be a material similar to the adhesive substrate 223, but with protruding structures existing only at specific positions thereon, rather than having protruding structures in an array corresponding to the slots.

Referring to FIG. 3A and FIGS. 9A to 9G, where FIGS. 9A to 9G are schematic views of the flows of the mass transfer apparatus performing mass transfer according to other embodiments of the present invention. The main difference between the present embodiment and the previous embodiment exists in that the present embodiment adds a transfer process for adjusting the direction of the LED chips CP between the transfer processes of the alignment substrate SUBa and the target substrate SUBt, such that the LED chips CP may be transferred and arranged on the target substrate SUBt in the correct direction at one time.

Specifically, in the present embodiment, the LED chips CP are similar to those in the embodiment of FIGS. 8A to 8K described above, and are designed to have a trapezoidal cross-sectional structure with a narrow upper side and a wide lower side, and the electrodes of the LED chips CP are disposed on the upper bottom side as an example, but the present invention is also not limited thereto. In addition, in the transfer process of the present embodiment, the alignment substrate used by the mass transfer apparatus is described by taking the primary alignment substrate SUBa for aligning the direction of the LED chips CP as an example, but the present invention is not limited thereto. In certain embodiments, the present embodiment may also use the secondary alignment substrate SUBa′ with inspection, repair and precise arrangement as described in the previous embodiment to perform mass transfer.

As shown in FIG. 9A, the alignment substrate SUBa of the present embodiment has a plurality of slots CAV1, where the shape of each slot CAV1 is designed to correspond to the LED chips CP with a trapezoidal cross-sectional structure to accommodate one LED chip CP. The process of how to make the LED chips CP fall into the slots CAVI correctly may refer to the description of the embodiment of FIG. 8A as described above, and is not further reiterated herein.

After the supporting portion 210 and the picking and disposing portion 220 complete the pre-alignment (with the specific process thereof referring to the previous embodiment, and is not further reiterated herein), the alignment substrate SUBa and the adhesive substrate 223 are relatively moved, such that the LED chips CP are aligned with the corresponding protrusions on the adhesive substrate 223, and the adhesive substrate 223 moves toward the alignment substrate SUBa on the supporting platform 212 based on the vertical distance being inspected, such that the protruding portions contact the corresponding LED chips CP.

It should be noted that each of the LED chips CP on the alignment substrate SUBa includes a chip body cb, where the LED chips CP are disposed in the alignment substrate SUBa in such a way that the chip bodies cb are located at the bottom of the slots of the alignment substrate SUBa without being exposed. Therefore, the adhesive surface of the adhesive substrate 223 is in contact with the surfaces of the LED chips CP on the alignment substrate SUBa that do not have the chip bodies cb.

At this time, since the adhesive force of the adhesive substrate 223 acts on the LED chips CP of the alignment substrate SUBa, the LED chips CP in contact with the adhesive substrate 223 adhere to the adhesive substrate 223, and when the adhesive substrate 223 moves away from the alignment substrate SUBa, it takes the LED chips CP away from the alignment substrate SUBa. That is, at this time, the LED chips CP on the alignment substrate SUBa are transferred to the adhesive substrate 223.

Then, as shown in FIGS. 9B and 9C, the position of the adhesive substrate 223 is re-calibrated to the position aligned with the reorientation substrate SUBm on the supporting platform 212. Then, the adhesive substrate 223 moves toward the reorientation substrate SUBm to dispose the LED chips CP on the reorientation substrate SUBm. In the present embodiment, since the reorientation substrate SUBm may adopt a material with a higher adhesive force than the adhesive substrate 223, the attaching force of the LED chips CP to the reorientation substrate SUBm is greater than the attaching force of the LED chips CP to the adhesive substrate 223. Therefore, when the adhesive substrate 223 moves in the direction away from the reorientation substrate SUBm, the LED chips CP originally located on the adhesive substrate 223 are transferred to the reorientation substrate SUBm.

In certain embodiments, the reorientation substrate SUBm may include, for example, an adhesive layer STL. The adhesive layer STL may be formed by, for example, heat-resistant polyester and adhesive materials disposed on two sides thereof. A thickness of the heat-resistant polyester may be between 17 μm and 33 μm, and may be, for example, 25 μm. A thickness of the adhesive materials may be between 14 μm and 26 μm, and may be, for example, 20 μm. Through the above configurations, the reorientation substrate SUBm may have the required adhesiveness. In addition, in order to prevent the LED chips CP adhered to the reorientation substrate SUBm from falling off during flipping, and to ensure that the LED chips CP may be smoothly transferred to the second substrate SUB2, the adhesive force (peeling force) of the adhesive layer STL of the reorientation substrate SUBm is, for example, between 0.2 N/25 mm and 20.5 N/25 mm, and may be, for example, 0.20 N/25 mm, 0.83 N/25 mm, 1.85 N/25 mm, or 20.11 N/25 mm, but the present invention is not limited thereto.

Then, as shown in FIGS. 9D and 9E, after the LED chips CP are transferred to the reorientation substrate SUBm, the mass transfer apparatus flips the reorientation substrate SUBm with a plurality of LED chips CP adhered thereon once, such that the LED chips CP originally facing upward become facing downward. The position of the reorientation substrate SUBm will be re-calibrated to the position aligned with the target substrate SUBt. The calibration process is similar to the pre-alignment process described in FIGS. 6A and 6B, but the present invention is not limited thereto. In the present embodiment, the configuration of the target substrate SUBt is similar to the previous embodiment, and is not further reiterated herein.

Then, as shown in FIGS. 9F and 9G, when the position of the reorientation substrate SUBm is calibrated, the clamping mechanism 222 drives the reorientation substrate SUBm to move toward the target substrate SUBt, such that the LED chips CP contact the bonding layer BL of the target substrate SUBt. After the LED chips CP contact the target substrate SUBt, the heating component 213 is activated to heat the target substrate SUBt through the supporting platform 212. The bonding layer BL after heating gradually cures, such that the attaching force of the LED chips CP to the target substrate SUBt gradually increases.

After a set heating time, the reorientation substrate SUBm is removed. In certain embodiments, the bonding force between the LED chips CP and the bonding layer BL of the target substrate SUBt may be 400 to 1000 KPa, and the thickness thereof may be 1.0 to 5.0 μm. The bonding force is greater than the peeling force of the adhesive material of the adhesive layer STL of the reorientation substrate SUBm. Therefore, when the reorientation substrate SUBm is separated from the LED chips CP, the LED chips CP do not fall off from the target substrate SUBt together, that is, the LED chips CP are separated from the adhesive material of the adhesive layer STL of the reorientation substrate SUBm and remain on the bonding layer BL on the target substrate SUBt.

In certain embodiments, the set heating temperature may be, for example, 100 °C, and the set heating time may be, for example, 10 minutes to complete curing, but the present invention is not limited thereto.

In other words, at this time, since the attaching force of the LED chips CP to the target substrate SUBt is greater than the attaching force to the reorientation substrate SUBm, the LED chips CP detach from the reorientation substrate SUBm and are transferred and fixed to the target substrate SUBt, thus completing the transfer process.

Therefore, in the application of LED chip transfer, the mass transfer process of the above-mentioned embodiment of FIGS. 9A to 9G may achieve the beneficial effect of accurately and quickly flipping a plurality of dice at one time without affecting the premise that they are aligned neatly and facing in the same direction on the alignment substrate, and at the same time, the flipped dice may be smoothly fixed on the target backplane.

In addition, in the cross-sectional structure shown in the above-mentioned embodiments of FIGS. 6A to 9G, in order to clearly show the relative configuration relationship between the LED chips CP and the source substrate SUBs/alignment substrate SUBa/reorientation substrate SUBm/target substrate SUBt, the structure in which the LED chips CP protrude from the source substrate SUBs/alignment substrate SUBa/reorientation substrate SUBm/target substrate SUBt is illustrated, but the present invention is not limited thereto. In practical applications, according to the structural design of the source substrate SUBs/alignment substrate SUBa/reorientation substrate SUBm/target substrate SUBt, the LED chips CP may also be configured to have the same height as the source substrate SUBs/alignment substrate SUBa/reorientation substrate SUBm/target substrate SUBt (that is, the top of the LED chips CP is approximately on the same plane as the top surface of the source substrate SUBs/alignment substrate SUBa/reorientation substrate SUBm/target substrate SUBt), or be configured to be slightly lower than the height of the source substrate SUBs/alignment substrate SUBa/reorientation substrate SUBm/target substrate SUBt (that is, the top of the LED chips CP is slightly lower than the top surface of the source substrate SUBs/alignment substrate SUBa/reorientation substrate SUBm/target substrate SUBt), where the top surface of the source substrate SUBs/alignment substrate SUBa/reorientation substrate SUBm/target substrate SUBt refers to the surface away from the supporting platform 212.

It is also noted that, although the mass transfer processes of the above-mentioned embodiments are all described in conjunction with the mass transfer apparatus 200 of the embodiment of FIG. 3A, the present invention is not limited thereto. In other embodiments, the above-mentioned mass transfer processes may also be realized in conjunction with the mass transfer apparatus 300 of FIGS. 3B and 3C. In the case of using the mass transfer apparatus 300, the source substrate SUBs, the alignment substrates SUBa and SUBa′, the reorientation substrate SUBm and the target substrate SUBt mentioned in the previous embodiments may be respectively configured on the supporting platforms 312a to 312d, and the multi-axis movement control mechanism 321 is used to sequentially perform picking, disposing and transferring between any two of the supporting platforms 312a to 312d.

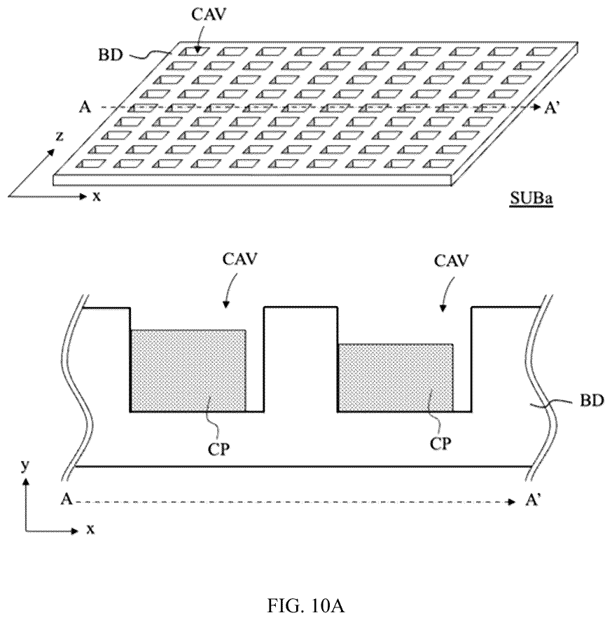

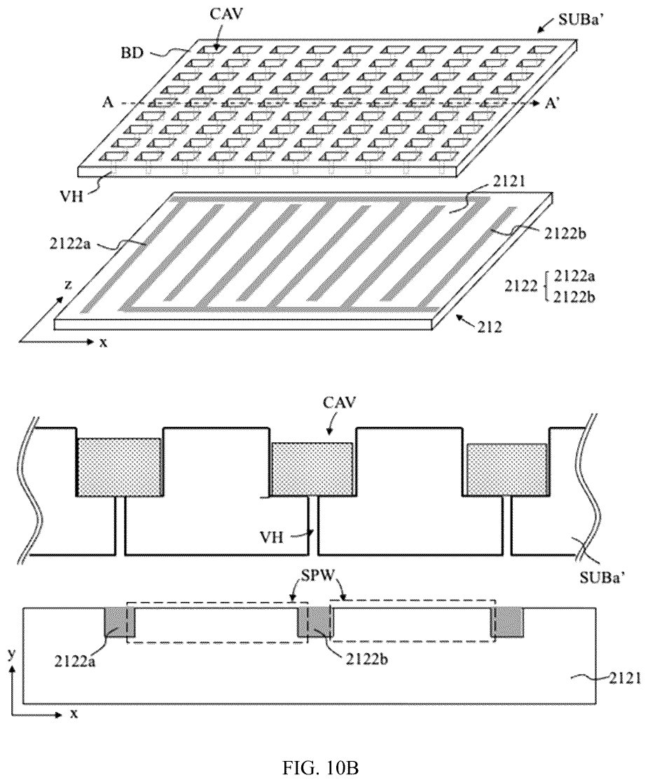

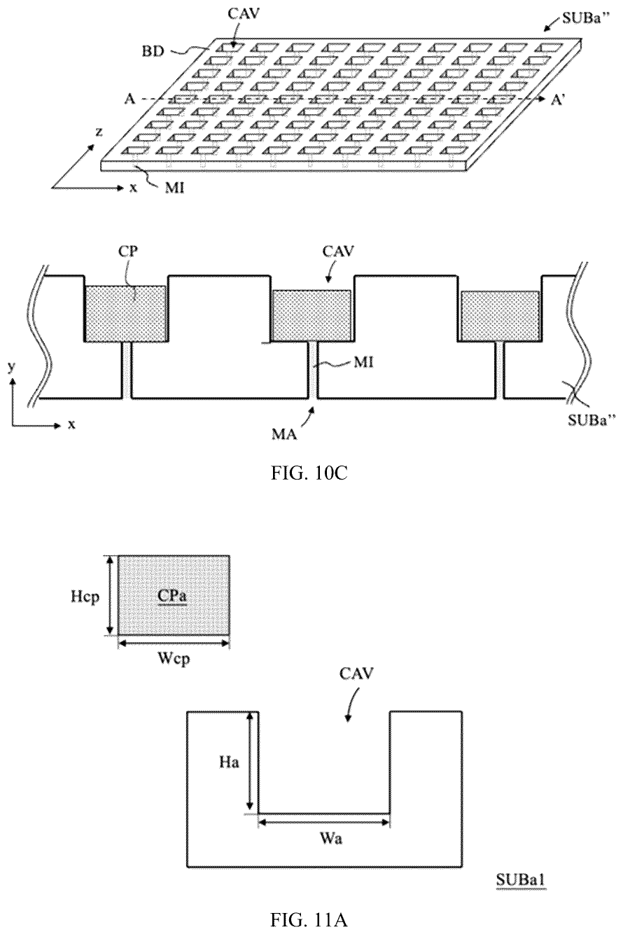

FIG. 10A is a schematic view of the structural configuration of an alignment substrate according to certain embodiments of the present application. The upper half of FIG. 10A is a top view of the alignment substrate SUBa, and the lower half of FIG. 10A is a cross-sectional view of the alignment substrate SUBa taken along line AA′. Referring to FIG. 10A, the alignment substrate SUBa in the present embodiment includes a substrate body BD and a plurality of slots CAV arranged in an array on the substrate body BD. The size of each slot CAV is designed to correspond substantially to the size of a single LED chip CP. Viewing from an external perspective, each slot CAV is a recessed accommodating space on the substrate body BD. When the LED chip CP is disposed in the slot CAV, the bottom or top of the LED chip CP may be substantially flush with the bottom surface of the slot CAV. In other words, when the LED chip CP is disposed in the slot CAV, the bottom surface of the slot CAV is substantially parallel to the bottom or top of the LED chip CP.

FIG. 10B is a schematic view of the structural configuration of an alignment substrate according to other embodiments of the present application. The upper half of FIG. 10B is a top view of the alignment substrate SUBa′, and the lower half of FIG. 10B is a cross-sectional view of the alignment substrate SUBa′ taken along line AA′. Referring to FIG. 10B, the alignment substrate SUBa′ in the present embodiment is similar to the alignment substrate SUBa in the previous embodiment, and also includes a substrate body BD and a plurality of slots CAV arranged in an array on the substrate body BD. Therefore, similar structural descriptions may be referred to the above embodiment, and are not further reiterated herein.

The main difference between these two embodiments exists in that each slot CAV of the alignment substrate SUBa′ in the present embodiment further has a corresponding micro-hole structure VH. One end opening of the micro-hole structure VH may, for example, be exposed on the bottom surface of the slot CAV, and the other end opening of the micro-hole structure VH is connected to the alignment actuation portion (such as 250). During the transfer process, the alignment actuation portion 250 may apply vacuum suction to the LED chips in the slots CAV through the micro-hole structures VH, such that the attaching force of the LED chips to the alignment substrate SUBa′ is greater than the attaching force of the adhesive substrate (such as 223_1/223_2), thereby realizing the transfer of the LED chips between substrates.

In certain embodiments, the supporting platform 212 may include, for example, a platform body 2121 and vacuum channels 2122 provided in the platform body 2121. When the alignment substrate SUBa′ is disposed on the supporting platform 212, the positions of the micro-hole structures VH of the slots CAV correspond to the positions of the vacuum channels 2122 to form a closed pipeline. The alignment actuation portion 250 may apply the suction force to the LED chips in the slots CAV through the closed pipeline. It should be noted that the closed pipeline refers to the fact that the pipeline gap does not prevent the acting force from applying to the LED chips when the alignment actuation portion 250 applies the suction force, and does not limit the pipeline to be in a completely sealed and gap-free state.

In certain embodiments, the vacuum channels 2122 of the supporting platform 212 may be configured to have interleaved first comb-shaped channels 2122a and second comb-shaped channels 2122b. The first comb-shaped channels 2122a are configured at positions corresponding to odd-numbered rows of the slots CAV, and the second comb-Attorney shaped channels 2122b are configured at positions corresponding to even-numbered rows of the slots CAV. With the above-mentioned configuration, when the alignment actuation unit 250 applies the suction force, the suction force may be evenly distributed on the platform body 2121, thereby avoiding problems such as collapse or other abnormalities of the platform body 2121 when the alignment actuation portion 250 applies the suction force.

In certain embodiments, the platform body 2121 may also be formed with supporting walls SPW protruding in the region between the first comb-shaped channels 2122a and the second comb-shaped channels 2122b. The supporting walls SPW may be used to prevent the peripheral areas of the first comb-shaped channels 2122a and the second comb-shaped channels 2122b from collapsing when the alignment actuation portion 250 applies the suction force, thereby improving the life and reliability of the supporting platform 212.

FIG. 10C is a schematic view of the structural configuration of an alignment substrate according to still other embodiments of the present invention. The upper half of FIG. 10C is a top view of the alignment substrate SUBa″, and the lower half of FIG. 10C is a cross-sectional view of the alignment substrate SUBa″ taken along line AA′. Referring to FIG. 10C, the alignment substrate SUBa″ in the present embodiment is similar to the alignment substrate SUBa′ in the previous embodiment, which also includes a substrate body BD and a plurality of slots CAV arranged in an array on the substrate body BD. Therefore, similar structural descriptions may be referred to the above embodiment, and are not further reiterated herein.

The main difference between the present embodiment and the previous embodiment exists in that each slot CAV of the alignment substrate SUBa″ in the present embodiment further has a corresponding magnetic structure MI. The bottom of each slot CAV has a corresponding material accommodating portion MA. The magnetic structure MI may be, for example, filled in the material accommodating portion MA. In certain embodiments, the material accommodating portion MA may be, for example, a groove or a micro-hole structure VH similar to that of the embodiment of FIG. 10B, and the present invention is not limited thereto.

In certain embodiments, each LED chip CP includes a chip body (not shown, that is, the part including the light emitting layer) and a magnetic component (not shown). The chip body is disposed on one side of the LED chip CP, and the magnetic component is disposed on the opposite side of the LED chip CP. During the transfer of this type of the LED chips CP, the magnetic components on the LED chips CP may respond to the magnetic force provided by the magnetic structures MI and fall into the slots CAV of the alignment substrate SUBa″ in the same direction.

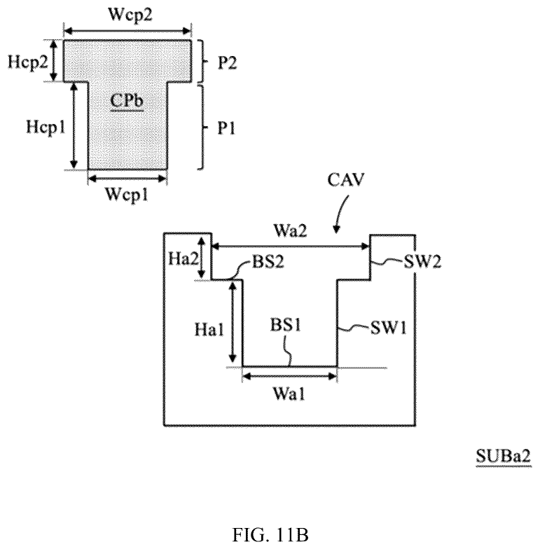

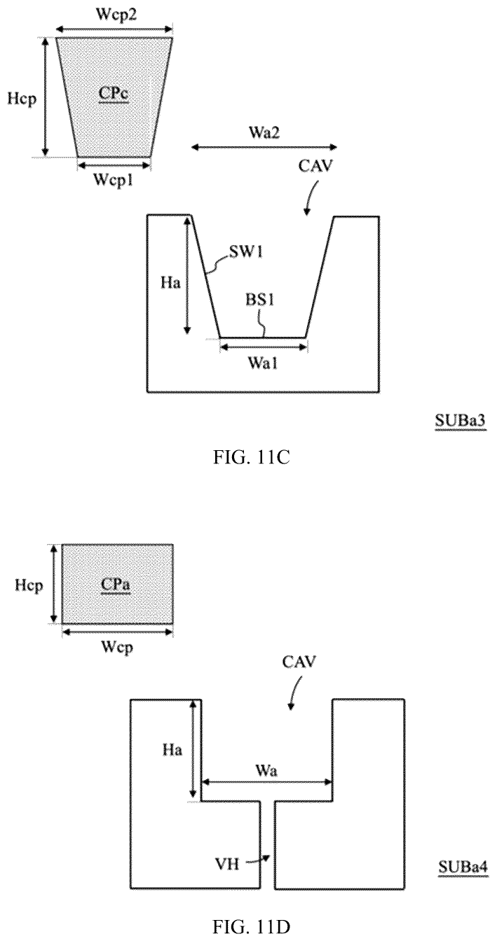

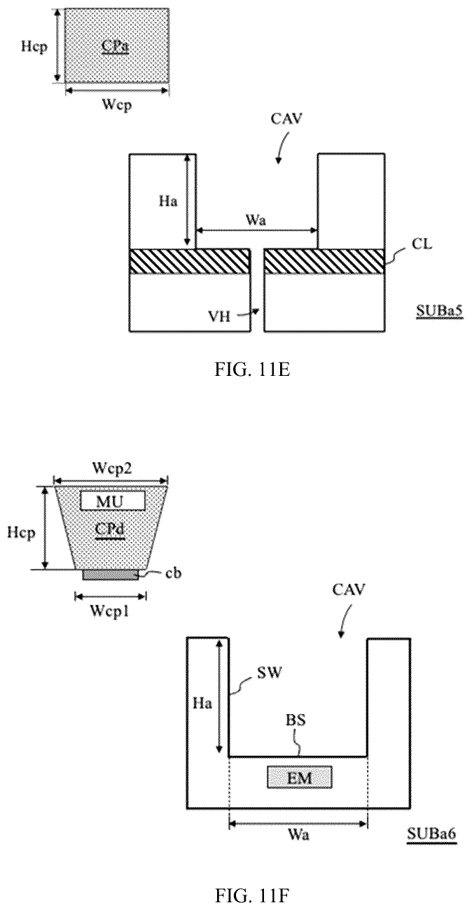

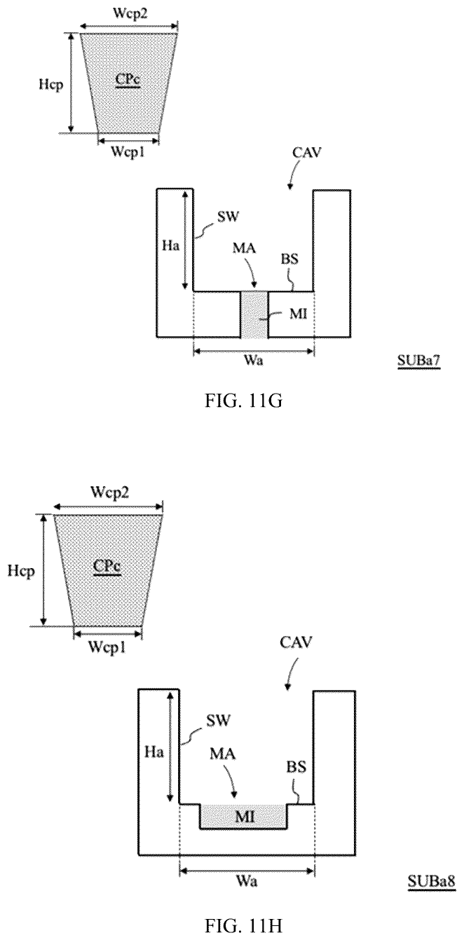

For example, the magnetic structure MI and the magnetic component on each LED chip CP may be set to have mutually attractive magnetic force directions, such that when the LED chip CP falls into the corresponding slot CAV, the side provided with the magnetic component faces the magnetic structure MI. In other words, the side of the LED chip CP provided with the chip body faces upward and is exposed. Through the above configuration of the alignment substrate SUBa/SUBa′/SUBa″, the LED chips CP may fall into the corresponding slots CAV facing in the same direction, so as to achieve the orderly arrangement of the LED chips CP. The structural design of the alignment substrate SUBa/SUBa′/SUBa″ in different embodiments is further described below with reference to FIGS. 11A to 11H.

FIGS. 11A to 11H are schematic views of cross-sections of the alignment substrate according to different embodiments of the present invention, in which each figure illustrates the structural configuration of a single slot as an example, and those skilled in the art should understand that the slot structure described in each embodiment may be applied to at least some/all of the slots of the alignment substrate. In addition, the alignment substrate described in the following embodiments are mainly described using a two-dimensional cross-sectional structure. Therefore, only the width (horizontal distance in the figure; i.e., the distance in the x-direction) and height (vertical distance in the figure; i.e., the distance in the y-direction) of the LED chip/slot are shown in each figure. However, those skilled in the art should understand that the design considerations for the length (distance in the direction normal to the figure; i.e., the distance in the z-direction) of the LED chip/slot are similar to the width of the LED chip/slot. Therefore, although the following descriptions of the embodiments focus on the width, those skilled in the art should understand the design considerations for the length of the LED chip/slot based on the related descriptions.

Referring to FIG. 11A, in the present embodiment, a cuboid-shaped slot CAV is formed on the substrate body of the alignment substrate SUBa1. The cuboid-shaped slot CAV may be used to accommodate a cuboid-shaped LED chip CPa, where the width of the LED chip CPa is Wcp, the height thereof is Hcp, and the width of the slot CAV is Wa, and the depth thereof is Ha.

In the present embodiment, the width Wa of the slot CAV is designed to be slightly greater than the width Wcp of the LED chip CPa, and the depth Ha of the slot CAV is designed to be slightly greater than the height Hcp of the LED chip CPa.

In certain embodiments, the width Wa of the slot CAV is designed to be between 101% and 140% of the width Wcp of the LED chip CPa, so as to prevent multiple LED chips CPa from falling into the same slot CAV. Since the LED chips CPa with different emission wavelengths may have different sizes, the width Wcp of the LED chip CPa described herein may be determined based on the LED chip CPa with the maximum width, but the present invention is not limited thereto.

In certain embodiments, the depth Ha of the slot CAV is designed to be between 101% and 140% of the height Hcp of the LED chip CPa, and more preferably, for example, between 101% and 110%, so as to prevent the LED chip CPa that has fallen into the slot CAV from running out of the slot CAV due to vibration or other forces, or to prevent two LED chips CPa from entering the same slot. Similarly, the height Hcp of the LED chip CPa described herein may be determined based on the LED chip with the maximum height, but the present invention is not limited thereto.

For example, if the width Wcp/height Hcp of the LED chip CPa is 5 μm, the width Wa/depth Ha of the slot CAV may be designed to be between 5.25 μm and 6.5 μm.

Referring to FIG. 11B, the present embodiment illustrates an example of an alignment substrate SUBa2 with another slot CAV structure. In the present embodiment, the slot CAV on the alignment substrate SUBa2 is designed to accommodate an LED chip CPb with a two-layer structure. Specifically, the LED chip CPb with the two-layer structure includes a first part P1 and a second part P2, in which both the first part P1 and the second part P2 may be, for example, cuboid structures, and the first part P1 is formed on one side (the lower side in the figure) of the second part P2.

In the present embodiment, the width Wcp1 of the first part P1 is less than the width Wcp2 of the second part P2, and the sum of the height Hcp1 of the first part P1 and the height Hcp2 of the second part P2 (i.e., the height of the LED chip CPb) is greater than the width Wcp1 of the first part P1. In other words, the LED chip CPb has a structure similar to a shape of the Chinese character “ [symbol] ”.

On the other hand, the slot CAV in the present embodiment is provided to correspond to the two-layer structure of the LED chip CPb. The slot CAV includes a first side wall SW1, a second side wall SW2, a first bottom surface BS1 and a second bottom surface BS2. The first side wall SW1 surrounds a periphery of the first bottom surface BS1, and the bottom of the first side wall SW1 is connected to the first bottom surface BS1. The space defined by the first side wall SW1 and the first bottom surface BS1 (hereinafter referred to as the first accommodating space) is used to accommodate the first part P1 of the LED chip CPb. The height of the first side wall SW1 is Hal, and the width defined by the first bottom surface BS1 is Wa1. One side of the second bottom surface BS2 is connected to the top of the first side wall SW1. The second side wall SW2 surrounds a periphery of the second bottom surface BS2, and the bottom of the second side wall SW2 is connected to the other side of the second bottom surface BS2. The space defined by the second side wall SW2, the first bottom surface BS1 and the second bottom surface BS2 (i.e., the space in the slot CAV that does not overlap with the first accommodating space, hereinafter referred to as the second accommodating space) is used to accommodate the second part P2 of the LED chip CPb. The height of the second side wall SW2 is Ha2, and the total width of the first bottom surface BS1 and the second bottom surface BS2 is Wa2.

Specifically, the slot CAV in the present embodiment forms a groove corresponding to the “ [symbol] ” shaped two-layer structure of the LED chip CPb, where the width Wa1 is less than the width Wa2. In some embodiments, the width Wa2 is 110% to 200% of the width Wa1, but the present invention is not limited thereto. In addition, in the present embodiment, the total height of Ha1 and Ha2 (i.e., the depth of the slot CAV) is designed to be greater than the width Wa1, so as to limit the LED chip CPb to correctly fall into the slot CAV only when the first part P1 faces toward the first accommodating space (i.e., the first part P1 is located in the first accommodating space, and the second part P2 is located in the second accommodating space).

In certain embodiments, the width Wa1/Wa2 of the slot CAV may be 101% to 140% of the width Wcp1/Wcp2 of the LED chip CPb, and the depth Ha1/Ha2 of the slot CAV may be 101% to 140% of the height Hcp1/Hcp2 of the LED chip CPb, but the present invention is not limited thereto.

In some embodiments, the width Wa2 may be, for example, a value selected from a numerical range greater than 5 μm and less than 100 μm, but the present invention is also not limited thereto.

With the above structural configuration, if the LED chip CPb falls into the slot CAV with the first part P1 not facing toward the first accommodating space, it will be easily vibrated away from the slot CAV during the action of the alignment force, thus preventing the LED chip CPb from being disposed in the slot CAV of the alignment substrate in an unintended manner and resulting in subsequent mass transfer failure. On the other hand, once the LED chip CPb correctly falls into the slot CAV, the LED chip CPb is more easily restricted by the side walls SW1/SW2 and the bottom surfaces BS1/BS2 during vibration or other acting forces, without easily detaching from the slot CAV and being vibrated out again. Therefore, the alignment success rate of the alignment substrate may be ensured. In sum, the mass transfer apparatus and the mass transfer method thereof proposed in the embodiments of the present invention may use an adhesive substrate configuration with a rigid layer and an adhesive layer to transfer the target objects on the source substrate to the target substrate in a single action, thereby effectively improving the efficiency of mass transfer. In addition, through the application of the intermediate alignment substrate, the mass transfer apparatus in the embodiments of the present invention may arrange the target objects on the source substrate according to the required target substrate size, and transfer all the target objects aligned by the alignment substrate to the target substrate at one time, further improving the efficiency of mass transfer between substrates of different sizes. In addition, the alignment substrate proposed in the embodiments of the present invention may form a slot structure that adapts to the LED chip with a two-layer structure, such that the LED chip may correctly fall into the corresponding slot during the alignment process, without being easily vibrated out again after falling into the slot, thereby improving the alignment success rate.

Referring to FIG. 11C, the present embodiment illustrates an example of an alignment substrate SUBa3 with another slot CAV structure. In the present embodiment, the slot CAV on the alignment substrate SUBa3 is designed to accommodate an LED chip CPc with a trapezoidal structure. Specifically, the LED chip CPc with a trapezoidal structure has an upper base width of Wcp1, a lower base width of Wcp2, and a height of Hcp. The chip body and the electrode part may be, for example, disposed on the side close to the upper base, but the present invention is not limited thereto.

On the other hand, the slot CAV in the present embodiment is provided corresponding to the trapezoidal structure of the LED chip CPc. The slot CAV has a bottom surface width of Wa1, a top opening width of Wa2, and a depth of Ha. In the present embodiment, the bottom surface width Wa1 of the slot CAV may be designed to be between 101% and 140% of the upper base width Wcp1 of the LED chip CPc, and the top opening width Wa2 of the slot CAV may be designed to be between 101% and 140% of the lower base width Wcp2 of the LED chip CPc, such that the shape of the slot CAV substantially conforms to and is slightly larger than the volume of the LED chip CPc, but the present invention is not limited thereto.

Viewing from another perspective, the trapezoidal structure of the slot CAV on the alignment substrate SUBa3 is formed by a bottom surface BS1 and a side wall SW1. The bottom surface BS1 is located at the bottom of the slot CAV, and the side wall SW1 surrounds a periphery of the bottom surface BS1. The bottom of the side wall SW1 is connected to the bottom surface BS1. In the present embodiment, at least one surface of the side wall SW1 is not perpendicular to the bottom surface BS1. If the side wall SW1 is formed in a cylindrical shape, the at least one surface may refer to the tangent plane of the cylinder. In other words, as long as the cross-sectional structure of the slot CAV along a section line (such as AA′) has a structural feature that the side wall SW1 and the bottom surface BS1 are not perpendicular, it belongs to the trapezoidal structure as described.

Referring to FIG. 11D, the present embodiment illustrates an example of an alignment substrate SUBa4 with another slot CAV structure. In the present embodiment, a cuboid-shaped slot CAV is formed on the substrate body of the alignment substrate SUBa4. The cuboid-shaped slot CAV may be used to accommodate a cuboid-shaped LED chip CPa, where the width of the LED chip CPa is Wcp, the height thereof is Hcp, the width of the slot CAV is Wa, and the depth thereof is Ha.

In the present embodiment, a micro-hole structure VH is also provided at the bottom of the slot CAV. One end opening of the micro-hole structure VH is exposed on the bottom surface of the slot CAV, and the other end opening is exposed on the bottom surface of the alignment substrate SUBa4. With the configuration of the present embodiment, the alignment actuation portion may adsorb the LED chip disposed in the slot CAV through the micro-hole structure VH.

Referring to FIG. 11E, the present embodiment illustrates an example of an alignment substrate SUBa5 with another slot CAV structure. The present embodiment is similar to the embodiment of FIG. 11D as described above, and the main difference between the two embodiments exists in that the alignment substrate SUBa5 in the present embodiment further includes a conductive layer CL. The conductive layer CL is located at the bottom of the slot CAV. When the LED chip CPa is disposed in the slot CAV, at least one electrode of the LED chip CPa is electrically connected to the conductive layer CL. Thus, by energizing the conductive layer CL, electrical/light-emitting inspection of the LED chip CPa may be realized on the alignment substrate SUBa5.

Referring to FIG. 11F, the present embodiment illustrates an example of an alignment substrate SUBa6 with another slot CAV structure. In the present embodiment, a cuboid-shaped slot CAV is formed on the substrate body of the alignment substrate SUBa6. The cuboid-shaped slot CAV may be used to accommodate an LED chip CPd with a trapezoidal structure. Specifically, the LED chip CPd with a trapezoidal structure has an upper base width of Wcp1, a lower base width of Wcp2, and a height of Hcp. In the present embodiment, the width Wa of the slot CAV may be designed to be slightly greater than the lower base width Wcp2 of the LED chip CPd, such that the LED chip CPd may be configured with the lower base in contact with the bottom surface BS of the slot CAV when it falls into the slot CAV.

In addition, the alignment substrate SUBa6 also includes an electromagnetic generating component EM, which may be used to generate a magnetic force with a specific direction under the control of the power provided by the alignment actuation portion. The electromagnetic generating component EM is, for example, an electromagnet.

The LED chip CPd includes a chip body cb and a magnetic component MU. The chip body cb may be, for example, disposed on the side close to the upper base, and the magnetic component MU may be, for example, a permanent magnet disposed on the side close to the lower base, but the present invention is not limited thereto. During the mass transfer using the alignment substrate SUBa6, the LED chip CPd may fall into the slot CAV of the alignment substrate SUBa6 through the acting force applied by the alignment actuation portion (such as 250). Meanwhile, the alignment actuation portion 250 provides power to drive the electromagnetic generating component EM, such that the electromagnetic generating component EM generates a magnetic force that attracts/repels the magnetic component MU.

In certain embodiments, the electromagnetic generating component EM generates a magnetic force that attracts the magnetic component MU during the alignment process, such that the LED chip CPd falling into the slot CAV with the lower base side facing the bottom of the slot CAV may be stably adsorbed in the slot CAV in response to the magnetic force. On the other hand, if the LED chip CPd falls into the slot CAV with the upper base (i.e., the side where the chip body cb is disposed) facing the bottom of the slot CAV, the electromagnetic generating component EM generates a repulsive force to the magnetic component MU, thereby causing the LED chip CPd to flip to the configuration with the lower base side facing the bottom of the slot CAV during the alignment force. Thus, the flipping of misaligned chips may be realized, such that all LED chips CPd may face the same direction after alignment.

In certain embodiments, the electromagnetic generating component EM may also generate a repulsive force to the magnetic component MU during the alignment process, such that only when the LED chip CPd falls into the slot CAV with the upper base side facing the bottom of the slot CAV, it may be stably adsorbed in the slot CAV without being flipped again by the alignment force.

Specifically, when manufacturing the alignment substrate SUBa6 with the electromagnetic generating component EM, an electromagnet that may control the magnitude of the magnetic force by applying power is usually made by winding a coil around an iron core, and then the electromagnet is disposed at the bottom of the slot CAV of the alignment substrate SUBa6, thereby realizing the structure of the alignment substrate SUBa6 that may adsorb the LED chip CPd. However, in order to realize the alignment function using the magnetic force, the LED chip CPd must be customized to implant a magnet, and the electromagnetic generating component EM must also be embedded in the alignment substrate SUBa6, which lead to high costs for mass transfer.

In addition, the alignment control using the electromagnetic generating component EM must be performed with experimental tests repeatedly to adjust the magnetic force parameters of the alignment substrate SUBa6 to be able to smoothly align and flip the LED chip CPd to face the same direction, and to simultaneously avoid the situation where the magnetic LED chips CPd attract each other and thus cannot be aligned.

Furthermore, the electromagnetic generating component EM formed by the coil needs to adjust the magnetic force parameters by changing the number of turns of the coil, the magnitude of the current, and the material of the central conductor. Therefore, during the experimental testing process, the adjustment process of the magnetic force parameters is also relatively complicated and the timeliness is poor, which is not conducive to the smooth progress of the production process.

Referring to FIG. 11G, the present embodiment illustrates an example of an alignment substrate SUBa7 with another slot CAV structure. In the present embodiment, a cuboid-shaped slot CAV is formed on the substrate body of the alignment substrate SUBa7. The cuboid-shaped slot CAV may be used to accommodate an LED chip CPc with a trapezoidal structure. Specifically, the LED chip CPc with a trapezoidal structure has an upper base width of Wcp1, a lower base width of Wcp2, and a height of Hcp. In the present embodiment, the width Wa of the slot CAV may be designed to be slightly larger than the lower base width Wcp2 of the LED chip CPc, such that the LED chip CPc may be configured with the lower base in contact with the bottom surface BS of the slot CAV when it falls into the slot CAV.

In the present embodiment, the alignment substrate SUBa7 includes a substrate body BD, a plurality of slots CAV arranged in an array, material accommodating portions MA and magnetic structures MI corresponding to the slots CAV. The cuboid-shaped slot CAV may be used to accommodate an LED chip CPc with a trapezoidal structure. The LED chip CPc with a trapezoidal structure has an upper base width of Wcp1, a lower base width of Wcp2, and a height of Hcp.

In the present embodiment, the LED chip CPc is made of, for example, a material containing ferromagnetic elements (such as iron, nickel). For example, the LED chip CPc may be a micro-LED chip made of a copper magnetic wafer (CMW).

In the present embodiment, the width Wa of the slot CAV may be designed to be slightly greater than the lower base width Wcp2 of the LED chip CPc, such that the LED chip CPc may be configured with the lower base in contact with the bottom surface BS of the slot CAV when it falls into the slot CAV. The material accommodating portions MA are respectively formed at the bottom of the slots CAV of the substrate body BD. The material accommodating portions MA may be through holes or grooves. The material accommodating portions MA correspond to the lower base side of the LED chip CPc (i.e., the side away from the chip body cb). As shown in FIG. 7G, the material accommodating portions MA in the present embodiment are through holes as an example, but the present invention is not limited thereto. In the present embodiment, the magnetic structures MI may be formed of, for example, a curable magnetic material, and are disposed in the material accommodating portions MA.

Specifically, during the manufacturing process of the alignment substrate SUBa7, the magnetic material in an uncured state (for example, a flowable state) may be injected into the material accommodating portions MA in each slot CAV, and the magnetic structure MI is formed after the magnetic material is cured.

The so-called uncured state herein is not particularly limited, as long as the curable magnetic material may be injected into the material accommodating portion MA. In other words, the curable magnetic material may be a fluid. From the perspective of material viscosity, the viscosity of the curable magnetic material only needs to be such that it may remain in the material accommodating portion MA when it is cured. Regarding the curing process, it is acceptable as long as the curable magnetic material may be cured, and air drying, natural drying or other methods may be used, and the present invention is not limited thereto.

In addition, the curable magnetic material injected into the material accommodating portion MA only needs to be a magnetic material, such as a magnetic fluid. The components of the curable magnetic material preferably include carbon (C), oxygen (O), and iron (Fe), where the content of carbon (C) is 42.8%, the content of oxygen (O) is 19.5%, and the content of iron (Fe) is Fe-37.7%, but it is not limited thereto. The contents of the above components may also be increased or decreased as long as the material has magnetism.

After the curable magnetic material injected into the material accommodating portion MA is cured to form the magnetic structure MI, the bottom of the slot CAV of the substrate body BD may have magnetism.

When the user uses the alignment substrate SUBa7 of the present embodiment to align the LED chips CPc, the magnetic structure MI of the alignment substrate SUBa7 may effectively adsorb the ferromagnetic substrate of the LED chips CPc at the bottom of the slot CAV, thereby achieving the effect of making the surfaces of all the LED chips CPc face the same direction.

In the present embodiment, since the material accommodating portion MA is a through-hole structure, the amount of curable magnetic material may be easily increased or decreased to adjust the magnetic force parameters during the testing of the alignment substrate SUBa7. For example, when it is desired to reduce the curable magnetic material, the curable magnetic material may flow out from the bottom of the material accommodating portion MA to reduce the amount; when it is desired to increase the curable magnetic material, it may be injected from the top of the material accommodating portion MA. By increasing or decreasing the amount of the curable magnetic structure MI in the above manner, the magnetic force of the finally formed magnetic structure MI may be quickly controlled, thereby quickly changing the magnetic force parameters of the alignment substrate SUBa7, and reducing the manufacturing and testing costs of the alignment substrate SUBa7.

In addition, since the magnetic structure MI is only provided at the bottoms of the slots CAV arranged in an array, only the bottoms of the slots CAV have magnetism, and other parts of the substrate body BD do not have magnetism. Moreover, in certain embodiments, the material accommodating portion MA may be set to have a certain distance from the inner side wall SW of the corresponding slot CAV. Thus, during alignment, the LED chip CPc may be made to fit as close as possible to the bottom surface BS of the slot CAV, thereby effectively avoiding the LED chip CPc from being obliquely accommodated in the slot CAV.

In certain embodiments, when viewing the substrate body BD from above, the cross-sectional area of the material accommodating portion MA is smaller than the bottom area of the LED chip CPc. In other words, when the LED chip CPc falls into the slot CAV and is adsorbed by the magnetic structure MI, it covers the entire material accommodating portion MA, thus achieving the effect of making the LED chip CPc fit as close as possible to the bottom surface BS of the slot CAV, thereby effectively avoiding the LED chip CPc from being obliquely accommodated in the slot CAV.

Referring to FIG. 11H, the present embodiment illustrates an example of an alignment substrate SUBa8 with another slot CAV structure. In the present embodiment, a cuboid-shaped slot CAV is formed on the substrate body of the alignment substrate SUBa8. The cuboid-shaped slot CAV may be used to accommodate an LED chip CPc with a trapezoidal structure.

Specifically, the present embodiment is substantially identical to the embodiment of FIG. 11G as described above. The main difference between the two embodiments exists in that the structure of the material accommodating portion MA in the present embodiment is a groove as an example, that is, the bottom of the substrate body is not penetrated. Other identical or similar features and/or advantages may be referred to the description of the above embodiment, and are not further reiterated herein.

Through the embodiments of the present invention, the alignment substrate may easily have magnetism, such that a plurality of LED chips with ferromagnetism arranged in any direction may be flipped to face the same direction and be aligned and accommodated in the slots of the substrate body. In addition, since the alignment substrate sets the curable magnetic material in the material accommodating portion located at the bottom of the slot, the dosage of the curable magnetic material may be easily adjusted before the magnetic material is cured, thereby achieving the effect of quickly changing the magnetic force parameters of the alignment substrate.

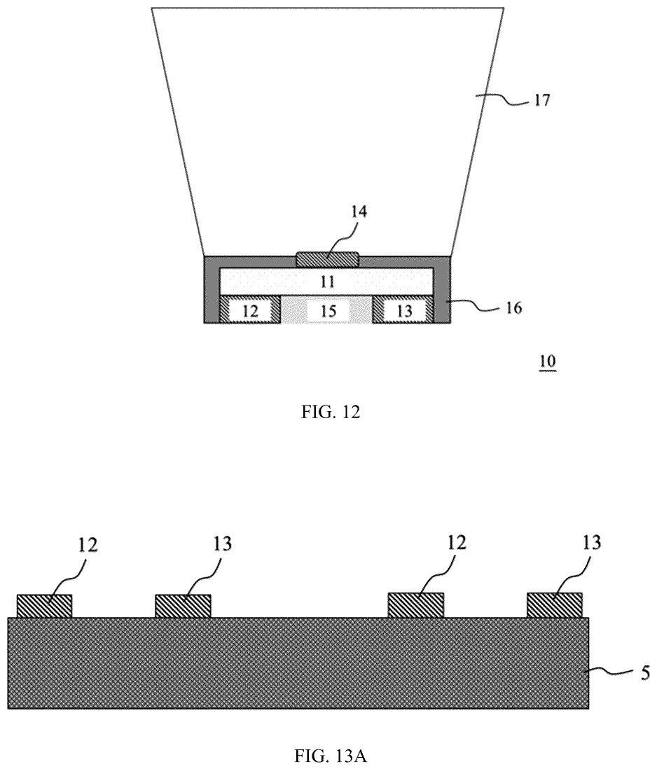

FIG. 12 is a schematic view of the structural configuration of an LED chip according to certain embodiments of the present invention. Referring to FIG. 12, the LED chip 10 as described in the present embodiment may be applied to the aforementioned embodiments in FIGS. 8A to 8K and FIG. 11C, but is not limited thereto. In the present embodiment, the LED chip 10 includes a light emitting layer 11, a first electrode 12, a second electrode 13, a third electrode 14, an insulating layer 15, a sacrificial layer 16, and a mass transfer layer 17. The first electrode 12 and the second electrode 13 are disposed on one side of the light emitting layer 11, and the third electrode 14 is disposed on the other opposite side of the light-emitting layer 11. The insulating layer 15 is disposed on the same side as the first electrode 12/second electrode 13, and is formed between the first electrode 12 and the second electrode 13. The sacrificial layer 16 is formed on a surface of the light emitting layer 11 where the third electrode 14 is disposed, and extends to the sides of the light-emitting layer 11 and the first electrode 12/second electrode 13. The mass transfer layer 17 is formed on the sacrificial layer 16 and the third electrode 14, and is electrically connected to the third electrode 14, and a thickness thereof may be defined according to the slot depth of the alignment substrate.

In the present embodiment, the first electrode 12 and the second electrode 13 may be, for example, configured as square-ring electrodes. The hollow part in the middle of the square-ring shape may facilitate electrical lighting tests during the mass transfer process and prevent the light emitted by the light emitting layer 11 from being blocked, but the present invention is not limited thereto. The third electrode 14 may be, for example, configured as a circular electrode, but the present invention is also not limited thereto. In addition, the first electrode 12, the second electrode 13, and the third electrode 14, in addition to being used as conductive interfaces, may also provide supporting functions in the subsequent mass transfer process.

The insulating layer 15 is used to electrically isolate the first electrode 12 and the second electrode 13. The insulating layer 15 may be a transparent insulating layer, so as to avoid blocking the light emission of the light emitting layer 11 during subsequent electrical tests in the mass transfer process.

The sacrificial layer 16 is formed of a material that is easily removable, such as an organic material or an organic polymer. The sacrificial layer 16 is an interface for connecting the mass transfer layer 17 and the light-emitting layer 11 during the mass transfer process, and is a part removable by chemical methods or other methods after the mass transfer is completed.

The mass transfer layer 17 may be configured as a trapezoid or other shapes that may identify directions (such as an asymmetrical cross-sectional structure). Taking an example of using a trapezoidal configuration as shown in FIG. 12, the upper base width of the mass transfer layer 17 is set to correspond to the thickness of the light emitting layer 11/sacrificial layer 16, and the lower base width of the mass transfer layer 17 is designed to be greater than the upper base width to form a trapezoidal structure. During the mass transfer process, the mass transfer layer 17 corresponding to the slot shape of the alignment substrate may make the LED chip 10 fall into the slot in a set direction, thereby avoiding the problem of inconsistent directions of the LED chips 10 in different slots. In the present embodiment, the mass transfer layer 17 may be made of, for example, a conductive material, such as a nickel-iron alloy. In this way, during electrical testing, electrical signals may be applied to the third electrode 13 through the mass transfer layer 17.

It should be noted that the trapezoidal structure part may be configured to be removed together with the sacrificial layer 16 in a subsequent process. Therefore, this structural feature may not necessarily be directly observable in the final product after the transfer is completed. However, as long as the structure mentioned in the present invention is used during the transfer or manufacturing processes, it should be stated herein that the structure, even if not existing in the end, should also fall within the trapezoidal structure defined in the present invention. In addition, the asymmetrical cross-sectional structure may be, for example, that the width of the bottom of the mass transfer layer 17 is different from the width of the top.

Viewing from another perspective, the LED chip 10 includes a light emitting part (i.e., the light emitting layer 11, the first electrode 12, the second electrode 13, the third electrode 14, and the insulating layer 15) that continues to be retained after the mass transfer is completed, and a mass transfer part (i.e., the sacrificial layer 16 and the mass transfer layer 17) that is removed after the mass transfer is completed. The mass transfer part is used as a contact interface for picking and disposing during the mass transfer process. In other words, in a final product where the LED chip 10 is configured on the target substrate, the mass transfer part will not be observed.

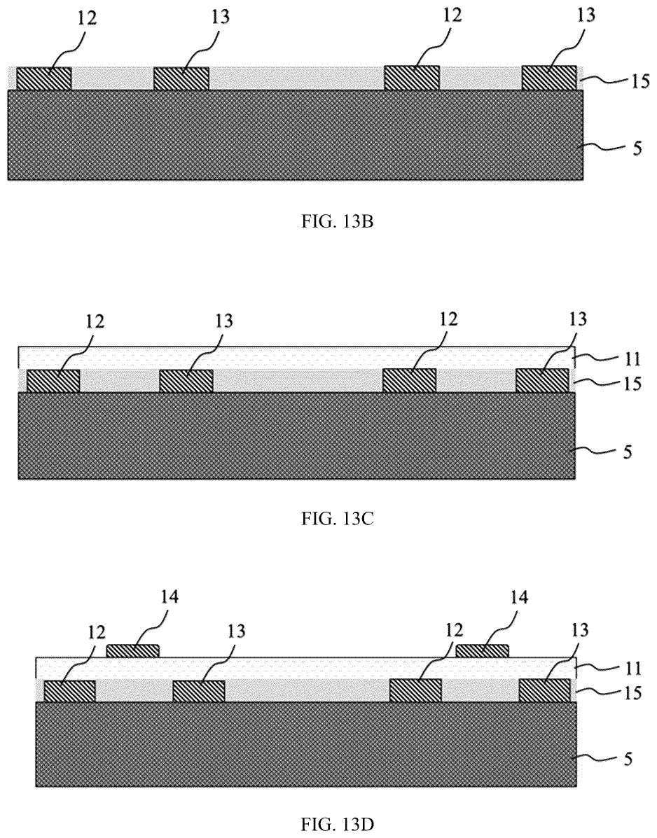

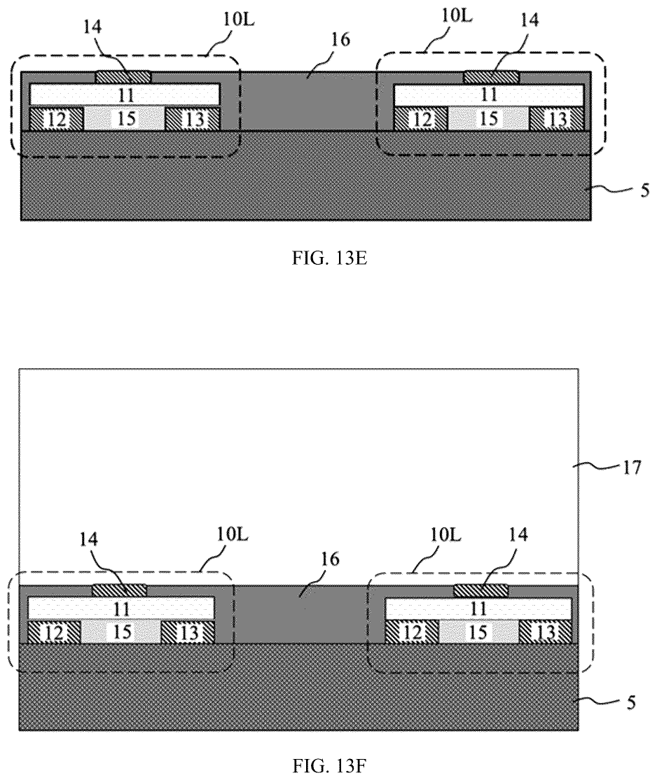

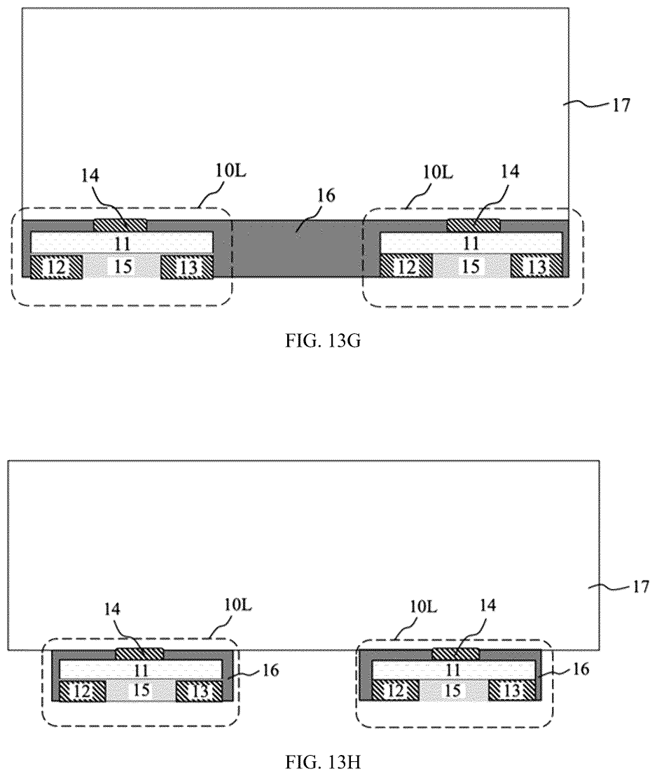

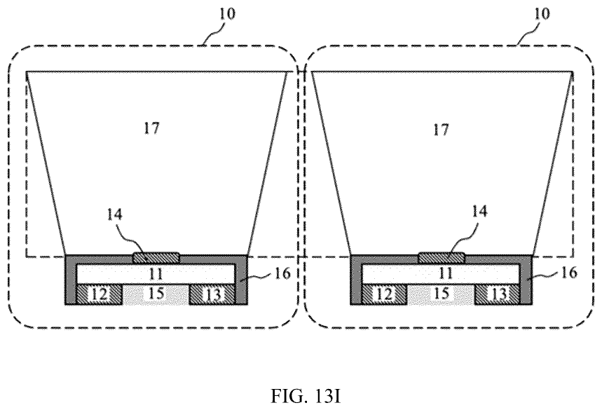

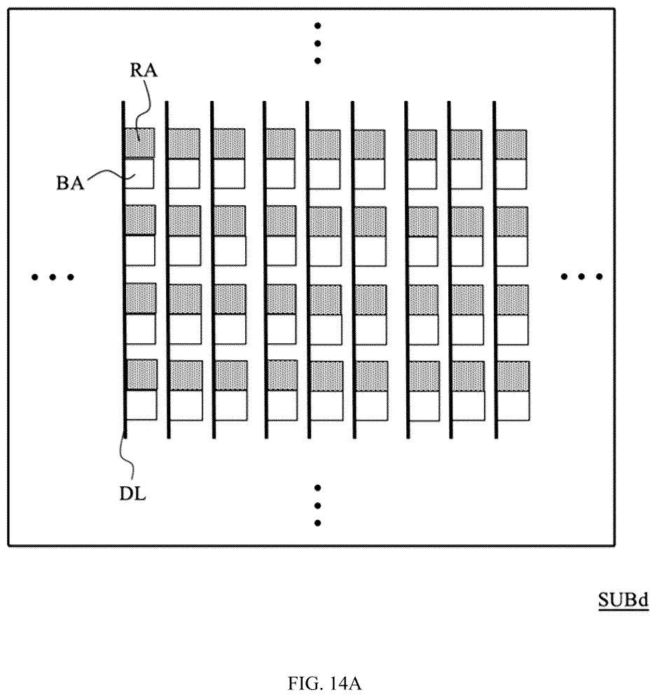

FIGS. 13A to 13I are schematic views of the manufacturing process of the LED chips according to certain embodiments of the present invention. The manufacturing process of the LED chips described in the present embodiment may be used to manufacture the LED chip 10 as described in the previous embodiment of FIG. 12. Firstly, referring to FIG. 13A, in the manufacturing process of the LED chips, a plurality of first electrodes 12 and second electrodes 13 are alternately disposed on a substrate 5. The substrate 5 may be, for example, a silicon substrate or other semiconductor material.

After the first electrodes 12 and the second electrodes 13 are formed, a transparent insulating layer 15 is formed on the substrate 5 and filled between the first electrodes 12 and the second electrodes 13 to electrically isolate each electrode, as shown in FIG. 13B.

Next, as shown in FIG. 13C, a light emitting layer 11 is formed on the first electrodes 12, the second electrodes 13 and the insulating layer 15. Those skilled in the art should understand that the light emitting layer 11 may have different structural configurations depending on the selected manufacturing process and the required color.

After the light emitting layer 11 is formed, the third electrodes 14 are disposed on the light emitting layer 11, as shown in FIG. 13D. Then, as shown in FIG. 13E, after removing the excess light emitting layer 11 and the insulating layer 15, a plurality of light emitting parts 10L of the LED chips are formed. After the light emitting parts 10L are formed, a removable sacrificial layer 16 is formed on the light emitting parts 10L, and a mass transfer layer 17 is formed on the sacrificial layer 16, as shown in FIG. 13F.

Next, as shown in FIGS. 13G to 13I, after removing the substrate 5 and the excess sacrificial layer 16, the shape of the mass transfer layer 17 is adjusted to have a trapezoidal cross-sectional structure corresponding to the shape of the slots of the alignment substrate by laser cutting, etching, or other methods. Thus, the manufacturing of the LED chip 10 is completed. Subsequent back-end processing such as mixed cleaning may be performed on each LED chip 10 to remove residual glue or other foreign matter. After cleaning, the subsequent mass transfer process may be performed.

In one embodiment of the present invention, the LED chips (such as CP, 10) transferred and disposed on the target substrate may be LED chips with the same wavelength range, or multi-color LED chips with different wavelength ranges, such as the blue light wavelength range, the red light wavelength range, and the green light wavelength range.

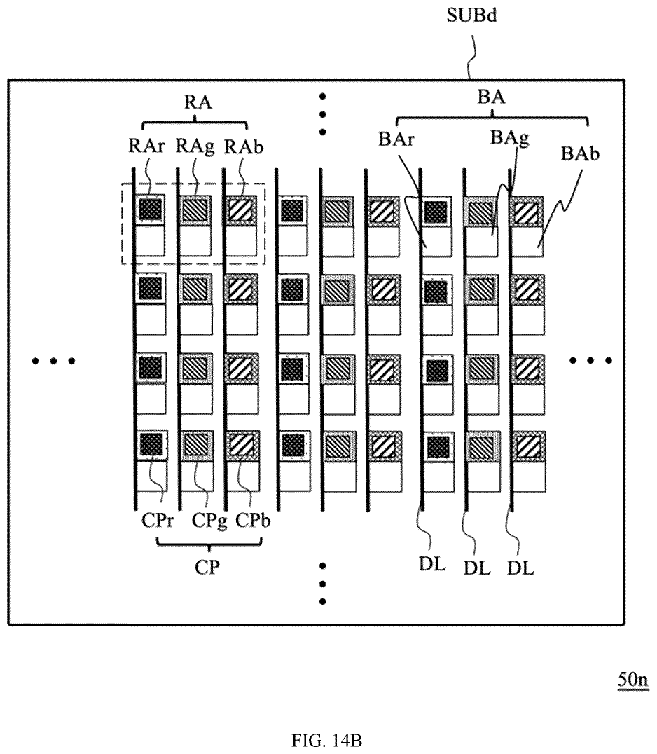

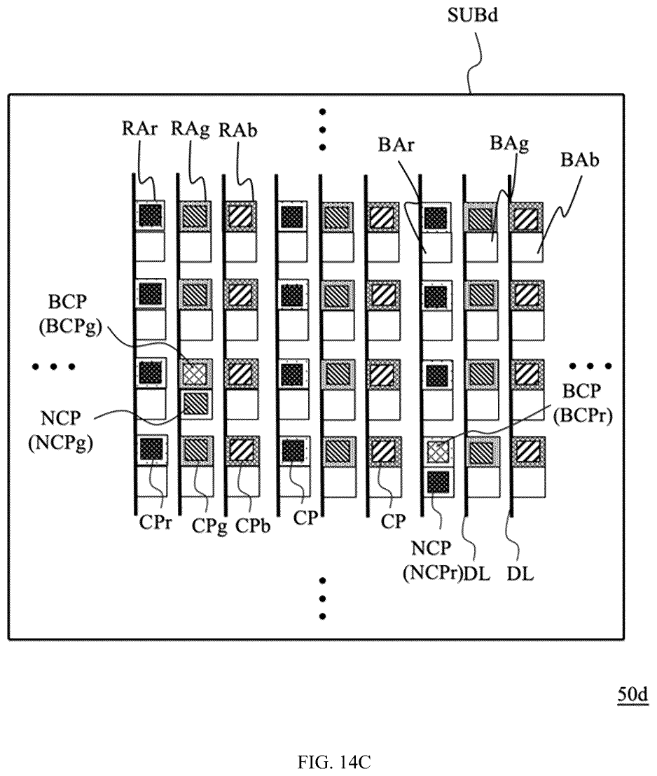

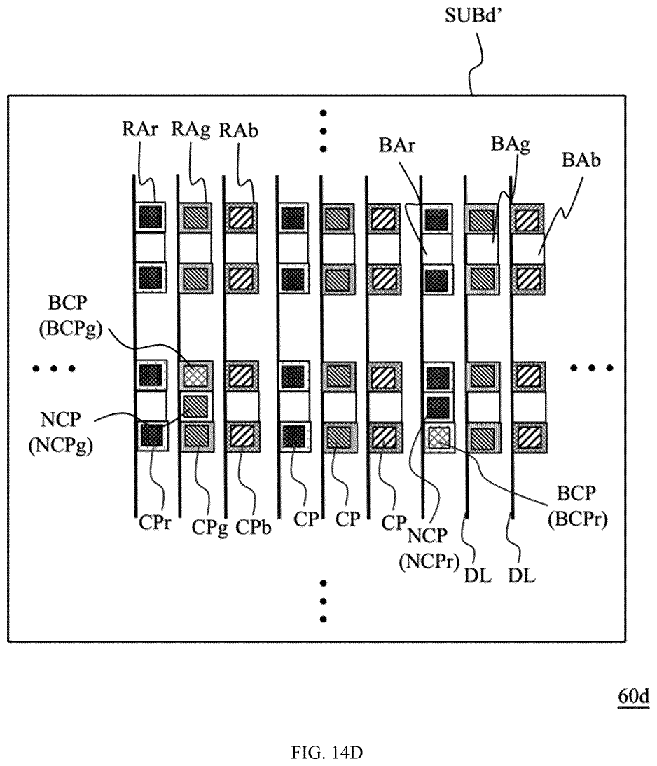

After the mass transfer process is completed, the LED chips are moved to specific positions on the target substrate (such as a display substrate) to form a final product (such as a display panel) or a semi-finished product of the final product. Then, in the manufacturing process, an inspection and repair process is further performed on the LED chips being transferred. Several structural configuration embodiments are used with reference to FIGS. 14A to 14D to describe the display panel after the mass transfer is completed, and to further describe the inspection and repair process under different structural configurations.

Firstly, referring to FIG. 14A, the present embodiment illustrates a schematic view of the structural configuration of a display substrate SUBd as a target substrate. In the present embodiment, the display substrate SUBd is formed with a plurality of signal lines DL, and includes a plurality of configuration regions RA and a plurality of spare regions BA.

The configuration regions RA and the spare regions BA are arranged in an array on the display substrate SUBd, and are used to receive a plurality of LED chips transferred by the mass transfer. In the present embodiment, the spare regions BA and the configuration regions RA are arranged alternately. For example, as shown in FIG. 14A, in the display substrate SUBd, each configuration region RA is provided with an adjacent spare region BA in the column direction. That is, in the column direction, a spare region BA is provided between two configuration regions RA.

It should be noted that, although the present embodiment illustrates that the spare region BA has a shorter distance from one of the two adjacent configuration regions RA, the present invention application is not limited thereto. Using FIG. 14A as an example, each spare region BA is adjacent to the configuration region RA on the upper side, but has a distance from the configuration region RA on the lower side. In other embodiments, the spare region BA may also be configured to be adjacent to the configuration regions RA on both the upper and lower sides simultaneously (with further descriptions in subsequent embodiments).

In addition, although FIG. 14A illustrates that the spare regions BA and the configuration regions RA are alternately arranged in a one-to-one manner in the column direction, the present invention is not limited thereto. In certain embodiments, the spare regions BA may also be provided only in the peripheral area or the central area of the display substrate SUBd, and may be actually configured in the regions where failures are more likely to occur according to the needs of the designer.

FIGS. 14B and 14C illustrate embodiments of the structural configuration of a display panel formed after the display substrate SUBd receives the LED chips CP being mass transferred. The display panel 50n in FIG. 14B illustrates a state where none of the LED chips CP have failed after mass transfer, and the display panel 50d in FIG. 14C illustrates a state where some of the LED chips CP have failed after mass transfer and have been repaired using the spare regions BA.

Firstly, referring to FIG. 14B, in the present embodiment, the LED chips CP are exemplified to include red light LED chips CPr, green light LED chips CPg, and blue light LED chips CPb. Therefore, the configuration regions RA in the present embodiment may be correspondingly configured to have three types of configuration regions, which are a plurality of blue light configuration regions RAb, a plurality of red light configuration regions RAr and a plurality of green light configuration regions RAg. The blue light configuration regions RAb are used to receive the blue light LED chips CPb, the red light configuration regions RAr are used to receive the red light LED chips CPr, and the green light configuration regions RAg is used to receive the green light LED chips CPg. As described above, the blue light configuration regions RAb, the red light configuration regions RAr and the green light configuration regions RAg are also arranged on the display substrate SUBd, respectively.

It should be noted and clarified that the red light LED chips CPr, the green light LED chips CPg and the blue light LED chips CPb described herein may also be understood as LED chips with light emission wavelengths being located in the red light wavelength range, the green light wavelength range and the blue light wavelength range, respectively.

When the configuration regions RA receive the LED chips CP that emit different colors of light, three adjacent configuration regions RA that receive the LED chips CP emitting different colors of light may be referred to as a pixel configuration region. The three adjacent LED chips CP emitting different colors of light in the pixel configuration region are regarded as one pixel. In other words, each pixel includes one blue light LED chip CPb, one red light LED chip CPr and one green light LED chip CPg, but it is not limited thereto. In other embodiments, one pixel may also include more than three LED chips CP.

A plurality of spare regions BA are provided on the display substrate SUBd and adjacent to the configuration regions RA, as shown in FIG. 14B. Each spare region BA is provided below each configuration region RA, but the present embodiment is not limited thereto. Each spare region BA may also be provided above each configuration region RA (not shown). The spare regions BA may also be electrically connected to the LED chips CP.

In an embodiment where the configuration regions RA are used to receive LED chips CP that emit different colors of light, the spare regions BA also have three types of configuration regions, which are a plurality of blue light spare regions BAb, a plurality of red light spare regions BAr and a plurality of green light spare regions BAg. The blue light spare regions BAb are adjacent to the blue light configuration regions RAb and are used to receive the blue light LED chips CPb. The red light spare regions BAr are adjacent to the red light configuration regions RAr and are used to receive the red light LED chips CPr. The green light spare regions BAg are adjacent to the green light configuration regions RAg and are used to receive the green light LED chips CPg. Therefore, each pixel configuration region has three spare regions BAr, BAg, and BAb corresponding to the three configuration regions RAr, RAg, and RAb.

In FIG. 14B, since the LED chips CP on the display substrate SUBd are determined to have no LED chip failures or damages after the mass inspection process, all the LED chips CP on the display panel 50n are disposed in the configuration regions RA and are electrically connected to the corresponding signal lines DL through the configuration regions RA.

On the other hand, referring to FIG. 14C, if some LED chips CP are inspected to be damaged in the inspection process, such that these LED chips CP are determined to be in a defective state, the defective LED chips are represented by the symbol “BCP,” and in the subsequent repair process, a new LED chip (represented by the symbol “NCP”) is disposed in the spare region BA adjacent to the configuration region RA where a defective LED chip BCP is located to replace the defective LED chip BCP.

For example, as shown in FIG. 14C, if the defective LED chips BCP are a green light LED chip BCPg and a red light LED chip BCPr, a new green light LED chip NCPg and a new red light LED chip NCPr are disposed in the corresponding green light spare region BAg and the corresponding red light spare region BAr in the repair process, respectively. Thus, the embodiment of the present invention may save the process of removing the defective LED chips, and directly install the corresponding new LED chips on the target substrate, thereby achieving the beneficial effect of rapid repair.

FIG. 14D illustrates another structural configuration of the display panel according to one embodiment of the present application. Referring to FIG. 14D, the main difference between the present embodiment and the previous FIGS. 14B and 14C exists in that, in the present embodiment, each spare region BAr, BAg, and BAb in the column direction of the display panel 60d is adjacent to the nearest two configuration regions RAr, RAg, and RAb, respectively. In other words, the two adjacent configuration regions RAr/RAg/RAb that receive the LED chips CPr/CPg/CPb and emit the same color of light share one spare region BAr/BAg/BAb. That is, two adjacent pixel configuration regions share three spare regions BAr, BAg, and BAb. Specifically, as shown in FIG. 14D, a blue light spare region BAb is located between two blue light configuration regions RAb arranged in the column direction of the display substrate SUBd′, a red light spare region BAr is located between two red light configuration regions RAr arranged in the column direction of the display substrate SUBd′, and a green light spare region BAg is located between two green light configuration regions RAg arranged in the column direction of the display substrate SUBd′, but the embodiment of the present invention is not limited thereto.

Therefore, through the configuration of the present embodiment, the LED chips may be arranged more closely on the display substrate SUBd, thereby reducing the size of the display panel.

In sum, through the structural configurations of the display panel and the display substrate thereof according to the embodiments of the present application, regardless of whether the configuration region RA above or below a spare region BA has a defective LED chip BCP, a new LED chip NCP may be received through the adjacent spare region BA to replace the defective LED chip BCP, thus omitting the process of removing the defective LED chip, and the corresponding new LED chip is directly installed on the target substrate, thereby achieving the beneficial effect of rapid repair, and the size design of the target substrate is reduced by sharing the spare region.

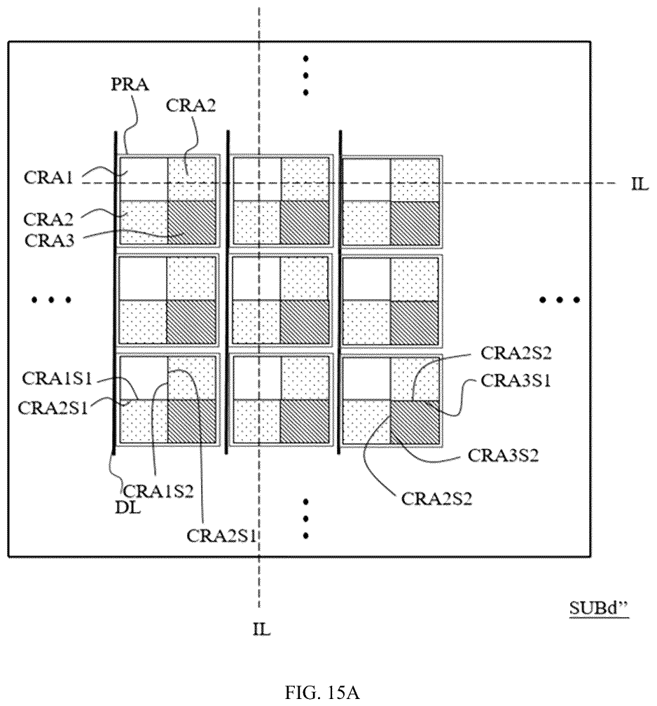

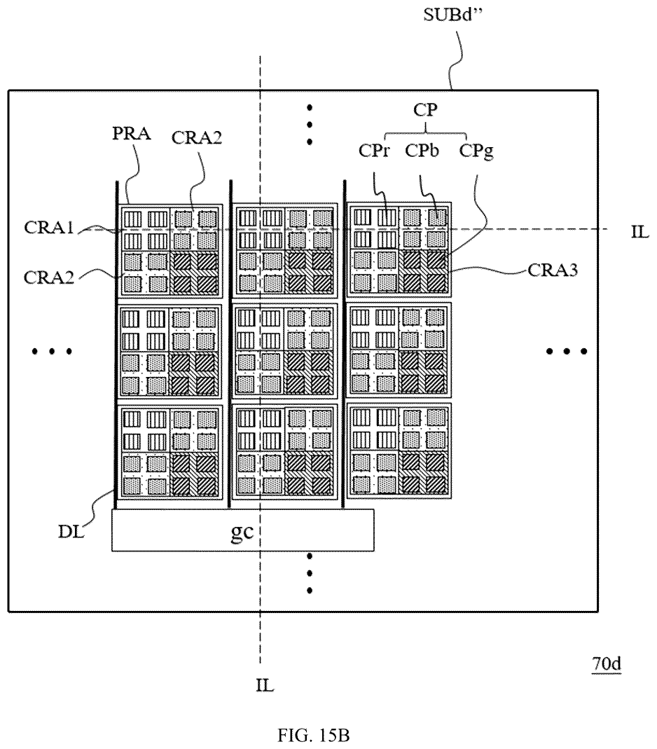

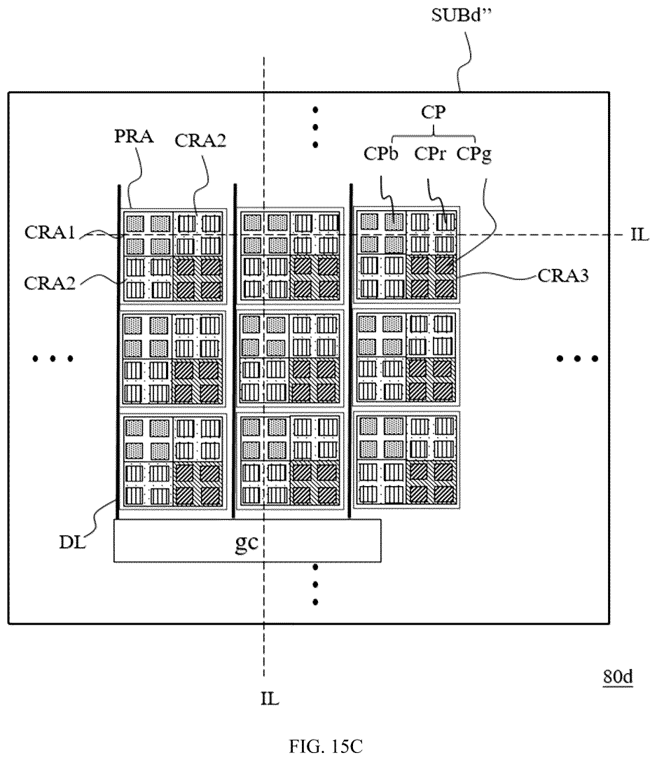

As described above, in the manufacturing process, the LED chips being transferred undergo further inspection and repair processes. However, the equipment used for picking and disposing the LED chips and the solder used for reflow soldering in the repair process often encounter various limitations when applied to small-sized LEDs, resulting in problems with difficulties to repair. Several structural configuration embodiments are used with reference to FIGS. 15A to 15C to describe the display panel after mass transfer is completed, such that even if there are defective LED chips, light emission is performed well, thus avoiding the problem with difficulties to repair.

Referring to FIGS. 15A and 15B, the present embodiment illustrates schematic views of the structural configuration of a display substrate SUBd″. In the present embodiment, the display substrate SUBd″ is formed with a plurality of signal lines DL, and includes a plurality of pixel configuration regions PRA.

The pixel configuration regions PRA are arranged in an array on the display substrate SUBd″ and are used to receive a plurality of LED chips CP transferred by mass transfer. Specifically, each pixel configuration region PRA is configured with a plurality of LED chips CP, and the pixel configuration region PRA is a region for receiving three types of the LED chips CP that emit different colors of light. Three adjacent LED chips CP that emit different colors of light within the pixel configuration region PRA are considered one pixel. In other words, each pixel includes at least one blue LED chip CPb, at least one red LED chip CPr and at least one green LED chip CPg, but is not limited thereto.

Each pixel configuration region PRA has the following three types of configuration regions: first chip configuration regions CRA1, second chip configuration regions CRA2 and third chip configuration regions CRA3. Each first chip configuration region CRA1 may be configured to accommodate two LED chips CP with a first wavelength in each row and column. Each second chip configuration region CRA2 may be configured to accommodate two LED chips CP with a second wavelength in each row and column. Each third chip configuration region CRA3 may be configured to accommodate two LED chips CP with a third wavelength in each row and column. Specifically, the first chip configuration region CRA1 in FIG. 15B has two LED chips CP with the first wavelength configured horizontally and two LED chips CP with the first wavelength configured vertically. The second chip configuration region CRA2 in FIG. 15B has two LED chips CP with the second wavelength configured horizontally and two LED chips CP with the second wavelength configured vertically. The third chip configuration region CRA3 in FIG. 15B has two LED chips CP with the third wavelength configured horizontally and two LED chips CP with the third wavelength configured vertically.

Each pixel configuration region PRA has one first chip configuration region CRA1, two second chip configuration regions CRA2 and one third chip configuration region CRA3. Two edges CRA1S1 and CRA1S2 adjacent to the first chip configuration region CRA1 correspond to one edge CRA2S1 of the two second chip configuration regions CRA2, respectively. Two edges CRA3S1 and CRA3S2 adjacent to the third chip configuration region CRA3 correspond to the other edge CRA2S2 of the two second chip configuration regions CRA2, respectively. Specifically, as shown in FIG. 15A, one edge CRA2S1 and the other edge CRA2S2 of each second chip configuration region CRA2 are adjacent to each other. The first chip configuration region CRA1 and any of the second chip configuration regions CRA2 are located on the same imaginary line IL. The first chip configuration region CRA1 and the third chip configuration region CRA3 are arranged in a corner-to-corner manner, and the two second chip configuration regions CRA2 are also arranged in a corner-to-corner manner.

Depending on the LED technology, the quantity of the LED chips CP that emit different colors of light varies. Using FIG. 15B as an example, each pixel configuration region PRA of the display panel 70d in the present embodiment may be configured with eight blue LED chips CPb, four red LED chips CPr, and four green LED chips CPg. Using FIG. 15C as another example, each pixel configuration region PRA of the display panel 80d in the present embodiment may be configured with four blue LED chips CPb, eight red LED chips CPr, and four green LED chips CPg.

In FIG. 15B, the LED chips CP with the first wavelength are red light LED chips CPr, so the first chip configuration region CRA1 is also referred to as a red light chip configuration region. The LED chips CP with the second wavelength are blue light LED chips CPb, so the second chip configuration regions CRA2 are also referred to as blue light chip configuration regions. The LED chips CP with the third wavelength are green light LED chips CPg, so the third chip configuration region CRA3 is also referred to as a green light chip configuration region.

In FIG. 15B, the LED technology used is to obtain white light by ultraviolent (UV) LEDs to excite three-color phosphors (RGB QD powder). Because the conversion rate of quantum dot blue (QD Blue) is poor, the second chip configuration regions CRA2 with a greater quantity in the pixel configuration region PRA are used as the blue light chip configuration regions to increase the quantity of the blue LED chips CPb, thereby resolving the problem of poor conversion rate of quantum dot blue (QD Blue).

In FIG. 15C, the LED chips CP with the first wavelength are blue light LED chips CPb, so the first chip configuration region CRA1 is also referred to as a blue light chip configuration region. The LED chips CP with the second wavelength are red light LED chips CPr, so the second chip configuration regions CRA2 are also referred to as red light chip configuration regions. The LED chips CP with the third wavelength are green light LED chips CPg, so the third chip configuration region CRA3 is also referred to as a green light chip configuration region.

In FIG. 15C, the LED technology used is RGB LED. Because the efficiency of red LED miniaturization is poor, the second chip configuration regions CRA2 with a greater quantity in the pixel configuration region PRA are used as the red light chip configuration regions to increase the quantity of the red LED chips CPr, thereby resolving the problem of poor efficiency of red LED miniaturization.

It should be noted that, although the present embodiment illustrates that each pixel configuration region PRA has the same spacing, the present invention is not limited thereto. The spacing size may be adjusted according to user needs.

FIG. 15A illustrates an embodiment of the structural configuration of the pixel configuration region PRA on the display substrate SUBd″. FIGS. 15B and 15C illustrate embodiments of the structural configuration of the display panel formed after the display substrate SUBd″ receives the LED chips CP being mass transferred, and the display panel in the figures illustrates a state where all the LED chips CP after the mass transfer have not failed.

As described above, the red LED chips CPr, the green LED chips CPg and the blue LED chips CPb described herein may also be understood as the LED chips with emission wavelengths being located in the red light wavelength range, the green light wavelength range and the blue light wavelength range, respectively.

In FIGS. 15B and 15C, all the LED chips CP are respectively configured in the pixel configuration regions PRA on the display substrate SUBd″ and are electrically connected to the corresponding signal lines DL through the pixel configuration regions PRA.

If an LED chip CP is inspected to be damaged in the inspection process, such that the LED chip CP is determined to be in a defective state, the remaining LED chips in good condition in the same chip configuration region as the LED chip CP determined to be in the defective state may still be used to assist in light emission, thereby eliminating the removal and repair processes. Thus, since there is no need to use the equipment for picking and disposing LED chips, and there is no need to perform reflow soldering, the problem with difficulties to repair is avoided. For example, although not shown in the figures, assuming that one LED chip CP (red light LED chip CPr) with the first wavelength in the first chip configuration region CRA1 (red light chip configuration region) in FIG. 15B is defective, even if the defective LED chip CP is not replaced, the other three good LED chips CP (red light LED chips CPr) with the first wavelength in the same first chip configuration region CRA1 may still be used to assist in light emission. Therefore, the same applies even if it occurs in the second chip configuration regions CRA2 or the third chip configuration region CRA3.

In addition, the display panels in FIGS. 15B and 15C may further include a color gamut control portion gc, which is electrically connected to a plurality of LED chips CP through a plurality of signal lines DL to adjust the brightness of at least one of the LED chips CP. Specifically, if an LED chip CP is inspected to be damaged in the inspection process, such that the LED chip CP is determined to be in a defective state, the color gamut control portion gc may be used to control the brightness (for example, increase the brightness) of the remaining LED chips in good condition in the same chip configuration region as the LED chip CP determined to be in the defective state to assist in light emission, thereby eliminating the removal and repair processes. Thus, since there is no need to use the equipment for picking and disposing the LED chips, and there is no need to perform reflow soldering, the problem with difficulties to repair is avoided.

In sum, through the structural configuration of the display panel and the display substrate thereof according to the embodiment of the present application, no matter which LED chip CP in the pixel configuration region PRA is determined to be in the defective state, the remaining LED chips in good condition in the same chip configuration region as the LED chip CP determined to be in the defective state may be used to assist in light emission. The process of removing the defective LED chip is eliminated, and the original LED chips disposed on the display substrate are directly utilized, thereby achieving the beneficial effect of rapid repair and avoiding the problem with difficulties to repair.

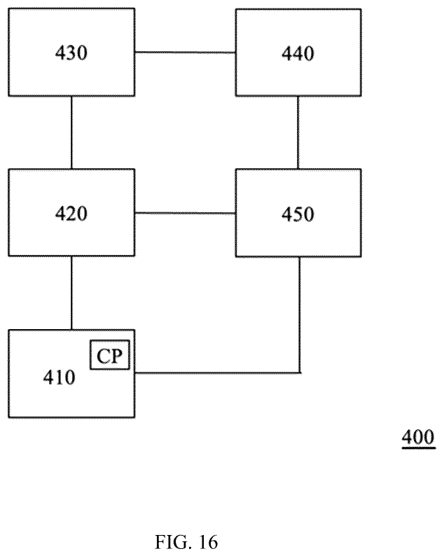

FIG. 16 is a schematic view of an electrical inspection apparatus according to one embodiment of the present invention. Referring to FIG. 16, the present embodiment relates to an electrical inspection apparatus 400, which is used to inspect the electrical properties (such as current characteristics, voltage characteristics and/or lighting characteristics, etc.) of at least one target object on a substrate 410. The target object CP may be, for example, a small-sized electronic component such as an LED chip, specifically, for example, a mini light-emitting diode (mini-LED) or a micro light-emitting diode (micro-LED), and the present invention is not limited thereto. The electrical inspection apparatus 400 of the present embodiment is particularly applicable for performing in-process electrical inspection of vertical micro-LED chips (especially in the stage after mass transfer and before the micro-LED chips are attached to the substrate). In other embodiments, the electrical inspection apparatus 400 may also be used to inspect the electrical properties of other types of target objects CP other than the LED chips. In one embodiment, the substrate 410 may be a target substrate for supporting the target objects CP being transferred.

In the present embodiment, the electrical inspection apparatus 400 includes a substrate 410, a jig portion 420, an inspection portion 430, a control portion 440 and a power supply portion 450. In the present embodiment, the substrate 410 is used to support a plurality of target objects CP being transferred, such as vertical micro-LED chips (hereinafter referred to as the LED chips). Therefore, the electrical inspection apparatus 400 may be used to inspect the electrical properties of the vertical micro-LED chips after the mass transfer.

The jig portion 420 is disposed opposite to the substrate 410 and has a transparent conductive structure. During electrical inspection, the jig portion 420 may cooperate with the substrate 410 as a lower electrode to apply an inspection voltage, so as to generate a voltage difference between the upper and lower electrodes of the LED chip, thereby driving the LED chip.

The inspection portion 430 is disposed opposite to the substrate 410 and the jig portion 420, such that the inspection range may cover at least part of the regions of the substrate 410 and the jig portion 420. The inspection portion 430 is used to perform electrical characteristic capturing on the substrate 410 and the jig portion 420. In certain embodiments, the inspection portion 430 may include one or more image capturing devices. During the electrical inspection process, a normal LED chip will be lit in response to the inspection voltage, such that the light beam may be transmitted from the jig portion 420 towards the inspection portion 430. The inspection portion 430 may use the brightness data of the LED chip as a basis for inspection and determination. In other words, the electrical characteristic may be, for example, the light emission brightness of the LED chip after being lit by the inspection voltage.

In some embodiments, the image capturing devices may be, for example, one of an optical microscope, a charge-coupled device (CCD) image sensor, a complementary metal-oxide semiconductor (CMOS) image sensor, and an industrial camera, or a combination thereof, and the present invention is not limited thereto.

The control portion 440 is coupled to the substrate 410, the jig portion 420, the inspection portion 430 and the power supply portion 450, and is used to control the operation of the inspection portion 430 and the power supply portion 450. In certain embodiments, the control portion 440 may be implemented by hardware, firmware, or software, and is not necessarily disposed inside the machine of the electrical inspection apparatus 400. For example, the control portion 440 may be implemented by an external computer, and the external computer may transmit signals to each module in the electrical inspection apparatus 400 through a specific transmission interface to achieve control.

In the present embodiment, the jig portion 420 is connected to the power supply portion 450, and the power supply portion 450 supplies the input of the inspection voltage and current. When the electrical inspection apparatus 400 performs electrical inspection (such as a lighting test) on the LED chip, the jig portion 420 may cooperate with the conductive substrate 410 (as a lower electrode) supporting the LED chips after the mass transfer. Specifically, during the lighting test, the electrical inspection apparatus 400 performs image capturing through the inspection portion 430. The inspection portion 430 is disposed on the side of the transparent jig portion 420 (for example, the position at the top of the figure). The light emitted after the LED chip is lit may pass through the transparent jig portion 420 and be captured by the inspection portion 430. The inspection data after being captured may be analyzed by the control portion 440. For example, the control portion 440 sets the image grayscale value per unit area, and determines whether the LED chip is lit by the difference in grayscale value.

Embodiments of the structure of the jig portion and the vertical micro-LED chip of the present invention are described as follows.

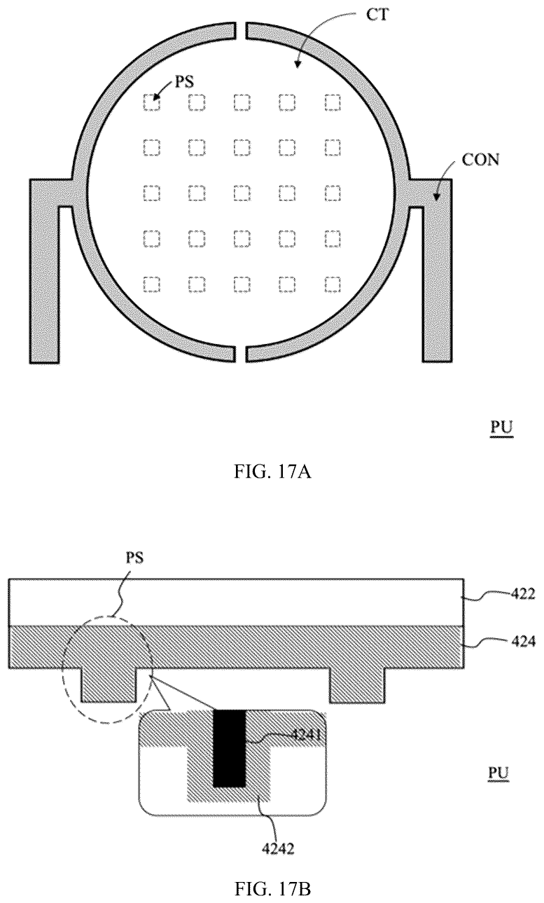

FIGS. 17A and 17B are schematic views of the structure of the jig portion according to one embodiment of the present invention, where FIG. 17A is a top view of the jig portion, and FIG. 17B is a cross-sectional view of the jig portion. Referring to FIGS. 17A and 17B simultaneously, the jig portion 420 of the present embodiment is, for example, a probe unit (PU). From the structural perspective, the probe unit PU has a contact portion CT and a conductive portion CON. The contact portion CT has a plurality of protruding structures PS, and the arrangement configuration of the protruding structures PS corresponds to the arrangement of the LED chips on the substrate 410, such that when the contact portion CT is in contact with an LED chip, each protruding structure PS is electrically connected to the upper electrode of the corresponding LED chip. The conductive portion CON is disposed in a peripheral area of the contact portion CT, and is used to transmit/conduct the inspection voltage received from the power supply portion to the contact portion CT.

From the configuration perspective, the probe unit PU includes a transparent substrate 422 and a transparent upper electrode jig 424. The protruding structures PS are located on the side of the upper electrode jig 424 close to the LED chips. The upper electrode jig 424 may be used to electrically connect to the upper electrodes of the LED chips. The upper electrode and its position of each LED chip may be customized to the transparent upper electrode jig 424. The electrical inspection apparatus 400 may generate a voltage difference between the upper and lower electrodes by applying power to the jig portion 420 and the lower electrode, thereby driving the LED chips to emit light. After the light beam passes through the above of the jig portion 420, the brightness inspection of the LED chip after the mass transfer is performed by the inspection portion 430. In certain embodiments, the transparent substrate 422 is, for example, a glass substrate, and the present invention is not limited thereto.

More specifically, in the upper electrode jig 424, each protruding structure PS may be formed by, for example, a photoresist material 4241 and a conductive film 4242. The photoresist material 4241 is spaced apart and formed on one side of the transparent substrate 422 with a certain thickness, and the conductive film 4242 covers the photoresist material 4241 and the surface of the transparent substrate 422 on the side. The photoresist material 4241 and the conductive film 4242 covering thereon form the protruding structure PS. In certain embodiments, the conductive film 4242 may be, for example, a high-transmission ITO conductive film, but the present invention is not limited thereto.

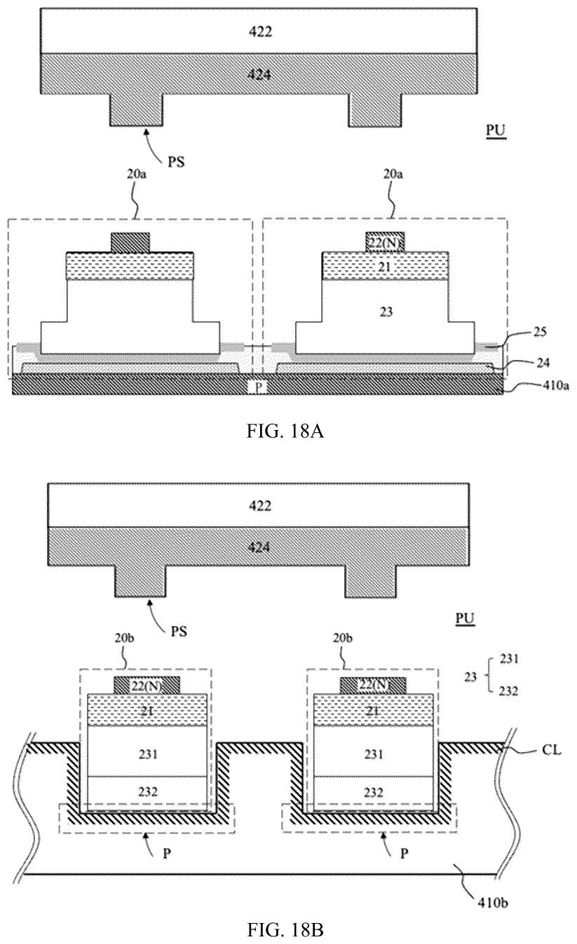

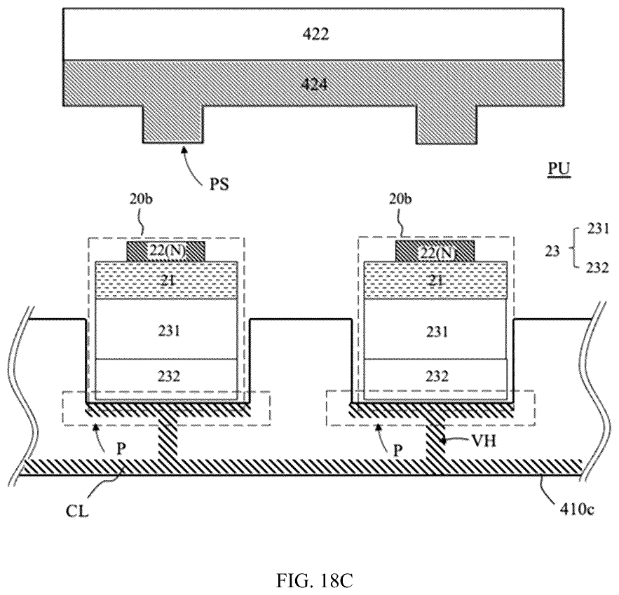

FIGS. 18A to 18C are schematic views of the inspection process of the electrical inspection apparatus according to different embodiments of the present invention. Firstly, referring to FIG. 18A, FIG. 18A shows a plurality of vertical micro-LED chips 20a (hereinafter referred to as the LED chips 20a) disposed on a substrate 410a after the mass transfer. The substrate 410a may be, for example, the target substrate SUBt in the previous embodiment, but the present invention is not limited thereto. Each LED chip 20a includes, for example, a light emitting layer 21, a plurality of metal layers 22-24, and a connection layer 25. The metal layer 22 is disposed on one side of the light emitting layer 21 (the upper side in the present embodiment), and is used as the upper electrode of the LED chip 20a (hereinafter referred to as the upper electrode 22). The metal layer 23 is disposed on the opposite side of the light-emitting layer 21, and is connected to the metal layer 24 on the side away from the light emitting layer 21 through the connection layer 25. When the LED chips 20a are disposed on the substrate 410a after the mass transfer, the metal layer 24 of each LED chip 20a is electrically connected to the substrate 410a, such that the substrate 410a may be regarded as the lower electrode of the LED chip 20a. In the present embodiment, the upper electrode 22 is, for example, an N pole, and the lower electrode is, for example, a P pole, but the present invention is not limited thereto.

Since the upper electrodes 22 of the LED chips 20a after the mass transfer cannot be used for power-on testing, in the electrical inspection process, the probe unit PU as described in the embodiment of FIGS. 17A and 17B must be used, and the electrical connection with the upper electrodes 22 of the LED chips 20a is realized through the protruding structures PS. After the protruding structures PS of the upper electrode jig 424 contact the upper electrodes 22 and is powered on, they may cooperate with the substrate 410a as a lower electrode to generate a voltage difference between the two electrodes of each LED chip 20a, thereby realizing the electrical inspection of the LED chips 20a.

In certain embodiments, the metal layer 23 may be composed of multiple layers of different metal materials. The metal materials may be, for example, one or more of indium, silver or other metal materials with the same or similar properties, and the present invention is not limited thereto. In addition, in the embodiment where the metal layer 23 is formed by multiple layers of metal materials, the different metal materials may have different cross-sectional areas and stacking sequences.

In some embodiments, the connection layer 25 may be implemented by, for example, an ITO material, but the present invention is also not limited thereto.

Next, referring to FIG. 18B, FIG. 18B shows a plurality of vertical micro-LED chips 20b (hereinafter referred to as the LED chips 20b) disposed on a substrate 410b after the mass transfer. The substrate 410b may be, for example, the alignment substrate SUBa in the previous embodiment, but the present invention is not limited thereto. Each LED chip 20b includes, for example, a light emitting layer 21 and a plurality of metal layers 22 and 23. The metal layer 22 is disposed on one side of the light emitting layer 21 (the upper side in the present embodiment), and is used as the upper electrode of the LED chip 20b (hereinafter referred to as the upper electrode 22). The metal layer 23 is disposed on the opposite side of the light emitting layer 21. When the LED chips 20b are disposed on the substrate 410b after the mass transfer, the metal layer 23 of each LED chip 20b contacts the bottom surface of the corresponding slot of the substrate 410b, such that the part of the substrate 410b in contact with the metal layer 23 may be regarded as the lower electrode of the LED chip 20b. In the present embodiment, the upper electrode 22 is, for example, an N pole, and the lower electrode is, for example, a P pole, but the present invention is not limited thereto.

In the process of performing electrical inspection on the LED chips 20b of the present embodiment, by the probe unit PU as described in the embodiment of FIGS. 17A and 17B, the electrical connection with the upper electrodes 22 of the LED chips 20 may be realized through the protruding structures PS. After the upper electrode jig 424 contacts the upper electrodes 22 and is powered on, it may cooperate with the substrate 410b as a lower electrode to generate a voltage difference between the two electrodes of each LED chip 20b, thereby realizing the electrical inspection of the LED chips 20b.

Furthermore, in the present embodiment, a conductive layer CL is provided on the substrate 410b. The conductive layer CL is continuously formed on the surface of the substrate 410b (including the surfaces inside the slots), such that when an LED chip 20b is disposed in the slot, the conductive layer CL may be electrically connected to the metal layer 23. Therefore, during electrical inspection, by applying a voltage to the probe unit PU and the substrate 410b, a voltage difference may be generated between the two electrodes of each chip 20b. In certain embodiments, the conductive layer CL may be, for example, ITO or IZO formed on the surface of the substrate 410b, and the present invention is not limited thereto.

In the present embodiment, the metal layer 23 may include a first metal layer 231 and a second metal layer 232 arranged in a stacked manner, and the first metal layer 231 is located on the side close to the light emitting layer 21. In certain embodiments, the first metal layer 231 may be, for example, copper or other metal materials with high thermal conductivity, and the second metal layer 232 may be, for example, a magnetic material such as iron or nickel, but the present invention is not limited thereto.

Next, referring to FIG. 18C, FIG. 18C shows a plurality of LED chips 20b disposed on a substrate 410c after the mass transfer. The substrate 410c may be, for example, the alignment substrate SUBa in the previous embodiment, but the present invention is not limited thereto.

The present embodiment is substantially identical to the previous embodiment of FIG. 18B, so similar parts may refer to the descriptions of the above embodiment, and are not further reiterated herein. The main difference between the present embodiment and the previous embodiment of FIG. 18B exists in that the substrate 410c in the present embodiment has a micro-hole structure VH similar to that in FIG. 11E. The conductive layer CL in the present embodiment is formed at the bottom of the slot of the substrate 410c, and extends to the back of the substrate 410b through the micro-hole structure VH. In this way, the flexibility of the external control electrical connection configuration of the conductive layer CL may be improved.

It should be noted that FIGS. 11E, 18B, and 18C respectively illustrate the conductive layer CL configuration structure of different embodiments of the present invention, but the present invention is not limited thereto. The embodiments may prove that, in the alignment substrate structure proposed in the embodiments of the present invention, the conductive layer CL may be formed only on part of the surfaces of the substrate, or only be exposed on part of the surfaces of the substrate, so as to be electrically connected to the corresponding LED chip in the slot and/or electrically connected to the external power supply line.

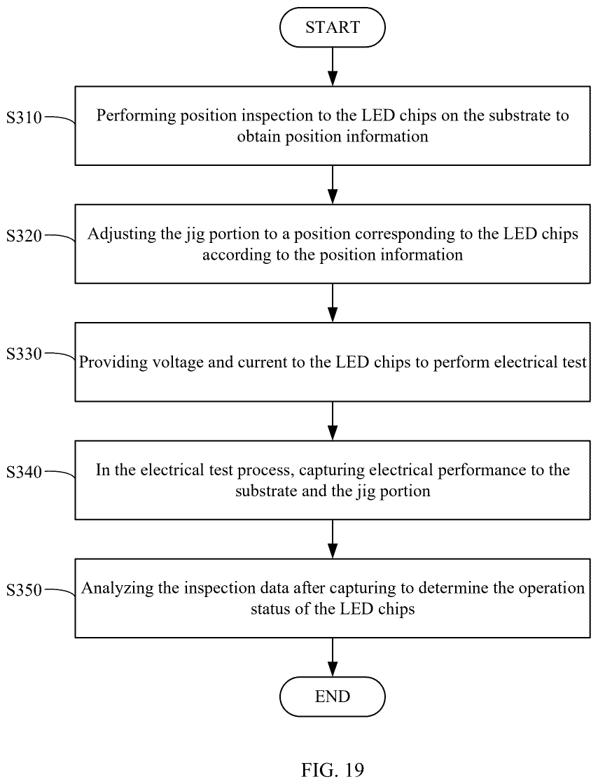

The electrical inspection apparatus 400 may be operated by the electrical inspection method as shown in FIG. 19, where FIG. 19 is a flowchart of the electrical inspection method according to one embodiment of the present invention. Referring to FIG. 16 and FIG. 19 simultaneously, the electrical inspection in the present embodiment includes: performing position inspection to the target objects CP (such as the LED chips 20a shown in FIG. 18A or the LED chips 20b shown in FIG. 18B/18C) on the substrate 410 to obtain position information (step S310); adjusting the jig portion 420 to a corresponding position of the target objects CP according to the position information (step S320); controlling the power supply portion 450 to supply voltage and current to the upper and lower electrodes of the target objects CP to perform electrical test (step S330); performing electrical characteristic capturing through the inspection portion 430 during the electrical testing process (step S340); and analyzing the inspection data after capturing by the control portion 440 to determine the operation state of the target objects CP (step S350).

More specifically, taking the process of adopting the probe unit PU of FIGS. 17A and 17B to perform electrical inspection on the LED chips 20a/20b of FIGS. 18A to 18C as an example, in the step S310, after the LED chips 20a/20b are disposed on the substrate 410a/410b/410c through the mass transfer, position inspection may be performed on the LED chips 20a/20b to obtain the position information. In the step S320, the upper electrode jig 424 of the jig portion 420 may be adjusted to the corresponding position of the LED chip 20a/20b according to the position information, such that each protruding structure PS on the upper electrode jig 424 is electrically connected to the upper electrode 22 of the LED chip 20a/20b. In the step S330, the conductive portion CON of the probe unit PU and the substrate 410a/410b/410c are powered by the power supply portion 450, such that power is applied to the upper electrode 22 of the LED chip 20a/20b through the conductive portion CON and each protruding structure PS, and is also applied to the substrate 410a/410b/410c as a lower electrode simultaneously, thereby lighting up the LED chip 20a/20b. In the steps S340 and S350, after the image capturing is performed by the inspection portion 430, the control portion 440 may analyze the image data after capturing and determine whether the LED chip 20a/20b is lit.

In sum, the electrical inspection apparatus of the present invention may be used to inspect the electrical properties of vertical micro-LED chips after the mass transfer. The existing technology does not have electrical inspection for vertical micro-LED chips after the mass transfer. The present invention uses a transparent upper electrode jig, and generates a voltage difference by applying power to the lower electrode, so as to drive the vertical micro-LED chips to emit light. After the light beam passes through the jig portion, the inspection portion performs the brightness inspection of the vertical micro-LED chips after the mass transfer.

While the present invention has been disclosed by the above embodiments, they are not intended to limit the present invention. Any person skilled in the art who, without departing from the spirit and scope of the present invention, may make various changes and modifications to the embodiments, which still fall within the technical scope protected by the present invention. Therefore, the scope of protection of the present invention shall be determined by the claims.

1. A mass transfer apparatus, comprising:
a supporting portion, configured to support a first substrate and a second substrate;
a picking and disposing portion, disposed relative to the supporting portion, and configured to be controlled to pick up a target object from the first substrate or to dispose the target object on the second substrate;
an inspection portion, disposed relative to the supporting portion and the picking and disposing portion, and configured to inspect a relative position of at least one of the first substrate and the second substrate and the picking and disposing portion, and to generate relative position information to control movement of the supporting portion and the picking and disposing portion;
a control portion, coupled to the supporting portion, the picking and disposing portion and the inspection portion, and configured to control operations of the supporting portion and the picking and disposing portion according to the relative position information; and
an alignment actuation portion, configured to apply an acting force to at least one of the first substrate and the second substrate on the supporting portion to adjust a position of the target object on the substrate to which the acting force is applied.

2. The mass transfer apparatus according to claim 1, wherein when the picking and disposing portion disposes the target object on the second substrate, the supporting portion is controlled to output energy to the second substrate, such that an attaching force of the target object to the second substrate is greater than an attaching force of the target object to the picking and disposing portion.

3. The mass transfer apparatus according to claim 1, wherein the alignment actuation portion applies a suction force to the target object to one of the substrates by a closed channel formed by the supporting portion and one of the substrates.

4. The mass transfer apparatus according to claim 1, wherein the supporting portion comprises:
a supporting platform, configured to support at least one of the first substrate and the second substrate; and
a heating assembly, in contact with the supporting platform, and controlled by the control portion to heat the supporting platform.

5. The mass transfer apparatus according to claim 4, wherein the supporting portion further comprises:
a movement control mechanism, connected to the supporting platform, and configured to drive the supporting platform to move on a first plane.

6. The mass transfer apparatus according to claim 1, wherein the picking and disposing portion comprises:
a movement control mechanism, configured to be controlled to move in a three-dimensional space;
a clamping mechanism, driven by a movement of the movement control mechanism; and
an adhesive substrate, configured to be fixed on the clamping mechanism,
wherein when the picking and disposing portion is controlled to pick up the target object from the first substrate, the movement control mechanism moves to a position aligned to the first substrate according to the relative position information, and drives the adhesive substrate to be in contact with the target object on the first substrate.

7. The mass transfer apparatus according to claim 6, wherein the adhesive substrate comprises:
a rigid layer; and
an adhesive layer, disposed on the rigid layer, and having one side thereof away from the rigid layer facing toward the supporting portion, wherein the adhesive layer has a plurality of first protrusion structures arranged at intervals, and each of the first protrusion structures has a first cross-section configured to be in contact with the target object.

8. The mass transfer apparatus according to claim 7, wherein the adhesive layer further has a plurality of second protrusion structures arranged at intervals and disposed in an array on the rigid layer, and each of the second protrusion structures has a second cross-section configured to support the first protrusion structures.

9. The mass transfer apparatus according to claim 8, wherein an area of the first cross-section is less than an area of the second cross-section.

10. The mass transfer apparatus according to claim 6, wherein the movement control mechanism is a multi-axis movement control mechanism, the multi-axis movement control mechanism has a first movement mode during movement, and when the multi-axis movement control mechanism moves in the first movement mode, three-dimensional coordinates of the multi-axis movement control mechanism are simultaneously changed.

11. The mass transfer apparatus according to claim 1, wherein the alignment actuation portion comprises:
a plurality of vibration mechanisms, configured to generate vibration in different directions, wherein two of the different directions are not parallel to each other.

12. The mass transfer apparatus according to claim 11, wherein
a first vibration mechanism, configured to generate vibration in a first direction;
a second vibration mechanism, configured to generate vibration in a second direction; and
a third vibration mechanism, configured to generate vibration in a third direction,
wherein any of the first direction to the third direction is substantially parallel to a normal direction of a plane formed by the other two of the first direction to the third direction.

13. The mass transfer apparatus according to claim 1, wherein the alignment actuation portion comprises:
an electromagnetic control module, configured to provide power to at least one substrate of the first substrate and the second substrate, such that the at least one substrate generates a magnetic force based on the power.

14. The mass transfer apparatus according to claim 1, wherein the at least one substrate of the first substrate and the second substrate is an alignment substrate, and the alignment substrate comprises a body and a plurality of slots arranged in an array on the body, and the plurality of slots are respectively provided for a plurality of LED chips to be disposed therein.

15. The mass transfer apparatus according to claim 14, wherein at least one of the slots comprises:
a first bottom surface;
a first side wall, surrounding a periphery of the first bottom surface, wherein a bottom of the first side wall is connected to the first bottom surface;
a second bottom surface, having a side connected to a top of the first side wall; and
a second side wall, surrounding a periphery of the second bottom surface, wherein a bottom of the second side wall is connected to another side of the second bottom surface;
wherein a sum of heights of the first side wall and the second side wall is greater than a width of the first bottom surface.

16. The mass transfer apparatus according to claim 14, wherein at least one of the slots comprises:
a first bottom surface;
a first side wall, surrounding a periphery of the first bottom surface, wherein a bottom of the first side wall is connected to the first bottom surface; and
a plurality of micro-hole structures, disposed respectively corresponding to the slots, and formed between the first bottom surface and a bottom of the body;
wherein each of the micro-hole structures has a first opening and a second opening, the first opening is exposed to the first bottom surface, and the second opening is exposed to the bottom of the body.

17. The mass transfer apparatus according to claim 14, wherein at least one of the slots comprises:
a first bottom surface;
a first side wall, surrounding a periphery of the first bottom surface, wherein a bottom of the first side wall is connected to the first bottom surface, and at least one surface of the first side wall is not perpendicular to the first bottom surface.

18. The mass transfer apparatus according to claim 14, wherein the alignment substrate further comprises:
a plurality of material receiving portions, respectively formed at bottoms of the slots; and
a magnetic structure, formed of a curable magnetic material, disposed in the material receiving portions, wherein magneticity of the curable magnetic material corresponds to the magneticity of a plurality of LED chips.

19. (canceled)

20. (canceled)

21. A mass transfer method, applicable to a mass transfer apparatus comprising a picking and disposing portion and a supporting portion, wherein the supporting portion is configured to support a first substrate and a second substrate, and the mass transfer method comprises:
applying a first acting force by the supporting portion, such that the plurality of target objects fall into a plurality of slots of the first substrate respectively;
controlling the picking and disposing portion to pick up the target objects from the first substrate;
controlling the picking and disposing portion to dispose the target objects being picked up on the second substrate; and
applying a second acting force by the supporting portion, such that an attaching force of the target objects to the second substrate is greater than an attaching force of the target objects to the picking and disposing portion, and the target objects are transferred from the picking and disposing portion to the second substrate.

22. The mass transfer method according to claim 21, further comprising, after the step of controlling the picking and disposing portion to pick up the target objects from the first substrate:
controlling the picking and disposing portion to dispose the target objects being picked up on the reorientation substrate;
moving and flipping the reorientation substrate, such that the target objects face toward the supporting portion; and
controlling the picking and disposing portion to move the reorientation substrate toward the second substrate, such that the target objects contact the second substrate.
